(19) United States
(12) Patent Application Publication
(10) Pub. No.: US 2026/0162724 A1
(43) Pub. Date: Jun. 11, 2026

(54) SEMICONDUCTOR MEMORY DEVICE AND MEMORY SYSTEM

(71) Applicant: Kioxia Corporation, Tokyo (JP)

(72) Inventors: Fumitaka ARAI, Yokkaichi Mie (JP); Ryota KATSUMATA, Yokkaichi Mie (JP)

(73) Assignee: Kioxia Corporation, Tokyo (JP)

(21) Appl. No.: 19/325,430

(22) Filed: Sep. 10, 2025

(30) Foreign Application Priority Data
Dec. 9, 2024 (JP) 2024-214722

(51) Int. Cl. G11C 16/04

(52) U.S. Cl. CPC G11C 16/0483

(57) ABSTRACT

According to one embodiment, a semiconductor memory device includes memory strings arranged apart from each other in a first direction. The memory strings each include a semiconductor layer extending in a second direction intersecting the first direction, a first string arranged closer to a first side surface of the semiconductor layer in a third direction intersecting the first direction and the second direction, and a second string arranged closer to a second side surface of the semiconductor layer in the third direction. The first string includes a first select transistor and first memory cell transistors each using the semiconductor layer as a channel and arranged apart from each other in the second direction. The second string includes first transistors and a second select transistor each using the semiconductor layer as a channel and arranged apart from each other in the second direction.

### CROSS-REFERENCE TO RELATED APPLICATION(S)

This application is based upon and claims the benefit of priority from Japanese Patent Application No. 2024-214722, filed Dec. 9, 2024, the entire contents of which are incorporated herein by reference.

### FIELD

Embodiments described herein relate generally to a semiconductor memory device and a memory system.

### BACKGROUND

A memory system including a semiconductor memory device and a memory controller configured to control the semiconductor memory device is known. A NAND flash memory is known as the semiconductor memory device.

### BRIEF DESCRIPTION OF THE DRAWINGS

FIG. 1 is a block diagram showing an example of a configuration of a memory system including a semiconductor memory device according to a first embodiment.

FIG. 2 is a circuit diagram showing an example of a circuit configuration of a memory cell array included in the semiconductor memory device according to the first embodiment.

FIG. 3 is a planar view showing an example of a planar layout of the memory cell array included in the semiconductor memory device according to the first embodiment.

FIG. 4 is a cross-sectional view taken along line IV-IV of FIG. 3 and showing an example of a cross-sectional structure of the memory cell array included in the semiconductor memory device according to the first embodiment.

FIG. 5 is a cross-sectional view taken along line V-V of FIG. 3 and showing an example of a cross-sectional structure of the memory cell array included in the semiconductor memory device according to the first embodiment.

FIG. 6 is a cross-sectional view taken along line VI-VI of FIG. 3 and showing an example of a cross-sectional structure of the memory cell array included in the semiconductor memory device according to the first embodiment.

FIG. 7 is a cross-sectional view taken along line VII-VII of FIG. 3 and showing an example of the cross-sectional structure of the memory cell array included in the semiconductor memory device according to the first embodiment.

FIG. 8 is a view showing voltages of respective interconnects in a first read operation of the semiconductor memory device according to the first embodiment.

FIG. 9 is a circuit diagram showing an example of a circuit configuration of a memory cell array included in a semiconductor memory device according to a modification of the first embodiment.

FIG. 10 is a planar view showing an example of a planar layout of the memory cell array included in the semiconductor memory device according to the modification of the first embodiment.

FIG. 11 is a view showing voltages of respective interconnects in a first read operation of the semiconductor memory device according to the modification of the first embodiment.

FIG. 12 is a circuit diagram showing an example of a circuit configuration of a memory cell array included in a semiconductor memory device according to a second embodiment.

FIG. 13 is a planar view showing an example of a planar layout of the memory cell array included in the semiconductor memory device according to the second embodiment.

FIG. 14 is a flowchart showing an example of a write operation of the semiconductor memory device according to the second embodiment.

FIG. 15 is a view showing voltages of respective interconnects in the first read operation of the semiconductor memory device according to the second embodiment.

FIG. 16 is a circuit diagram showing an example of a circuit configuration of a memory cell array included in a semiconductor memory device according to a modification of the second embodiment.

FIG. 17 is a planar view showing an example of a planar layout of the memory cell array included in the semiconductor memory device according to the modification of the second embodiment.

FIG. 18 is a view showing voltages of respective interconnects in the first read operation of the semiconductor memory device according to the modification of the second embodiment.

FIG. 19 is a view illustrating a string flag used in a semiconductor memory device according to a third embodiment.

FIG. 20 is a flowchart showing an example of a write operation of the semiconductor memory device according to the third embodiment.

FIG. 21 is a flowchart showing an example of a read operation of the semiconductor memory device according to the third embodiment.

FIG. 22 is a view showing voltages of respective interconnects in a first read operation of the semiconductor memory device according to the third embodiment.

FIG. 23 is a conceptional diagram of a string table used in a semiconductor memory device according to a first modification of the third embodiment.

FIG. 24 is a flowchart showing an example of a write operation of the semiconductor memory device according to the first modification of the third embodiment.

FIG. 25 is a flowchart showing an example of a read operation of the semiconductor memory device according to the first modification of the third embodiment.

FIG. 26 is a view showing voltages of respective interconnects in a first read operation of a semiconductor memory device according to a second modification of the third embodiment.

FIG. 27 is a view illustrating a method of designating a memory mode of a block in a semiconductor memory device according to a fourth embodiment.

FIG. 28 is a flowchart showing an example of a write operation of the semiconductor memory device according to the fourth embodiment.

FIG. 29 is a flowchart showing an example of a read operation of the semiconductor memory device according to the fourth embodiment.

FIG. 30 is a view showing voltages of respective interconnects in a second read operation of the semiconductor memory device according to the fourth embodiment.

FIG. 31 is a view showing voltages of respective interconnects in a second read operation of a semiconductor memory device according to a first modification of the fourth embodiment.

FIG. 32 is a view illustrating a method of designating a memory mode of a block in a semiconductor memory device according to a second modification of the fourth embodiment.

FIG. 33 is a view illustrating a mode flag used in the semiconductor memory device according to the second modification of the fourth embodiment.

FIG. 34 is a flowchart showing an example of a block region variable operation of the semiconductor memory device according to the second modification of the fourth embodiment.

FIG. 35 is a flowchart showing an example of a first variable operation of the semiconductor memory device according to the second modification of the fourth embodiment.

FIG. 36 is a flowchart showing an example of a second variable operation of the semiconductor memory device according to the second modification of the fourth embodiment.

FIG. 37 is a flowchart showing an example of a read operation of the semiconductor memory device according to the second modification of the fourth embodiment.

FIG. 38 is a conceptional diagram of a mode table used in a semiconductor memory device according to a third modification of the fourth embodiment.

FIG. 39 is a flowchart showing an example of a write operation of the semiconductor memory device according to the third modification of the fourth embodiment.

FIG. 40 is a flowchart showing an example of a block region variable operation of the semiconductor memory device according to the third modification of the fourth embodiment.

FIG. 41 is a flowchart showing an example of a first variable operation of the semiconductor memory device according to the third modification of the fourth embodiment.

FIG. 42 is a flowchart showing an example of a second variable operation of the semiconductor memory device according to the third modification of the fourth embodiment.

FIG. 43 is a flowchart showing an example of a read operation of the semiconductor memory device according to the third modification of the fourth embodiment.

FIG. 44 is a view illustrating a method of designating a memory mode of a block in a semiconductor memory device according to a fourth modification of the fourth embodiment.

FIG. 45 is a flowchart showing an example of a write operation of the semiconductor memory device according to the fourth modification of the fourth embodiment.

FIG. 46 is a flowchart showing an example of a write operation of a semiconductor memory device according to a fifth modification of the fourth embodiment.

FIG. 47 is a block diagram showing an example of a configuration of a memory system including a semiconductor memory device according to a fifth embodiment.

FIG. 48 is a block diagram showing an example of a configuration of an arithmetic module included in the semiconductor memory device according to the fifth embodiment.

FIG. 49 is a flowchart showing an example of arithmetic processing performed by the arithmetic module of the semiconductor memory device according to the fifth embodiment.

FIG. 50 is a block diagram showing an example of a configuration of an AI module in which a memory system including the semiconductor memory device according to the fifth embodiment is incorporated.

### DETAILED DESCRIPTION

In general, according to one embodiment, a semiconductor memory device includes a plurality of memory strings arranged apart from each other in a first direction. The plurality of memory strings each include a semiconductor layer extending in a second direction intersecting the first direction, a first string arranged closer to a first side surface of the semiconductor layer in a third direction intersecting the first direction and the second direction, and a second string arranged closer to a second side surface of the semiconductor layer in the third direction. The first string includes a first select transistor and a plurality of first memory cell transistors each using the semiconductor layer as a channel and arranged apart from each other in the second direction. The second string includes a plurality of first transistors and a second select transistor each using the semiconductor layer as a channel and arranged apart from each other in the second direction.

Hereinafter, embodiments will be described with reference the accompanying drawings. The drawings are either schematic or conceptual, and the dimensions and ratios of each drawing are not necessarily the same as the actual ones. In the following description, constituent elements having substantially the same function and configuration will be assigned the same reference symbol. In a case where elements having similar configurations are distinguished from each other in particular, their identical reference symbols may be assigned different letters or numbers.

In the following description, a first component being “coupled” to a second element includes the first component being coupled to the second component directly or through the intervention of a component that is constantly conductive or selectively conductive.

### 1. First Embodiment

A semiconductor memory device according to a first embodiment will be described.

### 1.1 Configuration

### 1.1.1 Configuration of Memory System

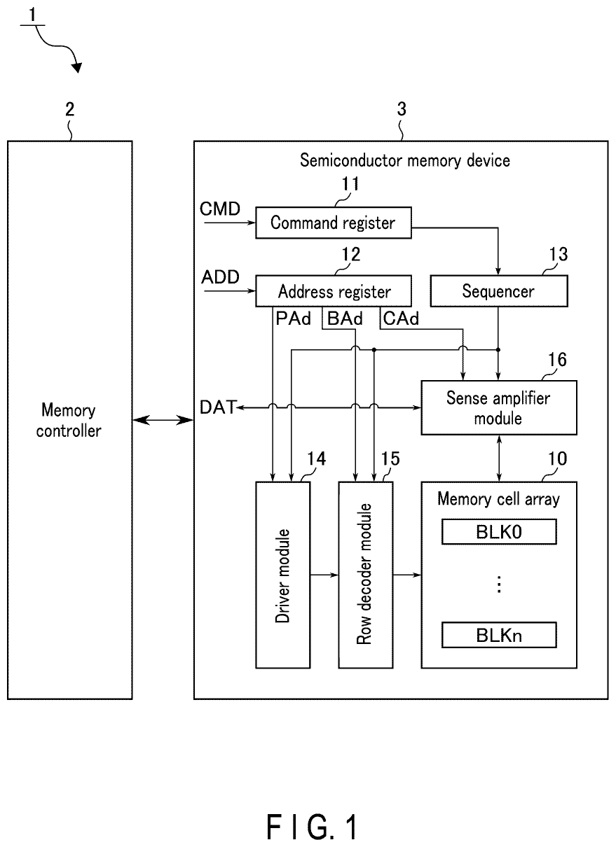

A configuration of a memory system including a semiconductor memory device according to a first embodiment will be described with reference to FIG. 1. FIG. 1 is a block diagram showing an example of the configuration of the memory system including the semiconductor memory device according to the first embodiment.

A memory system 1 is a memory device configured to be coupled to an external host (not shown). The memory system 1 is, for example, a memory card such as an SD™ card, a Universal Flash Storage (UFS), or a solid-state drive (SSD). The memory system 1 includes a memory controller 2 and a semiconductor memory device 3.

The memory controller 2 is configured as, for example, an integrated circuit such as a system-on-a-chip (SoC). The memory controller 2 is configured to control the semiconductor memory device 3 on the basis of a request received from the host. Specifically, for example, the memory controller 2 writes data which the host has requested the memory controller 2 to write to the semiconductor memory device 3. Furthermore, the memory controller 2 reads data which the host has requested the memory controller 2 to read from the semiconductor memory device 3 and transmits the read data to the host.

The semiconductor memory device 3 is a nonvolatile memory. The semiconductor memory device 3 is, for example, a NAND flash memory. The semiconductor memory device 3 is configured to store data in a nonvolatile manner.

Communications between the memory controller 2 and the semiconductor memory device 3 are compliant with, for example, a single data rate (SDR) interface, a toggle double data rate (DDR) interface, or an open NAND flash interface (ONFI).

### 1.1.2 Configuration of Semiconductor Memory Device

Continuously referring to the block diagram shown in FIG. 1, an internal configuration of the semiconductor memory device 3 will be described. The semiconductor memory device 3 includes, for example, a memory cell array 10, a command register 11, an address register 12, a sequencer 13, a driver module 14, a row decoder module 15, and a sense amplifier module 16.

The memory cell array 10 includes a plurality of blocks BLK0 to BLKn (where n is an integer equal to or greater than 1). The number of blocks BLK included in the memory cell array 10 may be 1. The block BLK is a set of a plurality of memory cells. The block BLK is used as, for example, a data erase unit. In the memory cell array 10, a plurality of bit lines and a plurality of word lines are provided. Each memory cell is associated with, for example, one bit line and one word line. A detailed configuration of the memory cell array 10 will be described later.

The command register 11 stores a command CMD which the semiconductor memory device 3 receives from the memory controller 2. The command CMD includes, for example, an order to cause the sequencer 13 to execute a read operation, a write operation, an erase operation, etc.

The address register 12 stores address information ADD which the semiconductor memory device 3 receives from the memory controller 2. The address information ADD includes, for example, a block address BAd, a page address PAd, and a column address CAd. For example, the block address BAd, the page address PAd, and the column address CAd are used to select a block BLK, a word line, and a bit line, respectively.

The sequencer 13 controls the overall operation of the semiconductor memory device 3. For example, the sequencer 13 controls the driver module 14, the row decoder module 15, and the sense amplifier module 16, etc., on the basis of the command CMD stored in the command register 11, thereby performing the read operation, the write operation, the erase operation, etc.

The driver module 14 generates voltages used in the read operation, the write operation, the erase operation, etc. The driver module 14 applies, based on the page address PAd stored in the address register 12, the generated voltage to a signal line corresponding to the selected word line.

Based on the block address BAd stored in the address register 12, the row decoder module 15 selects one corresponding block BLK in the memory cell array 10. Then, the row decoder module 15 transfers, for example, the voltage applied to the signal line corresponding to the selected word line to the selected word line in the selected block BLK.

The sense amplifier module 16 applies a desired voltage to each bit line in the write operation, in accordance with write data DAT received from the memory controller 2. In the read operation, the sense amplifier module 16 determines data stored in a memory cell on the basis of the voltage of the bit line, and transfers a result of the determination to the memory controller 2 as the read data DAT.

### 1.1.3 Circuit Configuration of Memory Cell Array

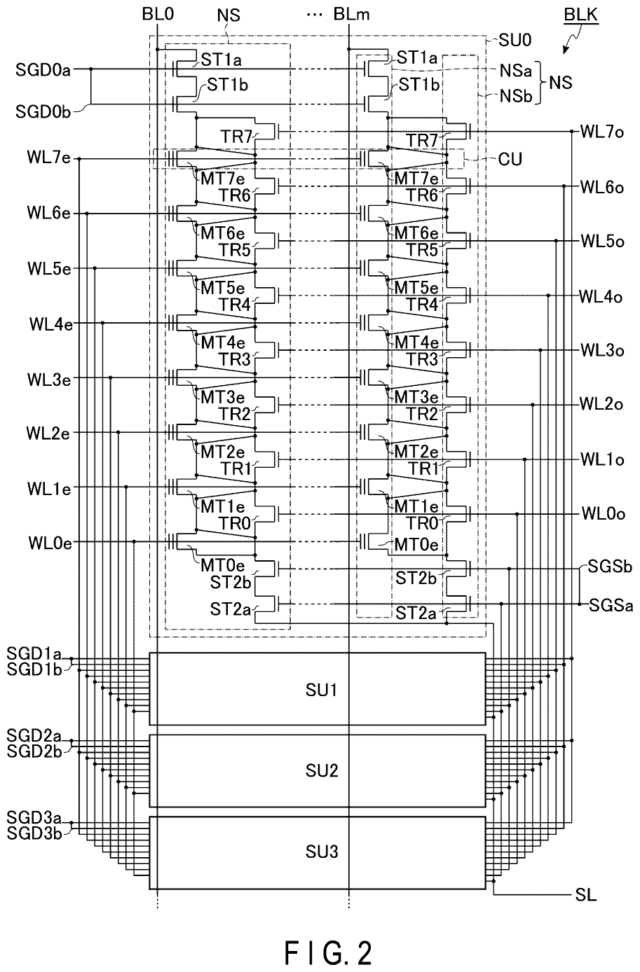

A circuit configuration of the memory cell array 10 will be described with reference to FIG. 2. FIG. 2 is a circuit diagram showing an example of the circuit configuration of the memory cell array 10. FIG. 2 shows a circuit configuration of the block BLK included in the memory cell array 10, as an example of the circuit configuration of the memory cell array 10. The other blocks BLK have similar configurations to that shown in FIG. 2.

The block BLK includes, for example, four string units SU0 to SU3. Each string unit SU is, for example, a set of NAND strings NS which are selected in batch during the write operation or the read operation. The string unit SU includes a plurality of NAND strings NS respectively associated with bit lines BL0 to BLm (where m is an integer equal to or greater than 1). Each NAND string NS is a set of memory cell transistors MT coupled in series.

The NAND string NS includes a first string NSa and a second string NSb. The first string NSa is a string configured to store data (hereinafter, also referred to as a “memory string”). The second string NSb is a string through which a read current flows (hereinafter, also referred to as a “read string”). The first string NSa includes, for example, memory cell transistors MT0e to MT7e and select transistors ST1a and ST1b. The second string NSb includes, for example, transistors TR0 to TR7 and select transistors ST2a and ST2b. A memory cell transistor MTe nonvolatilely stores data. The memory cell transistor MTe includes a control gate and a charge storage layer. The transistors TR0 to TR7 and the select transistors ST1a, ST1b, ST2a, an ST2b are switching elements. Each of the select transistors ST1a and ST2a is used for selection of a string unit SU at the time of various operations.

In the NAND strings NS, the memory cell transistors MT0e to MT7e are coupled in series. One end of the set of memory cell transistors MT0e to MT7e coupled in series (one end of the memory cell transistor MT7e) is coupled to a source of the select transistor ST1b. A drain of the select transistor ST1b is coupled to a source of the select transistor ST1a. A drain of the select transistor ST1a is coupled to the bit line BL associated therewith. The other end of the set of memory cell transistors MT0e to MT7e coupled in series (the other end of the memory cell transistor MT0e) is coupled to a drain of the select transistor ST2b. The transistors TR0 to TR7 are coupled in series. One end of the set of transistors TR0 to TR7 coupled in series (one end of the transistor TR7) is coupled to the source of the select transistor ST1b. The other end of the set of transistors TR0 to TR7 coupled in series (the other end of the transistor TR0) is coupled to the drain of the select transistor ST2b. A source of the select transistor ST2b is coupled to the drain of the select transistor ST2a. A source of a select transistor ST2a is coupled to a source line SL.

Furthermore, in each NAND string NS, one end of the memory cell transistor MT7e is coupled to each of one end and the other end of the transistor TR7. One end of the transistor TR6 is coupled to the other end of the memory cell transistor MT7e. One end of the memory cell transistor MT6e is coupled to the other end of the transistor TR6. One end of the transistor TR5 is coupled to the other end of the memory cell transistor MT6e. One end of the memory cell transistor MT5e is coupled to the other end of the transistor TR5. One end of the transistor TR4 is coupled to the other end of the memory cell transistor MT5e. One end of the memory cell transistor MT4e is coupled to the other end of the transistor TR4. One end of the transistor TR3 is coupled to the other end of the memory cell transistor MT4e. One end of the memory cell transistor MT3e is coupled to the other end of the transistor TR3. One end of the transistor TR2 is coupled to the other end of the memory cell transistor MT3e. One end of the memory cell transistor MT2e is coupled to the other end of the transistor TR2. One end of the transistor TR1 is coupled to the other end of the memory cell transistor MT2e. One end of the memory cell transistor MT1e is coupled to the other end of the transistor TR1. One end of the transistor TR0 is coupled to the other end of the memory cell transistor MT1e. One end of the memory cell transistor MT0e is coupled to the other end of the transistor TR0. The drain of the select transistor ST2b is coupled to the other end of the memory cell transistor MT0e.

In the same block BLK, control gates of the memory cell transistors MT0e to MT7e are respectively coupled in common to word lines WL0e to WL7e. Gates of transistors TR0 to TR7 are respectively coupled in common to word lines WL0o to WL7o. Gates of the select transistors ST1a in string units SU0 to SU3 are respectively coupled to select gate decode lines SGD0a to SGD3a. Hereinafter, in a case where the select gate decode lines SGD0a to SGD3a are not distinguished from each other, they will be simply referred to as a “select gate decode line SGDa”. Gates of the select transistors ST1b in the string units SU0 to SU3 are respectively coupled to select gate decode lines SGD0b to SGD3b. Furthermore, the select gate decode line SGD0b is coupled to the select gate decode line SGD0a. The select gate decode line SGD1b is coupled to the select gate decode line SGD1a. The select gate decode line SGD2b is coupled to the select gate decode line SGD2a. The select gate decode line SGD3b is coupled to the select gate decode line SGD3a. Hereinafter, in a case where the select gate decode lines SGD0b to SGD3b are not distinguished from each other, they will be simply referred to as a “select gate decode line SGDb”. Gates of the select transistors ST2a in the same block BLK are coupled to a select gate decode line SGSa. Gates of the select transistors ST2b in the same block BLK are coupled to a select gate decode line SGSb. Furthermore, the select gate decode line SGSb is coupled to the select gate decode line SGSa.

In the circuit configuration of the memory cell array 10 described above, the bit line BL is shared by, for example, the plurality of NAND strings NS to which the same column address is assigned in the plurality of string units SU. The source line SL is shared by, for example, the plurality of blocks BLK.

A set of memory cell transistors MT coupled to a common word line WL in one string unit SU will be referred to, for example, as a “cell unit CU”. Each of the blocks BLK includes a plurality of cells units CU. Data stored in the cell unit CU including the plurality of memory cell transistors MT each configured to store 1-bit data in accordance with a threshold voltage is equivalent to 1-page data. The cell unit CU may store 2-page data or more based on the number of bits stored in the memory cell transistors MT. In the present embodiment, the memory cell transistors MT will be presented by a single-level cell (SLC) configured to store 1-bit data, a multi-level cell (MLC) configured to store 2-bit data, a triple-level cell (TLC) configured to store 3-bit data, or a quad-level cell (QLC) configured to store 4-bit data; however, the memory cell transistors MT are capable of storing a number of bits other than the aforementioned numbers.

In addition, the circuit configuration of the memory cell array 10 is not limited to the configuration described above. For example, the number of string units SU in each block BLK and the number of memory cell transistors MT, transistors TR, and select transistors ST1 and ST2 in each NAND string NS may be set freely.

### 1.1.4 Structure of Memory Cell Array

A structure of the memory cell array 10 will be described. The memory cell array 10 is provided above a substrate. Hereinafter, a plane parallel to a surface of the substrate will be referred to as an “XY plane”. The directions intersecting each other on the XY plane will be referred to as an “X direction” and a “Y direction”. The direction extending from the substrate to the memory cell array 10 will be referred to as a “Z direction”. That is, the Z direction intersects the Y direction and the Y direction. The Z direction may be read as an “upper direction”.

### 1.1.4.1 Planar Layout of Memory Cell Array

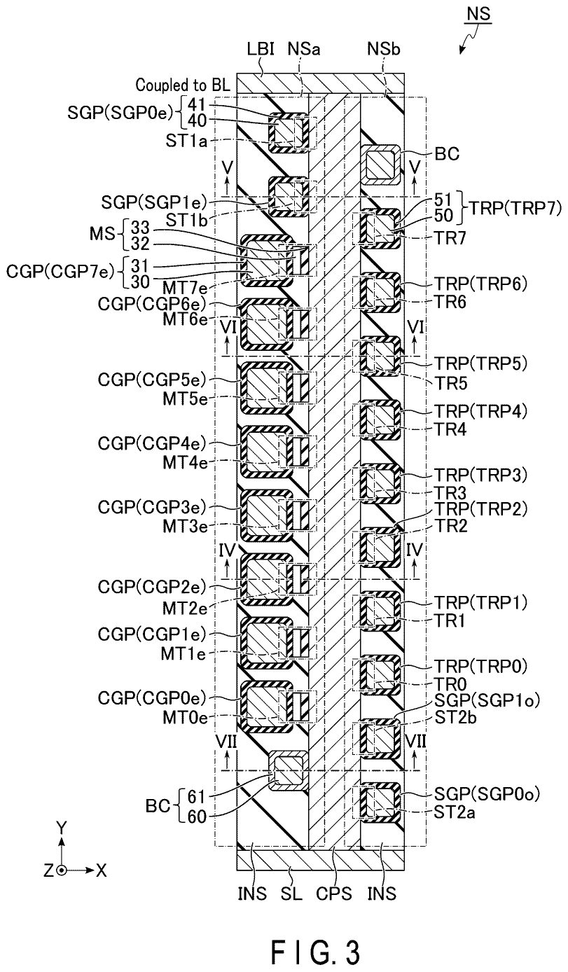

A planar layout of the memory cell array 10 will be described. FIG. 3 is a planar view showing an example of the planar layout of the memory cell array 10. FIG. 3 shows a planar view of a layer substantially equal in height (that is, a position in the Z direction) from the substrate in the block BLK. A portion shown in FIG. 3 corresponds to one NAND string NS in the circuit diagram shown in FIG. 2.

As shown in FIG. 3, in the same layer, the memory cell array 10 includes a semiconductor CPS, an interconnect LBI, a source line SL, a plurality of insulators INS, a plurality of conductive pillars CGP, SGP, and TRP, a plurality of memory structures MS, and a plurality of contact plugs BC.

The semiconductor CPS is a semiconductor extending over the XY plane. The semiconductor CPS includes, for example, polysilicon. The semiconductor CPS is formed into a line shape extending in the Y direction. One end in the Y direction of the semiconductor CPS is coupled to the interconnect LBI. The other end in the Y direction of the semiconductor CPS is coupled to the source line SL. The semiconductor CPS functions as a channel of the NAND string NS.

The interconnect LBI is a conductor extending in the X direction. The interconnect LBI is coupled to the bit line BL (not shown).

The source line SL is a conductor extending in the X direction.

The insulator INS is an insulator extending in the Y direction. The insulator INS includes, for example, silicon oxide. The insulator INS is provided in a region between the interconnect LBI and the source line SL. The example in FIG. 3 shows a case in which two insulators INS are arranged apart from each other in the X direction. The semiconductor CPS is positioned between two insulators INS.

The plurality of conductive pillars CGP, SGP, and TRP, and the plurality of contact plugs BC each extend in the Z direction so as to intersect the insulator INS and the semiconductor CPS. The plurality of conductive pillars CGP, SGP, and TRP, and the plurality of contact plugs BC are each provided on the left side in the drawing sheet and on the right side in the drawing sheet of the semiconductor CPS in a region between the interconnect LBI and the source line SL. Hereinafter, the left side in the drawing sheet of the semiconductor CPS will also be referred to as a “front side of the semiconductor CPS” or a “first side surface-side of the semiconductor CPS in the X direction”. The right side in the drawing sheet of the semiconductor CPS will also be referred to as a “rear side of the semiconductor CPS” or a “second side surface-side of the semiconductor CPS in the X direction”.

On the front side of the semiconductor CPS, the first string NSa is arranged. In the first string NSa, for example, two conductive pillars SGP, eight conductive pillars CGP, and one contact plug BC are arranged in this order from the upper side of the drawing sheet in the Y direction. Two conductive pillars SGP, eight conductive pillars CGP, and one contact plug BC are spaced apart from each other in the Y direction. Hereinafter, two conductive pillars SGP will also be referred to as “conductive pillars SGP0e and SGP1e”, respectively, in order from the upper side of the drawing sheet. Eight conductive pillars CGP will also be referred to as “conductive pillars CGP0e to CGP7e”, respectively, in order from the lower side of the drawing sheet.

On the rear side of the semiconductor CPS, the second string NSb is arranged. In the second string NSb, for example, one contact plug BC, eight conductive pillars TRP, and two conductive pillars SGP are arranged in this order from the upper side of the drawing sheet in the Y direction. One contact plug BC, eight conductive pillars TRP, and two conductive pillars SGP are spaced apart from each other in the Y direction. Hereinafter, eight conductive pillars TRP will also be referred to as “conductive pillars TRP0 to TRP7”, respectively, in order from the lower side of the drawing sheet. Two conductive pillars SGP will also be referred to as “conductive pillars SGP0o and SGP1o”, respectively, in order from the lower side of the drawing sheet.

When viewed from the upper surface (viewed in the Z direction), center positions of the plurality of conductive pillars CGP, SGP, and TRP and the plurality of contact plugs BC are displaced from each other in the Y direction. In other words, the plurality of conductive pillars CGP, SGP, and TRP and the plurality of contact plugs BC are each arranged in, for example, in a 22-row staggered pattern in a region between the interconnect LBI and the source line SL.

The plurality of conductive pillars CGP and SGP and the contact plug BC on the front side of the semiconductor CPS will be described.

A portion of the side surface of the conductive pillar CGP (a portion of a side surface facing the semiconductor CPS) is in contact with one of the two side surfaces facing the semiconductor CPS of the memory structure MS. The other one of the two side surfaces facing the semiconductor CPS of the memory configuration MS is in contact with the semiconductor CPS. That is, a portion of the side surface of the conductive pillar CGP is in contact with the semiconductor CPS via the memory structure MS. Of the side surface of the conductive pillar CGP, a portion not in contact with the memory structure MS is in contact with the insulator INS.

The conductive pillar CGP includes a conductive film 30 and an insulating film 31. The conductive film 30 includes, for example, tungsten, titanium nitride, or both tungsten and titanium nitride. The conductive film 30 functions as the word line WL. The insulating film 31 surrounds the side surface of the conductive film 30. The insulating film 31 includes, for example, silicon oxide. The insulating film 31 functions as a block insulating film. The insulating film 31 may be formed by stacking a plurality of layers.

The memory structure MS includes a charge storage film 32 and an insulating film 33. The charge storage film 32 covers a portion of the side surface of the insulating film 31. The charge storage film 32 includes a material having a function of storing charges. Specifically, the charge storage film 32 may include a conductor such as, for example, silicon or metal. Furthermore, the charge storage film 32 may also include an insulator such as, for example, silicon nitride. The insulating film 33 covers a portion of the side surface of the charge storage film 32. The insulating film 33 is, for example, silicon oxide. The insulating film 33 functions as a tunnel insulating film. The semiconductor CPS covers a portion of the side surface of the insulating film 33.

The above-mentioned structure including one conductive pillar CGP, one memory structure MS, and the semiconductor CPS functions as a memory cell transistor MT. FIG. 3 shows eight of the above-mentioned structures which respectively function as the memory cell transistors MT7e, MT6e, MT5e, MT4e, MT3e, MT2e, MT1e, and MT0e, in this order from the upper side of the drawing sheet. In a case where the charge storage film 32 includes a conductor such as silicon or metal, the memory cell transistor MT functions as a floating gate-type memory cell transistor MT. In a case where the charge storage film 32 includes an insulator such as silicon nitride, the memory cell transistor MT functions as a metal-oxide-nitride-oxide-silicon (MONOS) type memory cell transistor MT.

A portion of the side surface of the conductive pillar SGP (a portion of the side surface facing the semiconductor CPS) is in contact with the semiconductor CPS. Of the side surface of the conductive pillar SGP, a portion not in contact with the semiconductor CPS is in contact with the insulator INS.

The conductive pillar SGP includes a conductive film 40 and an insulating film 41. The conductive film 40 includes, for example, tungsten, titanium nitride, or both tungsten and titanium nitride. The conductive film 40 functions as a select gate decode line SGD. The insulating film 41 surrounds the side surface of the conductive film 40. The insulating film 41 includes, for example, silicon oxide. The insulating film 41 may be formed by stacking a plurality of layers.

The above-mentioned structure including one conductive pillar SGP and the semiconductor CPS functions as the select transistor ST. FIG. 3 shows two of the above-mentioned structures which respectively function as the select transistors ST1a and ST1b in this order from the upper side of the drawing sheet.

As described above, the first string NSa includes select transistors ST1a and ST1b and the memory cell transistors MT0e to MT7e each using the semiconductor CPS as a channel and arranged apart from each other in the Y direction.

A portion of the side surface of the contact plug BC (a portion of the side surface facing the semiconductor CPS) is in contact with the semiconductor CPS. Of the side surface of the contact plug BC, a portion not in contact with the semiconductor CPS is in contact with the insulator INS.

The contact plug BC includes a conductive film 60 and a semiconductor film 61. The conductive film 60 includes, for example, tungsten, titanium nitride, or both tungsten and titanium nitride. The semiconductor film 61 surrounds the side surface of the conductive film 60. The semiconductor film 61 includes, for example, polysilicon including P-type impurities. The contact plug BC functions as, for example, a hole supply source configured to inject holes into the charge storage film 32 of the memory cell transistor MT in the erase operation.

The above-mentioned structure including the semiconductor CPS and a set of two conductive pillars SGP, eight conductive pillars CGP, eight memory structures MS, and one contact plug BC on the front side of the semiconductor CPS corresponds to the first string NSa.

The conductive pillars TRP and SGP and the contact plug BC on the rear side of the semiconductor CPS will be described.

A portion of the side surface of the conductive pillar TRP (a portion of the side surface facing the semiconductor CPS) is in contact with the semiconductor CPS. Of the side surface of the conductive pillar TRP, a portion not in contact with the semiconductor CPS is in contact with the insulator INS.

The conductive pillar TRP includes a conductive film 50 and an insulating film 51. The conductive film 50 includes, for example, tungsten, titanium nitride, or both tungsten and titanium nitride. The conductive film 50 functions as the word line WL. The insulating film 51 surrounds the side surface of the conductive film 50. The insulating film 51 includes, for example, silicon oxide. The insulating film 51 may be formed by stacking a plurality of layers. Furthermore, the conductive pillar TRP may have a similar structure to that of the conductive pillar SGP or may have a different structure from that of the conductive pillar SGP.

The above-mentioned structure including one conductive pillar TRP and the semiconductor CPS functions as the transistor TR. FIG. 3 shows eight of the above-mentioned structures which respectively function as the transistors TR7, TR6, TR5, TR4, TR3, TR2, TR1, and TR0, in this order from the upper side of the drawing sheet.

A portion of the side surface of the conductive pillar SGP (a portion of the side surface facing the semiconductor CPS) is in contact with the semiconductor CPS. Of the side surface of the conductive pillar SGP, a portion not in contact with the semiconductor CPS is in contact with the insulator INS. The conductive pillar SGP has a similar structure to that of the conductive pillar SGP on the front side of the semiconductor CPS. The conductive film 30 functions as a select gate decode line SGS.

The above-mentioned structure including one conductive pillar SGP and the semiconductor CPS functions as the select transistor ST. FIG. 3 shows two of the above-mentioned structures which respectively function as the select transistors ST2b and ST2a in this order from the upper side of the drawing sheet.

As described above, the second string NSb includes the transistors TR0 to TR7 and the select transistors ST2a and ST2b each using the semiconductor CPS as a channel and arranged apart from each other in the Y direction. The transistors TR0 to TR7 may have the same structures as those of the select transistors ST1a, ST1b, ST2a, and ST2b.

A portion of the side surface of the contact plug BC (a portion of the side surface facing the semiconductor CPS) is in contact with the semiconductor CPS. Of the side surface of the contact plug BC, a portion not in contact with the semiconductor CPS is in contact with the insulator INS. The contact plug BC has a similar structure to that of the contact plug BC on the front side of the semiconductor CPS.

The above-mentioned structure including the semiconductor CPS and a set of two conductive pillars SGP, eight conductive pillars TRP, and one contact plug BC on the rear side of the semiconductor CPS corresponds to the second string NSb.

The plurality of NAND strings NS coupled to the same bit line BL are arranged such that the same structures, one of which is shown in FIG. 3, are apart from each other in the X direction in a region between the interconnect LBI and the source line SL, for example. More specifically, the above-mentioned structures (hereinafter, also referred to as “first structures”) each including the semiconductor CPS, the structure on the front side of the semiconductor CPS (two conductive pillars SGP, eight conductive pillars CGP, eight memory structures MS, and one contact plug BC), and the structure on the rear side of the semiconductor CPS (one contact plug BC, eight conductive pillars TRP, and two conductive pillars SGP) are arranged apart from each other in the X direction.

The plurality of NAND strings NS coupled to the same bit line BL may be arranged such that the first structures and structures corresponding to the first structures in which the structure on the front side of the semiconductor CPS is switched with the structure on the rear side thereof (hereinafter, also referred to as “second structures”) are alternately arranged in the X direction and apart from each other in a region between the interconnect LBI and the source line SL, for example. In such a case, the conductive pillar CGP may be shared by the first structure and the second structure which are adjacent to each other in the X direction. The shared conductive pillar CGP can drive two memory cell transistors MT on the first structure side and the second structure side.

### 1.1.4.2 Three-Dimensional Structure of Memory Cell Array

A three-dimensional structure of the memory cell array 10 will be described. The three-dimensional structure of the memory cell array 10 has a structure in which the same planar layouts, one of which is shown in FIG. 3, are arranged apart from each other in the Z direction. That is, the plurality of the NAND string NS are arranged apart from each other in the Z direction.

### 1.1.4.3 Sectional Structure of Conductive Pillar CGP

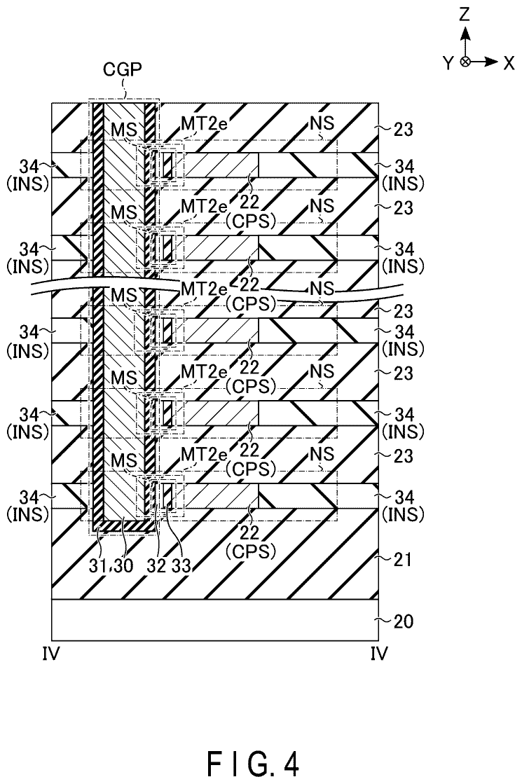

FIG. 4 is a cross-sectional view taken along line IV-IV of FIG. 3 and showing an example of a cross-sectional structure of the memory cell array 10.

As shown in FIG. 4, the memory cell array 10 includes a substrate 20, insulating layers 21 and 23, a semiconductor layer 22, an insulator 34, the conductive pillar CGP, and the memory structure MS.

The substrate 20 is, for example, a P-type semiconductor. The insulating layer 21 is provided on the upper surface of the substrate 20. The substrate 20 and the insulating layer 21 may also include circuits (not shown). The circuits included in the substrate 20 and the insulating layer 21 correspond to, for example, the row decoder module 15, the sense amplifier module 16, etc.

On the upper surface of the insulating layer 21, the plurality of semiconductor layers 22 and the plurality of insulating layers 23 are alternately stacked one by one. In the example shown in FIG. 4, five semiconductor layers 22 and five insulating layers 23 are alternately stacked one by one. In other words, the plurality of semiconductor layers 22 stacked with a space therebetween in the Z direction are provided above the substrate 20. The number of stacked semiconductor layers 22 corresponds to the number of bit lines BL coupled to one interconnect LBI.

Each of the semiconductor layers 22 corresponds to the semiconductor CPS and has a portion extending in the Y direction. The portion extending in the Y direction of the semiconductor layer 22 (that is, the portion shown in FIG. 4) functions as a channel of the NAND string NS. The insulating layers 21 and 23 include, for example, silicon oxide. The semiconductor layer 22 includes, for example, polysilicon.

The insulator 34 corresponds to the insulator INS and has a portion extending along the XY plane in the same layer as the semiconductor layer 22.

The conductive pillar CGP extends in the Z direction so as to intersect the plurality of semiconductor layers 22 and insulating layers 23. For example, the lower end of the conductive pillar CGP reaches the insulating layer 21. The upper end of the conductive pillar CGP is flush with the upper end of the uppermost insulating layer 23. The conductive pillar CGP is electrically coupled to the row decoder module 15 via a conductor (not shown) provided on the upper side, thereby functioning as the word line WL.

The memory structure MS is provided on the same layer as the semiconductor layer 22.

In the same layer as the semiconductor layer 22, a portion of the side surface of the conductive pillar CGP is in contact with the insulator 34. Of the side surface of the conductive pillar CGP in the same layer as the semiconductor layer 22, a portion not in contact with the insulator 34 is in contact with the memory structure MS.

The conductive film 30 of the conductive pillar CGP extends in the Z direction. For example, the lower end of the conductive film 30 is included in the layer lower than the lowermost semiconductor layer 22. The upper end of the conductive film 30 is flush with the upper end of the uppermost insulating layer 23. The insulating film 31 of the conductive pillar CGP covers the periphery of the portion excluding the upper surface of the conductive film 30.

The charge storage film 32 of the memory structure MS covers a portion of the side surface of the insulating film 31 in the same layer as the semiconductor layer 22. The insulating film 33 of the memory structure MS covers a portion of the side surface of the charge storage film 32 in the same layer as the semiconductor layer 22. The insulating layer 33 is in contact with the semiconductor layer 22.

### 1.1.4.4 Sectional Structure of Conductive Pillar SGP

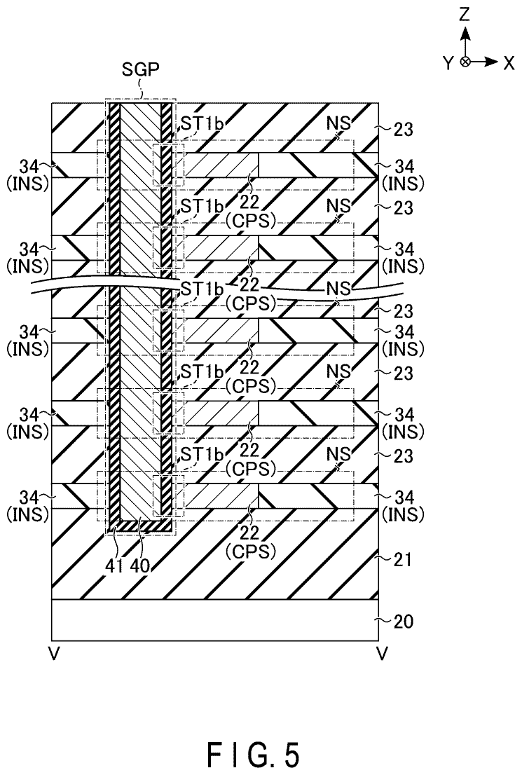

FIG. 5 is a cross-sectional view taken along line V-V of FIG. 3 and showing an example of a cross-sectional structure of the memory cell array 10.

As shown in FIG. 5, the memory cell array 10 further includes a conductive pillar SGP. Since structures other than the conductive pillar SGP are the same as those shown in FIG. 4, the description thereof will be omitted.

The conductive pillar SGP extends in the Z direction so as to intersect the plurality of semiconductor layers 22 and insulating layers 23. For example, the lower end of the conductive pillar SGP reaches the insulating layer 21. The upper end of the conductive pillar SGP is flush with the upper end of the uppermost insulating layer 23. The conductive pillar SGP is electrically coupled to the row decoder module 15 via a conductor (not shown) provided on the upper side, thereby functioning as the select gate decode line SGD.

In the same layer as the semiconductor layer 22, a portion of the side surface of the conductive pillar SGP is in contact with the insulator 34. Of the side surface of the conductive pillar SGP in the same layer as the semiconductor layer 22, a portion not in contact with the insulator 34 is in contact with the semiconductor layer 22.

The conductive film 40 of the conductive pillar SGP extends in the Z direction. For example, the lower end of the conductive film 40 is included in the layer lower than the lowermost semiconductor layer 22. The upper end of the conductive film 40 is flush with the upper end of the uppermost insulating layer 23. The insulating film 41 of the conductive pillar SGP covers the periphery of the portion excluding the upper surface of the conductive film 40.

### 1.1.4.5 Sectional-Structure of Conductive Pillar TRP

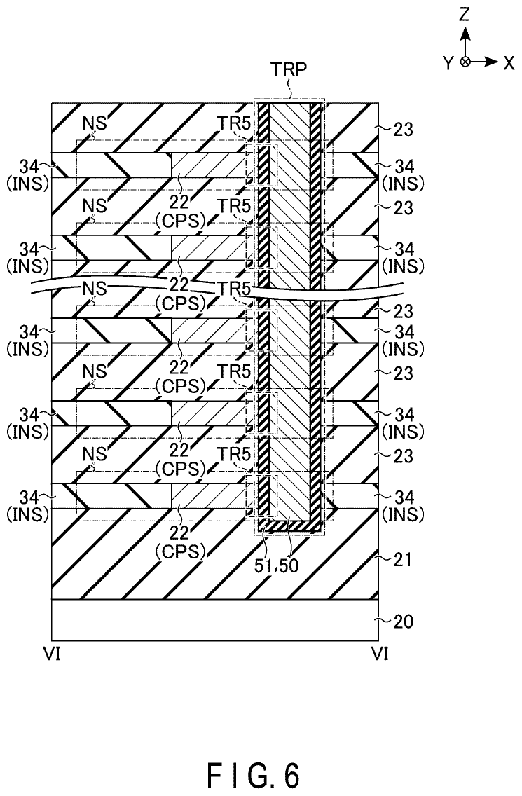

FIG. 6 is a cross-sectional view taken along line VI-VI of FIG. 3 and showing an example of a cross-sectional structure of the memory cell array 10.

As shown in FIG. 6, the memory cell array 10 further includes a conductive pillar TRP. Since structures other than the conductive pillar TRP are the same as those shown in FIG. 4, the description thereof will be omitted.

The conductive pillar TRP extends in the Z direction so as to intersect the plurality of semiconductor layers 22 and insulating layers 23. For example, the lower end of the conductive pillar TRP reaches the insulating layer 21. The upper end of the conductive pillar TRP is flush with the upper end of the uppermost insulating layer 23. The conductive pillar TRP is electrically coupled to the row decoder module 15 via a conductor (not shown) provided on the upper side, thereby functioning as the word line WL.

In the same layer as the semiconductor layer 22, a portion of the side surface of the conductive pillar TRP is in contact with the insulator 34. Of the side surface of the conductive pillar TRP in the same layer as the semiconductor layer 22, a portion not in contact with the insulator 34 is in contact with the semiconductor layer 22.

The conductive film 50 of the conductive pillar TRP extends in the Z direction. For example, the lower end of the conductive film 50 is included in the layer lower than the lowermost semiconductor layer 22. The upper end of the conductive film 50 is flush with the upper end of the uppermost insulating layer 23. The insulating film 51 of the conductive pillar TRP covers the periphery of the portion excluding the upper surface of the conductive film 50.

### 1.1.4.6 Sectional-Structure of Contact Plug BC

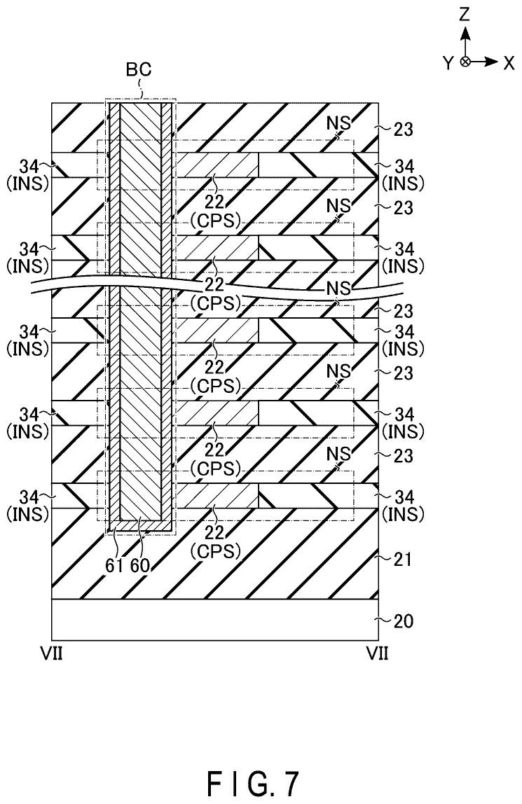

FIG. 7 is a cross-sectional view taken along line VII-VII of FIG. 3 and showing an example of a cross-sectional structure of the memory cell array 10.

As shown in FIG. 7, the memory cell array 10 further includes the contact plug BC. Since structures other than the contact plug BC are the same as those shown in FIG. 4, the description thereof will be omitted.

The contact plug BC extends in the Z direction so as to intersect the plurality of semiconductor layers 22 and insulating layers 23. For example, the lower end of the contact plug BC reaches the insulating layer 21. The upper end of the contact plug BC is flush with the upper end of the uppermost insulating layer 23. The contact plug BC functions as a contact plug for supplying a voltage to the conductor film 60 via a conductor (not shown) provided on the upper side.

In the same layer as the semiconductor layer 22, a portion of the side surface of the contact plug BC is in contact with the insulator 34. Of the side surface of the contact plug BC in the same layer as the semiconductor layer 22, a portion not in contact with the insulator 34 is in contact with the semiconductor layer 22.

The conductive film 60 of the contact plug BC extends in the Z direction. For example, the lower end of the conductive film 60 is included in the layer lower than the lowermost semiconductor layer 22. The upper end of the conductive film 60 is flush with the upper end of the uppermost insulating layer 23. The semiconductor film 61 of the contact plug BC covers the periphery of the portion excluding the upper surface of the conductive film 60.

### 1.2 Write Operation

First, an overview of a write operation will be described.

The write operation includes a program operation and a verify operation. A threshold value of the memory cell transistor MT is increased up to a target level by repeating a program loop including the program operation and the verify operation.

The program operation refers to an operation of injecting electrons into the charge storage film to increase a threshold voltage (or inhibiting the injection to maintain a threshold voltage). In the following description, an operation of increasing a threshold voltage will be referred to as a “program ‘0’”. The bit line BL which is subject to the program “0” is provided with a voltage (for example, a voltage VSS) for the program “0 ” by the sense amplifier module 16. On the other hand, an operation of maintaining a threshold voltage will be referred to as a “program ‘1’” or “write inhibit”. The bit line BL which is subject to the program “1” is provided with a voltage for the program “1” by the sense amplifier module 16.

The verify operation is an operation of reading data after the program operation, thereby determining whether or not a threshold voltage of the memory cell transistor MT has reached a target level. After a threshold voltage of a memory cell transistor MT reaches a target level, writing data to the memory cell transistor MT concerned is inhibited.

Next, the write operation of the semiconductor memory device 3 according to the first embodiment will be described. The write operation of the semiconductor memory device 3 according to the present embodiment includes a write operation (hereinafter referred to as a “first write operation”) with respect to the memory string.

For example, in a case where the memory controller 2 receives a write request from the host, the write operation is initiated, so that the memory controller 2 instructs the semiconductor memory device 3 to execute the first write operation.

Next, the sequencer 13 executes the first write operation on the basis of an instruction received from the memory controller 2. More specifically, in the selected block BLK, the program loop is repeated with respect to the memory cell transistors MT corresponding to the conductive pillars CGP respectively functioning as selected word lines WL within all of the first strings NSa within the string unit SU corresponding to the select gate decode line SGDa. Hereinafter, the conductive pillar CGP that functions as the selected word line WL will also be referred to as a “selected CG pillar CGPsel”. The conductive pillar CGP that functions as a non-selected word line WL will also be referred to as a “non-selected CG pillar CGPusel”.

In the program operation of the first write operation, in the selected string unit SU, a voltage VPGMe is applied to the conductive films 30 of the selected CG pillars CGPsel within all of the first strings NSa. The voltage VPGMe is a high voltage that can increase a threshold voltage of the memory cell transistor MT. For example, the voltages VPGMe are stepped up in response to the program loop being repeated.

In this state, the sense amplifier module 16 applies, for example, the voltage VSS to the bit line BL which is subjected to the program “0”, and applies, for example, a power supply voltage VCC to the bit line BL which is subjected to the program “1”. That is, the voltage VSS or the voltage VCC is applied to an interconnect BLI via the bit line BL.

Then, in the selected string unit SU, data is written to the memory cell transistors MT corresponding to the selected CG pillars CGPsel within all of the first strings NSa coupled to the bit line BL which is subjected to the program “0”. On the other hand, data in the memory cell transistors MT corresponding to the selected CG pillars CGPsel within all the first strings NSa coupled to the bit line BL which is subjected to the program “1” is maintained.

After the execution of the program operation, the verify operation is executed. The program loop is subsequently repeated in a similar manner. In the selected string unit SU, in a case where writing data to the memory cell transistors MT corresponding to the selected CG pillars CGPsel within all the first strings NSa is inhibited, the program loop is terminated with respect to the memory cell transistors MT corresponding to the selected CG pillars CGPsel.

For example, in the first string NSa, the conductive pillars CGP0e to CGP7e are selected in the order of the conductive pillars CGP7e, CGP6e, . . ., CGP1e, and CGP0e. Upon completion of the program loop with respect to each of the conductive pillars CGP, the first write operation is completed. In this manner, write data is written to the first string NSa. Upon completion of the first write operation, the write operation is completed.

### 1.3. Read Operation

The read operation of the semiconductor memory device 3 according to the first embodiment will be described. The read operation of the semiconductor memory device 3 according to the present embodiment includes the first read operation. In the first read operation, a cell current is not caused to flow through the memory cell transistor MT corresponding to the non-selected CG pillar CGPusel and the transistor TR corresponding to the conductive pillar TRP positioned in the vicinity of the selected CG pillar CGPsel, and is caused to flow through the transistor TR corresponding to the conductive pillar TRP not positioned in the vicinity of the selected CG pillar CGPsel.

For example, in a case where the memory controller 2 receives a read request from the host, the read operation is initiated, so that the memory controller 2 instructs the semiconductor memory device 3 to execute the first read operation.

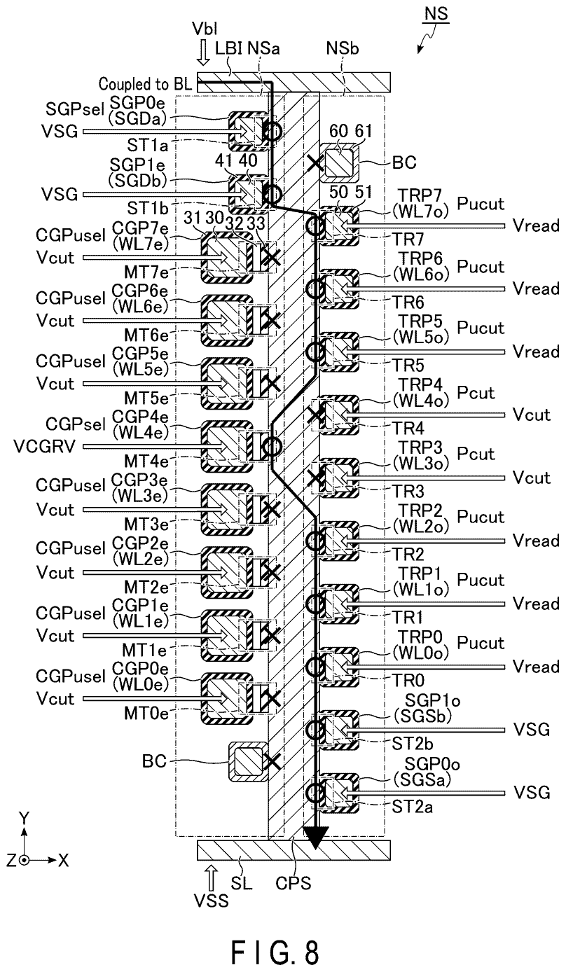

Next, the sequencer 13 executes the first read operation on the basis of an instruction received from the memory controller 2. FIG. 8 is a view showing voltages of respective interconnects in the first read operation. FIG. 8 shows the example in which in the selected block BLK, the plurality of memory cell transistors MT4e within the selected string unit SU are selected as a read target, and the memory cell transistor MT4e within one NAND string NS is turned to an ON state.

As shown in FIG. 8, in the first read operation, a voltage described below is applied by the row decoder module 15 to each of the conductive pillars SGP and CGP within the first string NSa.

For example, a voltage VSG is applied to each of the conductive films 40 of the conductive pillar SGP0e functioning as the selected gate decode line SGDa and the conductive pillar SGP1e functioning as the selected gate decode line SGDb. The voltage VSG is a voltage that turns the select transistor ST1 to the ON state regardless of the voltage of the corresponding bit line BL. Hereinafter, the conductive pillar SGP that functions as the selected gate line SGDa will also be referred to as a “selected SG pillar SGPsel”. For example, a voltage VCGRV is applied to the conductive film 30 of the conductive pillar CGP4e (selected CG pillar CGPsel) functioning as the word line WL4e (selected word line WL). The voltages VCGRV are a read voltage according to a threshold voltage level of read data. For example, a voltage Vcut is applied to each of the conductive films 30 of the conductive pillars CGP0e to CGP3e and CGP5e to CGP7e which respectively function as the word lines WL0e to WL3e and WL5e to WL7e (non-selected word lines WL). The voltage Vcut is a voltage that turns the memory cell transistor MT and the transistor TR to the cutoff state regardless of the threshold voltage. For example, the voltage Vcut may be a negative voltage.

Furthermore, in the first read operation, a voltage described below is applied by the row decoder module 15 to each of the conductive pillars SGP and TRP within the NAND string NSb.

For example, the voltage VSG is applied to each of the conductive films 40 of the conductive pillars SGP0o and SGP1o respectively functioning as the selected gate decode lines SGSa and SGSb. For example, the voltage Vcut is applied to each of the conductive films 50 of the conductive pillars TRP3 and TRP4 respectively functioning as the word lines WL3o and WL4o. The conductive pillars TRP3 and TRP4 are conductive pillars TRP positioned on the rear side of the semiconductor CPS and also in the vicinity of the selected CG pillar CGPsel. More specifically, the conductive pillars TRP3 and TRP4 are two conductive pillars TRP on the rear side of the semiconductor CPS which are positioned closest in a +Y direction and −Y direction to the position facing the selected CG pillar CGPsel on the front side of the semiconductor CPS in the X direction. Hereinafter, the conductive pillar which is positioned on the side opposite to the selected CG pillar CGPsel of the semiconductor CPS in the X direction and also in the vicinity of the selected CG pillar CGPsel will also be referred to as a “cutoff pillar Pcut”. For example, a voltage Vread is applied to each of the conductive films 50 of the conductive pillars TRP0 to TRP2 and TRP5 to TRP7 respectively functioning as the word lines WL0o to WL2o and WL5o to WL7o. The voltage Vread is a voltage that turns the transistor TR to the ON state regardless of the threshold voltage. The voltage Vread is a voltage higher than the voltage VCGRV. Hereinafter, the conductive pillar which is positioned on the side opposite to the selected CG pillar CGPsel of the semiconductor CPS in the X direction and also not positioned in the vicinity of the selected CG pillar CGPsel will also be referred to as a “non-cutoff pillar Pucut”.

In this state, the sense amplifier module 16 applies the voltage Vbl to the bit line BL which is set to a read target. That is, the voltage Vb1 is applied to the interconnect BLI via the bit line BL. The voltage VSS is applied to the source line SL. The voltage Vbl is a voltage higher than the voltage VSS.

In the semiconductor CPS, a conductive region, that is, a channel region, is formed in the vicinity of a portion in contact with each of the conductive pillars SGP (conductive pillars SGP0e, SGP1e, SGP0o, and SGP1o) to which the voltage VSG has been applied. The conductive region is not formed in the vicinity of a portion in contact with each of the conductive pillars CGP and TRP (conductive pillars CGP0e to CGP3e, CGP5e to CGP7e, TRP3, and TRP4) to which the voltage Vcut has been applied. The conductive region is formed in the vicinity of a portion in contact with each of the conductive pillars TRP (conductive pillars TRP0 to TRP2 and TRP5 to TRP7) to which the voltage Vread has been applied. In the vicinity of a portion in contact with the conductive pillar CGP (conductive pillar CGP4e) to which the voltage VCGRV has been applied, in a case where the selected memory cell transistor MT4e is in the ON state, the conductive region is formed. On the other hand, in a case where the selected memory cell transistor MT4e is in the OFF state, the conductive region is not formed.

Furthermore, since the semiconductor CPS (the distance in the X direction) is relatively small in width, in the semiconductor CPS, the conductive region is also formed between the conductive region formed in the vicinity of the conductive pillar SGP1e and the conductive region formed in the vicinity of the conductive pillar TRP7. In a case where the selected memory cell transistor MT4e is in the ON state, the conductive region is also formed between the conductive region formed in the vicinity of the conductive pillar TRP5 and the conductive region formed in the vicinity of the selected CG pillar CGPsel, and between the conductive region formed in the vicinity of the selected CG pillar CGPsel and the conductive region formed in the vicinity of the conductive pillar TRP2.

Since the semiconductor film 61 (for example, polysilicon including P-type impurities) of the contact plug BC is in contact with the semiconductor CPS, in the semiconductor CPS, the conductive region is not formed in the vicinity of the portion in contact with the contact plug BC.

Therefore, in a case where the selected memory cell transistor MT4e is in the ON state, as shown in FIG. 8, the interconnect LBI and the source line SL are electrically coupled via the conductive region of the semiconductor CPS. Thereby, an electron current flows from the interconnect LBI to the source line SL. On the other hand, in a case where the selected memory cell transistor MT4e is in the OFF state, the interconnect LBI and the source line SL are not electrically coupled. Thereby, in the selected string unit SU, data in the memory cell transistors MT corresponding to the selected CG pillars CGPsel within all the first strings NSa is read in a batch.

For example, in the first string NSa, the conductive pillars CGP0e to CGP7e are selected in order of the conductive pillars CGP7e, CGP6e, . . . , CGP1e, and CGP0e. Upon completion of the read with respect to each of the conductive pillars CGP, the first read operation is completed. As a result, the read operation is completed.

Meanwhile, in a case where the memory cell transistor MT7e is set to a read target, for example, the voltage VSG is applied to each of the conductive films 40 of the conductive pillars SGP0e, SGP1e, SGP0o, and SGP1o. For example, the voltage VCGRV is applied to the conductive film 30 of the conductive pillar CGP7e (selected CG pillar CGPsel). For example, the voltage Vcut is applied to each of the conductive films 30 of the conductive pillars CGP0e to CGP6e and each of the conductive films 50 of the conductive pillars TRP6 and TRP7. For example, the voltage Vread is applied to each of the conductive films 50 of the conductive pillars TRP0 to TRP5.

Furthermore, in a case where the memory cell transistor MT0e is set to a read target, for example, the voltage VSG is applied to each of the conductive films 40 of the conductive pillars SGP0e, SGP1e, SGP0o, and SGP1o. For example, the voltage VCGRV is applied to the conductive film 30 of the conductive pillar CGP0e (selected CG pillar CGPsel). For example, the voltage Vcut is applied to each of the conductive films 30 of the conductive pillars CGP1e CGP7e and the conductive film 50 of the conductive pillar TRP0. For example, the voltage Vread is applied to each of the conductive films 50 of the conductive pillars TRP1 to TRP7.

### 1.4 Advantageous Effects of Present Embodiment

In the read operation, in a case where the voltage Vread is applied to the non-selected word line WL coupled in series to the selected word line WL, read disturb may occur. In such a case, there is a possibility that the memory cell transistor MT corresponding to the non-selected word line WL may be decreased in cell tolerance.

On the other hand, the semiconductor memory device 3 according to the present embodiment includes the plurality of NAND strings arranged apart from each other in the Z direction. Each of the NAND strings NS includes the semiconductor CPS extending in the Y direction, the first string NSa arranged on the front side of the semiconductor CPS, and the second string NSb arranged on the rear side of the semiconductor CPS. The first string NSa includes the select transistors ST1a and St1b and the memory cell transistors MT0e to MT7e each using the semiconductor CPS as a channel and arranged apart from each other in the Y direction. The second string NSb includes the transistors TR0 to TR7 and the select transistors ST2a and ST2b each using the semiconductor CPS as a channel and arranged apart from each other in the Y direction.

As described above, in each of the NAND strings NS of the semiconductor memory device 3 according to the present embodiment, the first string NSa and the second string NSb are arranged with the semiconductor CPS intervening therebetween, the first string NSa is set to the memory string, and the second string NSb is set to the read string.

The above configuration enables, as described with reference to FIG. 8, in the read operation, a cell current to flow through the memory cell transistor MT corresponding to the selected CG pillar CGPsel without causing a cell current to flow through the memory cell transistor MT corresponding to the non-selected CG pillar CGPusel in the first string NSa. Furthermore, the above configuration enables, in the second string NSb, a cell current to flow through the memory cell transistor MT corresponding to the non-cutoff pillar Pucut without causing a cell current to flow through the memory cell transistor MT corresponding to the cutoff pillar Pcut. As a result, a cell current does not flow through the memory cell transistor MT corresponding to the non-selected CGPusel. Therefore, the semiconductor memory device 3 according to the present embodiment can realize a memory cell with a high read tolerance.

Furthermore, since a cell current does not flow through the memory cell transistors MT corresponding to two cutoff pillars Pcut respectively positioned on the rear side of the semiconductor CPS and also in the vicinity of the selected CG pillar CGPsel, data in the memory cell transistor MT corresponding to the selected CG pillar CGPsel can be read as appropriate.

The transistor TR with higher performance than that of the memory cell transistor MT is arranged in the second string NSb, so that a cell current can be obtained easily.

Furthermore, in a case where the configuration of the conductive pillar TRP within the second string NSb is set to the same as that of the conductive pillar SGP, in the manufacturing steps, the conductive pillars TRP and SGP can be simultaneously formed.

### 1.5 Modification

A semiconductor memory device 3A according to a modification of the first embodiment will be described. The semiconductor memory device 3A according to the present modification differs from that of the first embodiment in terms of a circuit configuration of a memory cell array 10A, a planar layout of the memory cell array 10A, and the read operation. Hereinafter, the following description will in principle concentrate on the features different from the first embodiment.

### 1.5.1 Circuit Configuration of Memory Cell Array

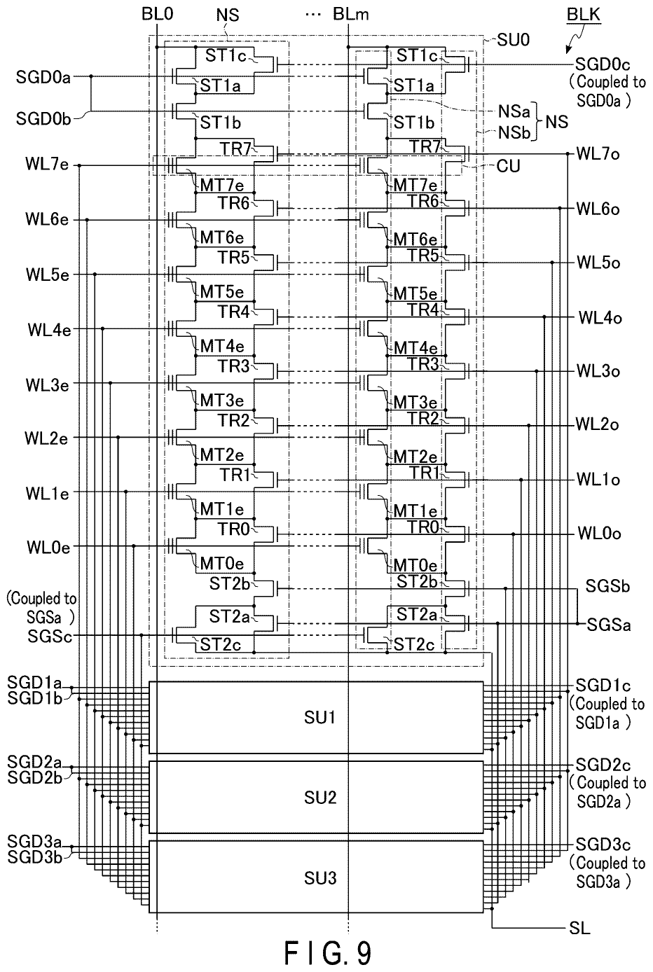

The circuit configuration of the memory cell array 10A will be described with reference to FIG. 9. FIG. 9 is a circuit diagram showing an example of the circuit configuration of the memory cell array 10A. FIG. 9 shows a circuit configuration of the block BLK included in the memory cell array 10A, as an example of the circuit configuration of the memory cell array 10A. The other blocks BLK have a similar configuration to that shown in FIG. 9.

The first string NSa includes, for example, the memory cell transistors MT0e to MT7e and select transistors ST1a, ST1b, and ST2c. The second string NSb includes, for example, the transistors TR0 to TR7 and select transistors ST2a, ST2b, and ST1c. The select transistors ST1c and ST2c are switching elements.

In the NAND strings NS, the memory cell transistors MT0e to MT7e are coupled in series. One end of the set of memory cell transistors MT0e to MT7e coupled in series (one end of the memory cell transistor MT7e) is coupled to the source of the select transistor ST1b. The drain of the select transistor ST1b is coupled to the source of the select transistor ST1a. The drain of the select transistor ST1a is coupled to the bit line BL associated therewith. A source of the select transistor ST1c is coupled to the drain of the select transistor ST1b. A drain of the select transistor ST1c is coupled to the bit line BL associated therewith. The other end of the set of memory cell transistors MT0e to MT7e coupled in series (the other end of the memory cell transistor MT0e) is coupled to the drain of the select transistor ST2b. The transistors TR0 to TR7 are coupled in series. One end of the set of transistors TR0 to TR7 coupled in series (one end of the transistor TR7) is coupled to the source of the select transistor ST1b. The other end of the set of transistors TR0 to TR7 coupled in series (the other end of the transistor TR0) is coupled to the drain of the select transistor ST2b. The source of the select transistor ST2b is coupled to the drain of the select transistor ST2a. The source of the select transistor ST2a is coupled to the source line SL. A drain of the select transistor ST2c is coupled to the drain of the select transistor ST2a. A source of the select transistor ST2c is coupled to the source line SL.

Furthermore, in each NAND string NS, one end of the memory cell transistor MT6e is coupled to one end of the transistor TR6. One end of the memory cell transistor MT5e is coupled to one end of the transistor TR5. One end of the memory cell transistor MT4e is coupled to one end of the transistor TR4. One end of the memory cell transistor MT3e is coupled to one end of the transistor TR3. One end of the memory cell transistor MT2e is coupled to one end of the transistor TR2. One end of the memory cell transistor MT1e is coupled to one end of the transistor TR1. One end of the memory cell transistor MT0e is coupled to one end of the transistor TR0.

Gates of the select transistors ST1c respectively included in the string units SU0 to SU3 in the same block BLK are respectively coupled to select gate decode lines SGD0c to SGD3c. Furthermore, the select gate decode line SGD0c is coupled to the select gate decode line SGD0a. The select gate decode line SGD1c is coupled to the select gate decode line SGD1a. The select gate decode line SGD2c is coupled to the select gate decode line SGD2a. The select gate decode line SGD3c is coupled to the select gate decode line SGD3a. Hereinafter, in a case where the select gate decode lines SGD0c to SGD3c are not distinguished from each other, they will be simply referred to as a “select gate decode line SGDc”. Gates of the select transistors ST2c in the same block BLK are coupled to a select gate decode line SGSc. Furthermore, the select gate decode line SGSc is coupled to the select gate decode line SGSa.

In addition, the circuit configuration of the memory cell array 10A is not limited to the configuration described above. For example, the number of string units SU in each block BLK and the number of memory cell transistors MT, transistors TR, and select transistors ST1 and ST2 in each NAND string NS may be set freely.

### 1.5.2 Planar Layout of Memory Cell Array

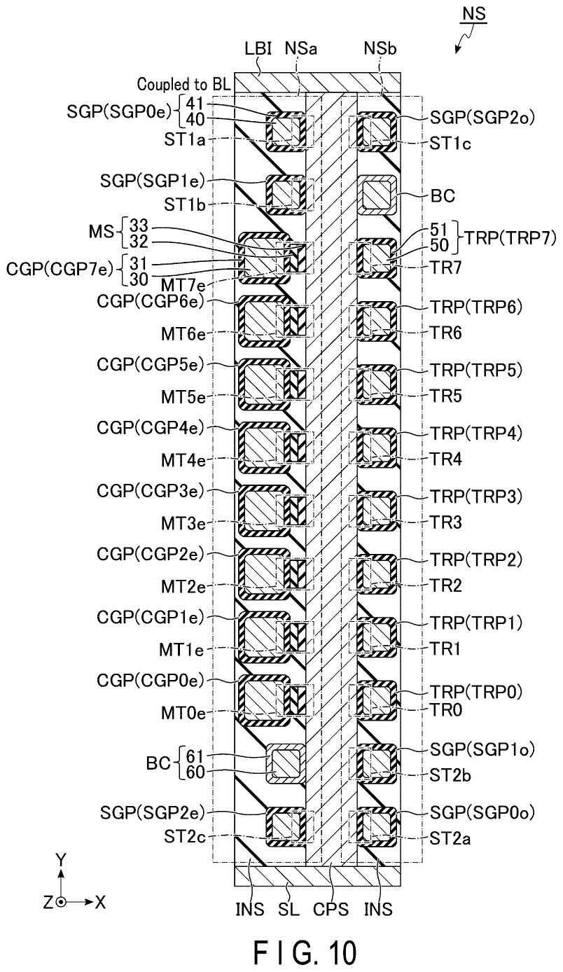

FIG. 10 is a plan view showing an example of a planar layout of the memory cell array 10A. FIG. 10 shows a planar view of a layer substantially equal in height from the substrate in the block BLK. A portion shown in FIG. 10 corresponds to one NAND string NS in the circuit diagram shown in FIG. 9.

As shown in FIG. 10, in the same layer, the memory cell array 10A includes the semiconductor CPS, the interconnect LBI, the source line SL, the plurality of insulators INS, the plurality of conductive pillars CGP, SGP, and TRP, the plurality of memory structures MS, and the plurality of contact plugs BC.

A planar layout of the semiconductor CPS, the interconnect LBI, the source line SL, and the insulator INS is similar to that shown in FIG. 3 described in the first embodiment.

On the front side of the semiconductor CPS, the first string NSa is arranged. In the first string NSa, for example, two conductive pillars SGP, eight conductive pillars CGP, one contact plug BC, and one conductive pillar SGP are arranged in this order from the upper side of the drawing sheet in the Y direction. Two conductive pillars SGP, eight conductive pillars CGP, one contact plug BC, and one conductive pillar SGP are spaced apart from each other in the Y direction. Hereinafter, three conductive pillars SGP will also be referred to as “conductive pillars SGP0e, SGP1e, SGP2e”, respectively, in order from the upper side of the drawing sheet.

On the rear side of the semiconductor CPS, the second string NSb is arranged. In the second string NSb, for example, one conductive pillar SGP, one contact plug BC, eight conductive pillars TRP, and two conductive pillars SGP are arranged in this order from the upper side of the drawing sheet in the Y direction. One conductive pillar SGP, one contact plug BC, eight conductive pillars TRP, and two conductive pillars SGP are spaced apart from each other in the Y direction. Hereinafter, three conductive pillars SGP will also be referred to as “conductive pillars SGP0o, SGP1o, and SGP2o”, respectively, in order from the lower side of the drawing sheet.

When viewed from the upper surface, two conductive pillars SGP, eight conductive pillars CGP, one contact plug BC, and one conductive pillar SCP on the front side of the semiconductor CPS each face, in the X direction, one conductive pillar SGP, eight conductive pillar TRP, one contact plug BC, and two conductive pillars SCP on the rear side of the semiconductor CPS.

On the front side of the semiconductor CPS, the conductive pillar SGP2e has a similar structure to those of the other conductive pillars SGP. Structures of two conductive pillars SGP other than the conductive pillar SGP2e, eight conductive pillars CGP, and one contact plug BC are similar to those shown in FIG. 3 described in the first embodiment. The above-mentioned structure including the semiconductor CPS and a set of three conductive pillars SGP, eight conductive pillars CGP, eight memory structures MS, and one contact plug BC on the front side of the semiconductor CPS corresponds to the first string NSa.

On the rear side of the semiconductor CPS, the conductive pillar SGP2o has a similar structure to those of the other conductive pillars SGP. Structures of two conductive pillars SGP other than the conductive pillar SGP2o, eight conductive pillars TRP, and one contact plug BC are similar to those shown in FIG. 3 described in the first embodiment. The above-mentioned structure including the semiconductor CPS and a set of three conductive pillars SGP, eight conductive pillars TRP, and one contact plug BC on the rear side of the semiconductor CPS corresponds to the second string NSb.

The plurality of NAND strings NS coupled to the same bit line BL are arranged as in the first embodiment, for example.

### 1.5.3 Three-Dimensional Structure of Memory Cell Array

A three-dimensional structure of the memory cell array 10A will be described. The three-dimensional structure of the memory cell array 10A has a structure in which the same planar layouts, one of which is shown in FIG. 10, are arranged apart from each other in the Z direction. That is, the plurality of the NAND strings NS are arranged apart from each other in the Z direction.

### 1.5.4 Write Operation

The write operation of the semiconductor memory device 3A according to the modification of the first embodiment is the same as that of the first embodiment.

### 1.5.5 Read Operation

The read operation of the semiconductor memory device 3A according to the modification of the first embodiment will be described. The read operation of the semiconductor memory device 3A according to the modification of the present embodiment includes the first read operation.

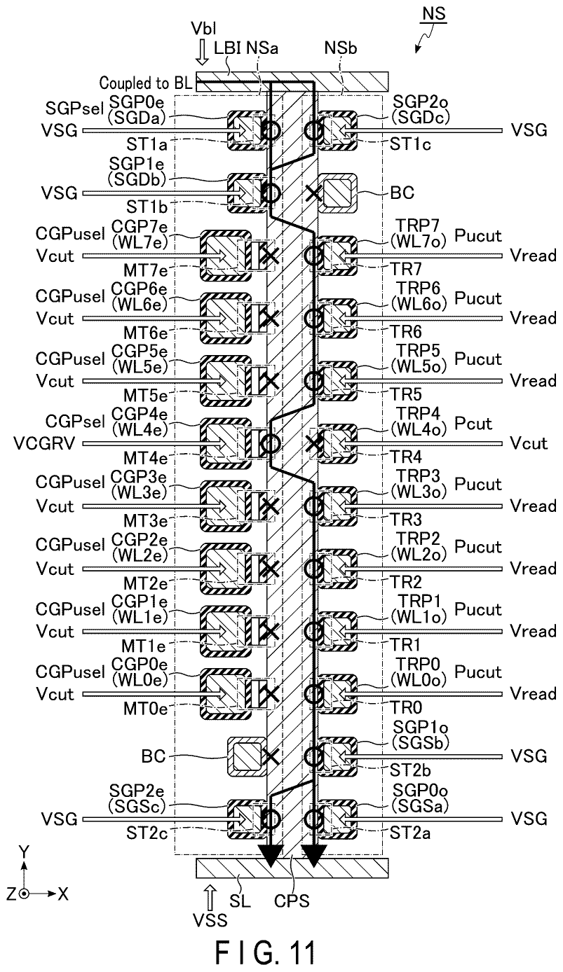

FIG. 11 is a view showing voltages of respective interconnects in the first read operation. FIG. 11 shows the example in which in the selected block BLK, the plurality of memory cell transistors MT4e within the selected string unit SU are selected as a read target, and the memory cell transistor MT4e within one NAND string NS is turned to an ON state.

As shown in FIG. 11, in the first read operation, a voltage described below is applied to each of the conductive pillars SGP and CGP within the first string NSa.

For example, the voltage VSG is applied to each of the conductive films 40 of the conductive pillars SGP0e, SGP1e, and SGP2e respectively functioning as the selected gate decode lines SGDa, SGDb, and SGSc. For example, the voltage VCGRV is applied to the conductive film 30 of the conductive pillar CGP4e. For example, the voltage Vcut is applied to each of the conductive films 30 of the conductive pillars CGP0e to CGP3e and CGP5e to CGP7e.

Furthermore, in the first read operation, a voltage described below is applied to each of the conductive pillars SGP and TRP within the NAND string NSb.

For example, the voltage VSG is applied to each of the conductive films 40 of the conductive pillars SGP0o, SGP1o, and SGP2o respectively functioning as the selected gate decode lines SGSa, SGSb, and SGDc. For example, the voltage Vcut is applied to the conductive film 50 of the conductive pillar TRP4. The conductive pillar TRP4 is a conductive pillar TRP positioned on the rear side of the semiconductor CPS and also in the vicinity of the selected CG pillar CGPsel. More specifically, the conductive pillar TRP4 is a conductive pillar TRP located on the rear side of the semiconductor CPS and in a position facing the selected CG pillar CGPsel on the front side of the semiconductor CPS in the X direction. For example, the voltage Vread is applied to each of the conductive films 50 of the conductive pillars TRP0 to TRP3 and TRP5 to TRP7.

In this state, the voltage Vbl is applied to the bit line BL which is set to a read target and the voltage VSS is applied to the source line SL.

In the semiconductor CPS, the conductive region is formed in the vicinity of a portion in contact with each of the conductive pillars SGP0e, SGP1e, SGP2e, SGP0o, SGP1o, and SGP2o. The conductive region is not formed in the vicinity of a portion in contact with each of the conductive pillars CGP0e to CGP3e, CGP5e to CGP7e, and TRP4. The conductive region is formed in the vicinity of a portion in contact with each of the conductive pillars TRP0 to TRP3 and TRP5 to TRP7. In the vicinity of the portion in contact with each conductive pillar CGP4e, in a case where the selected memory cell transistor MT4e is in the ON state, the conductive region is formed. On the other hand, in a case where the selected memory cell transistor MT4e is in the OFF state, the conductive region is not formed.

Furthermore, since the semiconductor CPS is relatively small in width, in the semiconductor CPS, the conductive region is also formed between the conductive region formed in the vicinity of the conductive pillar SGP2o and the conductive region formed in the vicinity of the conductive pillar SGP1e, between the conductive region formed in the vicinity of the conductive pillar SGP1e and the conductive region formed in the vicinity of the conductive pillar TRP7, and between the conductive region formed in the vicinity of the conductive pillar SGP1o and the conductive region formed in the vicinity of the conductive pillar SGP2e. In a case where the selected memory cell transistor MT4e is in the ON state, the conductive region is also formed between the conductive region formed in the vicinity of the conductive pillar TRP5 and the conductive region formed in the vicinity of the selected CG pillar CGPsel, and between the conductive region formed in the vicinity of the selected CG pillar CGPsel and the conductive region formed in the vicinity of the conductive pillar TRP3.

In the semiconductor CPS, the conductive region is not formed in the vicinity of a portion in contact with the contact plug BC.

Therefore, in a case where the selected memory cell transistor MT4e is in the ON state, as shown in FIG. 11, the interconnect LBI and the source line SL are electrically coupled so that an electron current flows from the interconnect LBI to the source line SL. On the other hand, in a case where the selected memory cell transistor MT4e is in the OFF state, the interconnect LBI and the source line SL are not electrically coupled.

Meanwhile, in a case where the memory cell transistor MT7e is set to a read target, for example, the voltage VSG is applied to each of the conductive films 40 of the conductive pillars SGP0e, SGP1e, SGP2e, SGP0o, SGP1o, and SGP2o. For example, the voltage VCGRV is applied to the conductive film 30 of the conductive pillar CGP7e (selected CG pillar CGPsel). For example, the voltage Vcut is applied to each of the conductive films 30 of the conductive pillars CGP0e CGP6e and the conductive film 50 of the conductive pillar TRP7. For example, the voltage Vread is applied to each of the conductive films 50 of the conductive pillars TRP0 to TRP6.

Furthermore, in a case where the memory cell transistor MT0e is set to a read target, for example, the voltage VSG is applied to each of the conductive films 40 of the conductive pillars SGP0e, SGP1e, SGP2e, SGP0o, SGP1o, and SGP2o. For example, the voltage VCGRV is applied to the conductive film 30 of the conductive pillar CGP0e (selected CG pillar CGPsel). For example, the voltage Vcut is applied to each of the conductive films 30 of the conductive pillars CGP1e CGP7e and the conductive film 50 of the conductive pillar TRP0. For example, the voltage Vread is applied to each of the conductive films 50 of the conductive pillars TRP1 to TRP7.

### 1.5.6 Advantageous Effects of Present Modification

The present modification produces advantageous effects similar to those of the first embodiment.

Furthermore, as described with reference to FIG. 11, in the read operation, the conductive region is formed between the conductive region formed in the vicinity of the conductive pillar SGP2o and the conductive region formed in the vicinity of the conductive pillar SGP1e in the semiconductor CPS, so that a cell current can be increased.

### 2. Second Embodiment

A semiconductor memory device 3B according to a second embodiment will be described. The semiconductor memory device 3B according to the second embodiment differs from that of the first embodiment in terms of a circuit configuration of the second string NSb, a planar layout of the second string NSb, and the write operation. Hereinafter, the following description will in principle concentrate on the features different from the first embodiment.

### 2.1 Circuit Configuration of Memory Cell Array

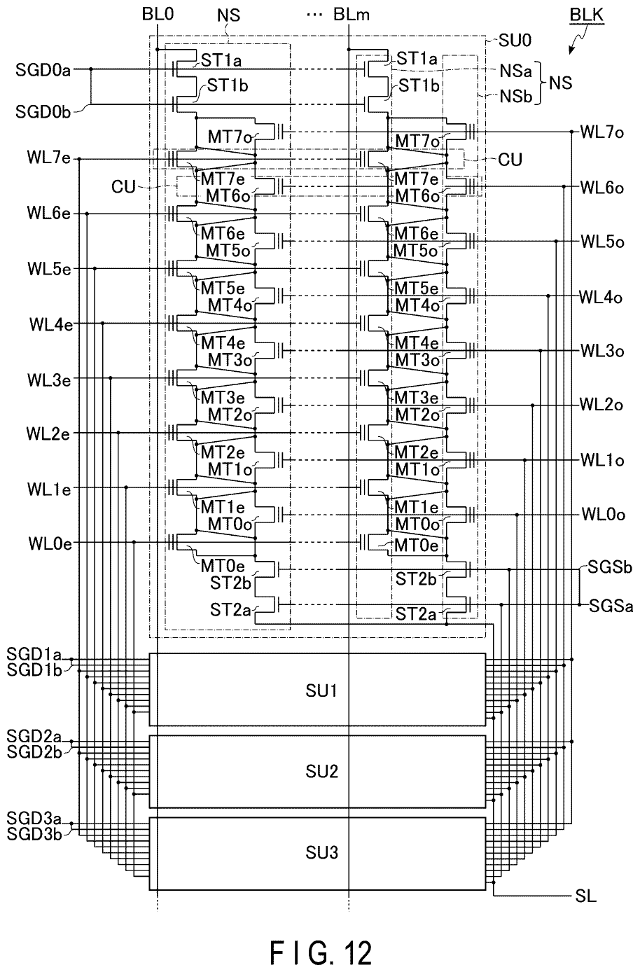

The circuit configuration of the memory cell array 10B will be described with reference to FIG. 12. FIG. 12 is a circuit diagram showing an example of the circuit configuration of the memory cell array 10B. FIG. 12 shows a circuit configuration of the block BLK included in the memory cell array 10B, as an example of the circuit configuration of the memory cell array 10B. The other blocks BLK have a similar configuration to that shown in FIG. 12.

As shown in FIG. 12, the circuit configuration of the memory cell array 10B is similar to that shown in FIG. 2 described in the first embodiment except that the transistors TR0 to TR7 within the second string NSb shown in FIG. 2 are replaced with memory cell transistors MT0o to MT7o. A configuration of the memory cell transistors MT0o to MT7o is similar to that of the memory cell transistors MT0e to MT7e. The first string NSa is the memory string and the second string NSb is the read string.

### 2.2 Planar Layout of Memory Cell Array

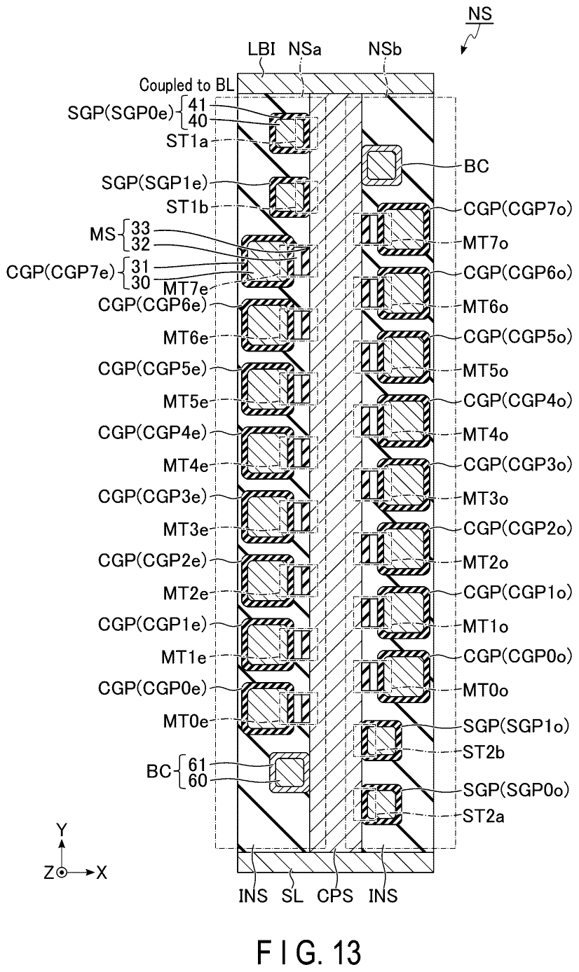

FIG. 13 is a plan view showing an example of a planar layout of the memory cell array 10B. FIG. 13 shows a planar view of a layer substantially equal in height from the substrate in the block BLK. A portion shown in FIG. 13 corresponds to one NAND string Ns in the circuit diagram shown in FIG. 12.

As shown in FIG. 13, a planar layout of the memory cell array 10B is similar to that shown in FIG. 3 described in the first embodiment except that eight conductive pillars TRP within the second string NSb are replaced with eight conductive pillars CGP and eight memory structures MS.

On the rear side of the semiconductor CPS, the second string NSb is arranged. In the second string NSb, for example, one contact plug BC, eight conductive pillars CGP, and two conductive pillars SGP are arranged in this order from the upper side of the drawing sheet in the Y direction. One contact plug BC, eight conductive pillars CGP, and two conductive pillars SGP are spaced apart from each other in the Y direction. Hereinafter, eight conductive pillars CGP will also be referred to as “conductive pillars CGP0o to CGP7o”, respectively, in order from the lower side of the drawing sheet.

On the rear side of the semiconductor CPS, the conductive pillar CGP and the memory structure MS have similar structures to those of the conductive pillar CGP and the memory structure MS on the front side of the semiconductor CPS. The above-mentioned structure including one conductive pillar CGP, one memory structure MS, and the semiconductor CPS functions as a memory cell transistor MT. FIG. 13 shows eight of the above-mentioned structures which respectively function as the memory cell transistors MT7o, MT6o, MT5o, MT4o, MT3o, MT2o, MT1o, and MT0o, in this order from the upper side of the drawing sheet. The above-mentioned structure including the semiconductor CPS and a set of three conductive pillars SGP, eight conductive pillars CGP, eight memory structures MS, and one contact plug BC on the rear side of the semiconductor CPS corresponds to the second string NSb.

As described above, the second string NSb includes the memory cell transistors MT0o to MT7o and the select transistors ST2a and ST2b each using the semiconductor CPS as a channel and arranged apart from each other in the Y direction.

The plurality of NAND strings NS coupled to the same bit line BL are arranged as in the first embodiment, for example.

### 2.3 Three-Dimensional Structure of Memory Cell Array

A three-dimensional structure of the memory cell array 10B will be described. The three-dimensional structure of the memory cell array 10B has a structure in which the same planar layouts, one of which is shown in FIG. 13, are arranged apart from each other in the Z direction. That is, the plurality of the NAND strings NS are arranged apart from each other in the Z direction.

### 2.4 Write Operation

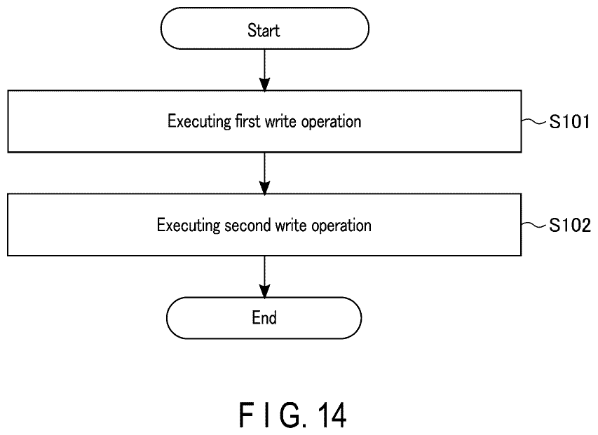

The write operation of the semiconductor memory device 3B according to the second embodiment will be described. The write operation of the semiconductor memory device 3B according to the present embodiment includes the first write operation and a write operation (hereinafter referred to as a “second write operation”) with respect to the read string. FIG. 14 is a flowchart showing an example of a write operation of the semiconductor memory device 3B according to the present embodiment.

For example, in a case where the write operation is initiated, the memory controller 2 instructs the semiconductor memory device 3B to execute the first write operation and the second write operation.

Next, the sequencer 13 executes the first write operation on the basis of an instruction received from the memory controller 2 (S101). That is, write data is written to the first string NSa.

Next, the sequencer 13 executes the second write operation on the basis of an instruction received from the memory controller 2 (S102). More specifically, in the selected block BLK, the program loop is repeated with respect to the memory cell transistors MT corresponding to the selected CG pillars CGPsel within all of the second strings NSb within the selected string unit SU.

In the program operation of the second write operation, in the selected string unit SU, a voltage VPGMo is applied to the conductive films 30 of the selected CG pillars CGPsel within all of the second strings NSb. The voltage VPGMo is a high voltage that can increase a threshold voltage of the memory cell transistor MT. For example, the voltage VPGMo is stepped up in response to the program loop being repeated.

In this state, for example, the voltage VSS is applied to the bit line BL which is subjected to the program “0”, and the voltage VCC is applied to, for example, the bit line BL which is subjected to the program “1”.

Then, in the selected string unit SU, data is written to the memory cell transistors MT corresponding to the selected CG pillars CGPsel within all the second strings NSb coupled to the bit line BL which is subjected to the program “0”. On the other hand, data in the memory cell transistors MT corresponding to the selected CG pillars CGPsel within all the second strings NSb coupled to the bit line BL which is subjected to the program “1” is maintained.

After the execution of the program operation, the verify operation is executed. The program loop is subsequently repeated in a similar manner to the first write operation.

For example, in the second string NSb, the conductive pillars CGP0o to CGP7o are selected in order of the conductive pillars CGP7o, CGP6o, . . . , CGP1o, and CGP0o. Upon completion of the program loop with respect to each of the conductive pillars CGP, the second write operation is completed. For example, data which is relatively resistant to read disturb or retention is written to the second string NSb. Such data is, for example, at a write level in the SLC or a level equivalent thereto. That is, predetermined data is written to the second string NSb. Upon completion of the second write operation, the write operation is completed.

Meanwhile, data written to the read string may be erased or may not be erased in the erase operation. In a case where such data is erased, the second write operation is executed again in the write operation after the erasure to write the data as described above, so that a data written state can be obtained. On the other hand, in a case where such data is not erased, the written data is maintained, so that writing of data can be prevented by executing no second write operation in the write operation after the erasure.

### 2.5 Write Operation

The read operation of the semiconductor memory device 3B according to the second embodiment will be described. The read operation of the semiconductor memory device 3B according to the present embodiment includes the first read operation. In the first read operation, a cell current is not caused to flow through the memory cell transistor MT corresponding to the non-selected CG pillar CGPusel and the memory cell transistor MT corresponding to the conductive pillar CGPo positioned in the vicinity of the selected CG pillar CGPsel, and is caused to flow through the memory cell transistor MT corresponding to the conductive pillar CGPo not positioned in the vicinity of the selected CG pillar CGPsel.

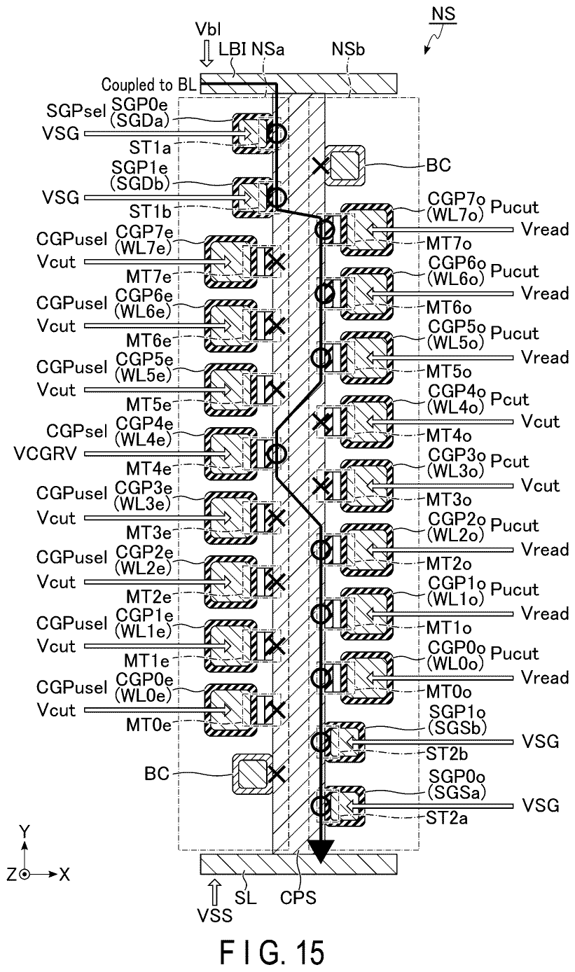

FIG. 15 is a view showing voltages of respective interconnects in the first read operation. FIG. 15 shows the example in which in the selected block BLK, the plurality of memory cell transistors MT4e within the selected string unit SU are selected as a read target, and the memory cell transistor MT4e within one NAND string NS is turned to the ON state.

As shown in FIG. 15, a voltage of each interconnect in the first read operation is similar to a voltage of each interconnect in the first read operation shown in FIG. 8 described in the first embodiment except that application of a voltage to eight conductive pillars TRP within the second string NSb shown in FIG. 8 is replaced with application of a voltage to eight conductive pillars CGP.

For example, the voltage Vcut is applied to each of the conductive films 30 of the conductive pillars CGP3o and CGP4o respectively functioning as the word lines WL3o and WL4o. The conductive pillars CGP3o and CGP4o are conductive pillars CGPo positioned on the rear side of the semiconductor CPS and also in the vicinity of the selected CG pillar CGPsel. More specifically, the conductive pillars CGP3o and CGP4o are two conductive pillars CGPo on the rear side of the semiconductor CPS which are positioned closest in a +Y direction and a −Y direction to the position facing the selected CG pillar CGPsel on the front side of the semiconductor CPS in the X direction. For example, the voltage Vread is applied to each of the conductive films 30 of the conductive pillars CGP0o to CGP2o and CGP5o to CGP7o respectively functioning as the word lines WL0o to WL2o and WL5o to WL7o. The voltage Vread is a voltage that turns the memory cell transistor MT to the ON state regardless of the threshold voltage. The voltage Vread is a voltage higher than the voltage VCGRV.

In the semiconductor CPS, the conductive region is formed as in the first embodiment. Therefore, in a case where the selected memory cell transistor MT4e is in the ON state, as shown in FIG. 15, the interconnect LBI and the source line SL are electrically coupled so that an electron current flows from the interconnect LBI to the source line SL. On the other hand, in a case where the selected memory cell transistor MT4e is in the OFF state, the interconnect LBI and the source line SL are not electrically coupled.

### 2.6 Advantageous Effects of Present Embodiment

The second embodiment produces advantageous effects similar to those of the first embodiment.

Furthermore, since the conductive pillar CGP in the first string NSa has the same structure as that of the conductive pillar CGP in the second string NSb, these conductive pillars CGP can be simultaneously formed.

Furthermore, data which is relatively resistant to read disturb or retention is written to the second string NSb, so that a memory cell with a high read tolerance can be realized.

### 2.7 Modification

A semiconductor memory device 3C according to a modification of the second embodiment will be described. The semiconductor memory device 3C according to the present modification differs from that of the second embodiment in terms of a circuit configuration of a memory cell array 10C, a planar layout of the memory cell array 10C, and the read operation. Hereinafter, the following description will in principle concentrate on the features different from the second embodiment.

### 2.7.1 Circuit Configuration of Memory Cell Array

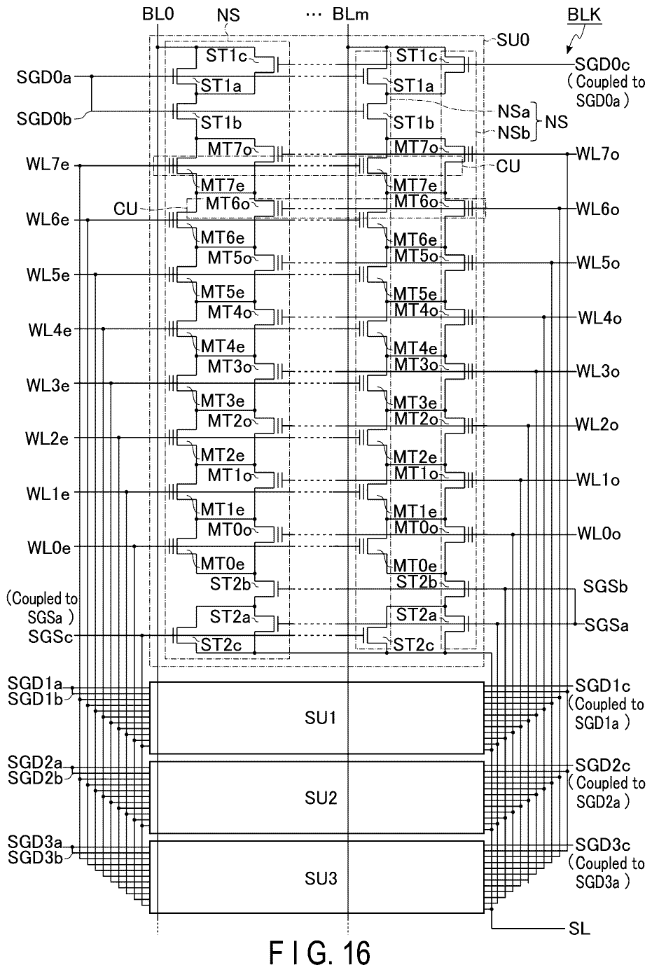

The circuit configuration of the memory cell array 10C will be described with reference to FIG. 16. FIG. 16 is a circuit diagram showing an example of the circuit configuration of the memory cell array 10C. FIG. 16 shows a circuit configuration of the block BLK included in the memory cell array 10C, as an example of the circuit configuration of the memory cell array 10C. The other blocks BLK have a similar configuration to that shown in FIG. 16.

As shown in FIG. 16, a circuit configuration of the memory cell array 10C is similar to that shown in FIG. 9 described in the modification of the first embodiment except that the transistors TR0 to TR7 within the second string NSb shown in FIG. 9 are replaced with the memory cell transistors MT0o to MT7o. A configuration of the memory cell transistors MT0o to MT7o is similar to that of the memory cell transistors MT0e to MT7e. The first string NSa is the memory string, and the second string NSb is the read string.

### 2.7.2 Planar Layout of Memory Cell Array

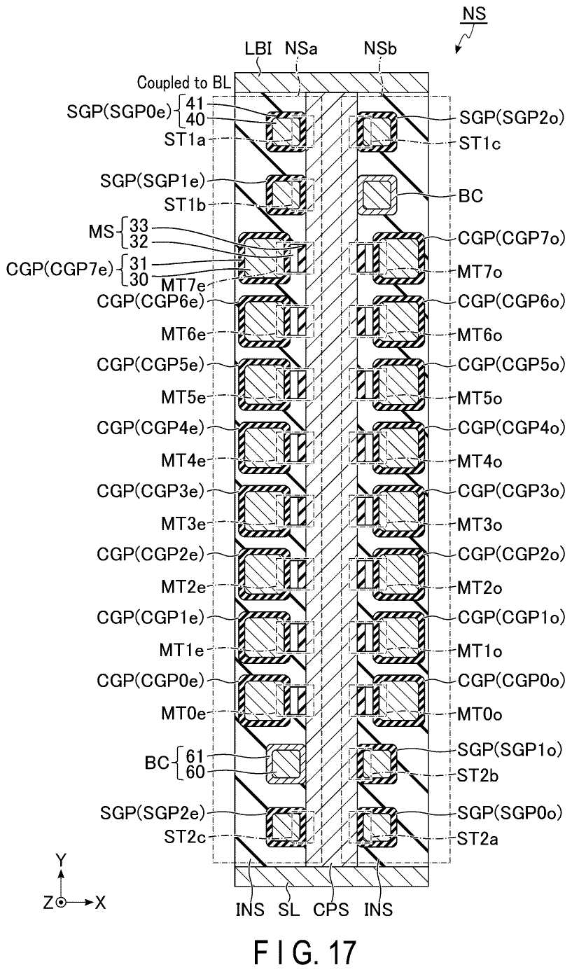

FIG. 17 is a plan view showing an example of a planar layout of the memory cell array 10C. FIG. 17 shows a planar view of a layer substantially equal in height from the substrate in the block BLK. A portion shown in FIG. 17 corresponds to one NAND string NS in the circuit diagram shown in FIG. 16.

As shown in FIG. 17, a planar layout of the memory cell array modification of 10C is similar to that shown in FIG. 10 described in the modification of the first embodiment except that eight conductive pillars TRP within the second string NSb are replaced with eight conductive pillars CGP and eight memory structures MS.

On the rear side of the semiconductor CPS, the second string NSb is arranged. In the second string NSb, for example, one conductive pillar SGP, one contact plug BC, eight conductive pillars CGP, and two conductive pillars SGP are arranged in this order from the upper side of the drawing sheet in the Y direction. One conductive pillar SGP, one contact plug BC, eight conductive pillars CGP, and two conductive pillars SGP are spaced apart from each other in the Y direction.

On the rear side of the semiconductor CPS, the conductive pillar CGP and the memory structure MS have similar structures to those of the conductive pillar CGP and the memory structure MS on the front side of the semiconductor CPS. The above-mentioned structure including one conductive pillar CGP, one memory structure MS, and the semiconductor CPS functions as a memory cell transistor MT. FIG. 17 shows eight of the above-mentioned structures which respectively function as the memory cell transistors MT7o, MT6o, MT5o, MT4o, MT3o, MT2o, MT1o, and MT0o, in this order from the upper side of the drawing sheet. The above-mentioned structure including the semiconductor CPS and a set of three conductive pillars SGP, eight conductive pillars CGP, eight memory structures MS, and one contact plug BC on the rear side of the semiconductor CPS corresponds to the second string NSb.

The plurality of NAND strings NS coupled to the same bit line BL are arranged as in the first embodiment, for example.

### 2.7.3 Three-Dimensional Structure of Memory Cell Array

A three-dimensional structure of the memory cell array 10C will be described. The three-dimensional structure of the memory cell array 10C has a structure in which the same planar layouts, one of which is shown in FIG. 17, are arranged apart from each other in the Z direction. That is, the plurality of the NAND strings NS are arranged apart from each other in the Z direction.

### 2.7.4. Write Operation

The write operation of the semiconductor memory device 3C according to the modification of the second embodiment is the same as that of the second embodiment.

### 2.7.5 Read Operation

The read operation of the semiconductor memory device 3C according to the modification of the second embodiment will be described. The read operation of the semiconductor memory device 3C according to the modification of the present embodiment includes the first read operation.

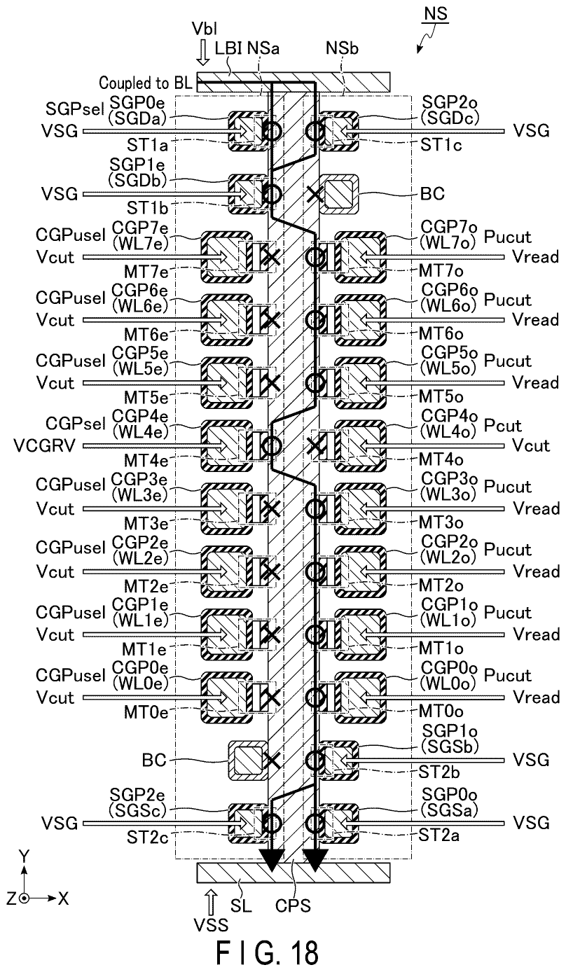

FIG. 18 is a view showing voltages of respective interconnects in the first read operation. FIG. 18 shows the example in which in the selected block BLK, the plurality of memory cell transistors MT4e within the selected string unit SU are selected as a read target, and the memory cell transistor MT4e within one NAND string NS is turned to an ON state.

As shown in FIG. 18, a voltage of each interconnect in the first read operation is similar to a voltage of each interconnect in the first read operation shown in FIG. 11 described in the modification of the first embodiment except that application of a voltage to eight conductive pillars TRP within the second string NSb shown in FIG. 11 is replaced with application of a voltage to eight conductive pillars CGP.

For example, the voltage Vcut is applied to the conductive film 30 of the conductive pillar CGP4o. The conductive pillar CGP4o is a conductive pillar CGPo positioned on the rear side of the semiconductor CPS and also in the vicinity of the selected CG pillar CGPsel. More specifically, the conductive pillar CGP4o corresponds to the conductive pillar CGPo located on the rear side of the semiconductor CPS and in a position facing the selected CG pillar CGPsel on the front side of the semiconductor CPS in the X direction. For example, the voltage Vread is applied to each of the conductive films 30 of the conductive pillars CGP0o to CGP3o and CGP5o to CGP7o.

In the semiconductor CPS, the conductive region is formed as in the modification of the first embodiment. Therefore, in a case where the selected memory cell transistor MT4e is in the ON state, as shown in FIG. 18, the interconnect LBI and the source line SL are electrically coupled so that an electron current flows from the interconnect LBI to the source line SL. On the other hand, in a case where the selected memory cell transistor MT4e is in the OFF state, the interconnect LBI and the source line SL are not electrically coupled.

### 2.7.6 Advantageous Effects of Present Modification

The present modification produces advantageous effects similar to those of the second embodiment.

Furthermore, a cell current can be increased as in the modification of the first embodiment.

### 3. Third Embodiment

A semiconductor memory device 3D according to a third embodiment will be described. The semiconductor memory device 3D according to the present embodiment differs from that of the second embodiment in that the memory strings and the read strings are switchable in units of block BLK. A circuit configuration of the memory cell array 10D is similar to that shown in FIG. 12 described in the second embodiment. One of the first string NSa and the second string NSb is a memory string, and the other is a read string. The planar layout of the memory cell array 10D is similar to that shown in FIG. 13 described in the second embodiment. Hereinafter, the following description will in principle concentrate on the features different from the second embodiment.

### 3.1 String Flag

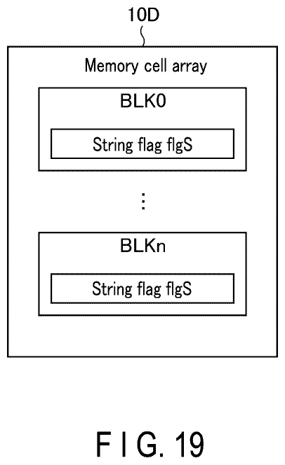

According to the present embodiment, in the NAND string NS within the block BLK, a string flag flgS is used as information (hereinafter referred to as “string information”) indicating which of the first string NSa and the second string NSb corresponds to the memory string. The string flag flgS will be described with reference to FIG. 19. FIG. 19 is a view illustrating a string flag flgS used in the semiconductor memory device 3D according to the present embodiment.

As shown in FIG. 19, each block BLK stores the string flag flgS in the memory cell transistor MT within the memory area. As the string flag flgS, for example, “0 ” is stored in a case where the first string NSa is the memory string, whereas “1” is stored in a case where the second string NSb is the memory string.

### 3.2 Write Operation

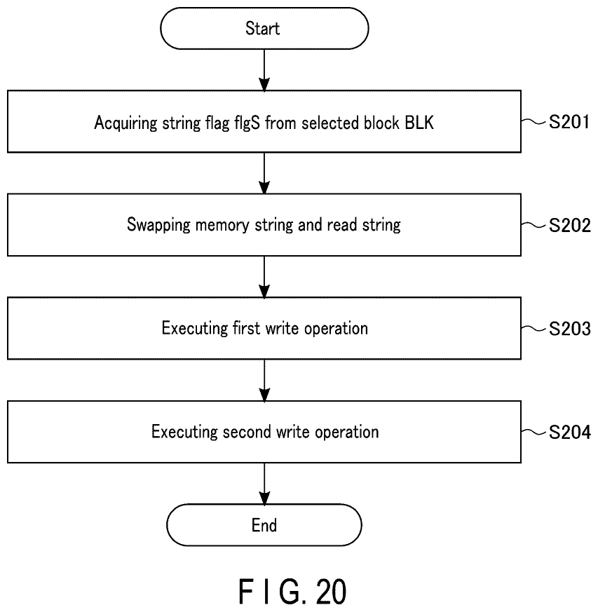

The write operation of the semiconductor memory device 3D according to the third embodiment will be described. The write operation of the semiconductor memory device 3D according to the present embodiment includes the first write operation and the second write operation. FIG. 20 is a flowchart showing an example of the write operation of the semiconductor memory device 3D according to the present embodiment.

For example, in a case where the write operation is initiated, the memory controller 2 accesses the semiconductor memory device 3D, thereby acquiring the string flag flgS from the selected block BLK (S201).

Next, the memory controller 2 swaps the memory string and the read string on the basis of the string flag flgS (S202). Thereby, the memory string and the read string after swapping is determined.

Next, the memory controller 2 instructs the semiconductor memory device 3D to execute the first write operation on the memory string after swapping and to execute the second write operation on the read string after swapping.

Next, the sequencer 13 executes the first write operation on the basis of an instruction received from the memory controller 2 (S203). In the first write operation, the sequencer 13 performs writing (updating) of the string flag flgS within the selected block BLK.

Next, the sequencer 13 executes the second write operation on the basis of an instruction received from the memory controller 2 (S204). Upon completion of the second write operation, the write operation is completed.

In this manner, between the first string NSa and the second string NSb, the string to which write data is to be written is periodically switched in units of blocks.

The above example described the case in which a sting to which write data is to be written is switched every time the write operation is executed on the block BLK (selected block BLK) designated by the block address BAd; however, the write operation of the semiconductor memory device 3D according to the present embodiment is not limited to the above case. For example, every time the plurality of write operations are executed on the selected block BLK or every time the erase operation is executed, the string to which the write data is to be written may be switched.

### 3.3 Read Operation

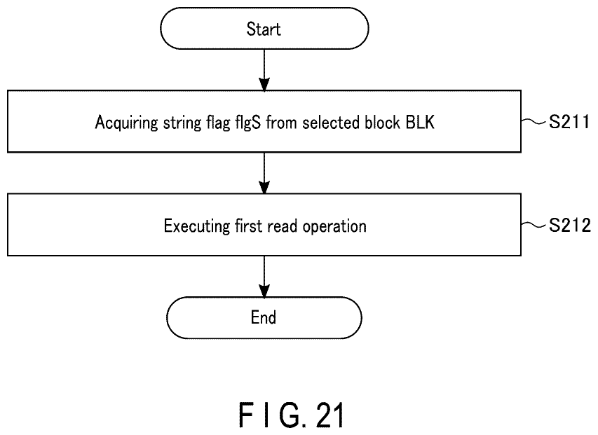

The read operation of the semiconductor memory device 3D according to the third embodiment will be described. The read operation of the semiconductor memory device 3D according to the present embodiment includes the first read operation. FIG. 21 is a flowchart showing an example of the read operation of the semiconductor memory device 3D according to the present embodiment.

For example, in a case where the read operation is initiated, the memory controller 2 accesses the semiconductor memory device 3D, thereby acquiring the string flag flgS from the selected block BLK (S211).

Next, the memory controller 2 instructs the semiconductor memory device 3D to execute the first read operation on the basis of the string flag flgS.

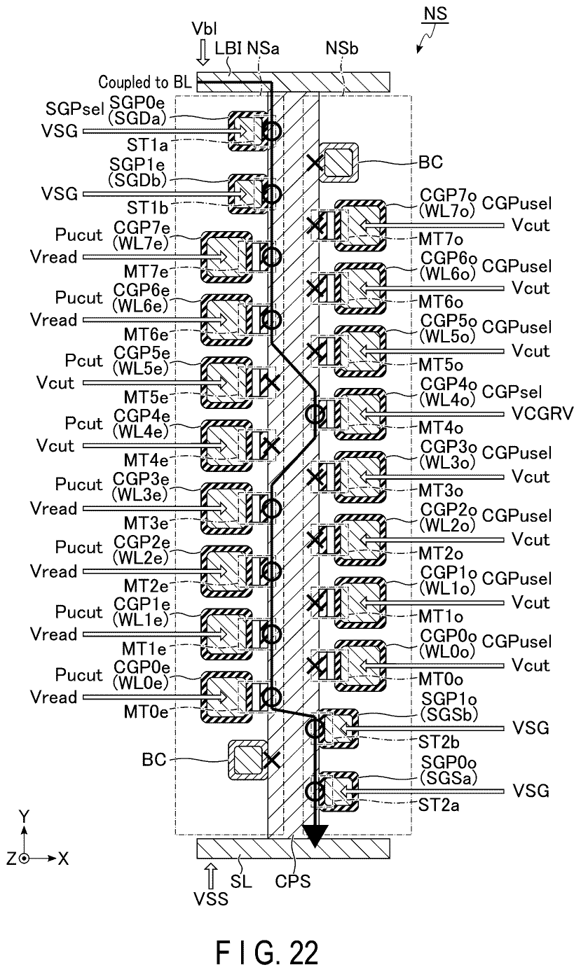

Next, the sequencer 13 executes the first read operation on the basis of an instruction received from the memory controller 2 (S212). FIG. 22 is a view showing voltages of respective interconnects in the first read operation. FIG. 22 shows the example in which in the selected block BLK, the plurality of memory cell transistors MT4o within the selected string unit SU are selected as a read target, and the memory cell transistor MT4o within one NAND string NS is turned to an ON state.

As shown in FIG. 22, in the first read operation, a voltage described below is applied to each of the conductive pillars SGP and CGP within the first string NSa.

For example, the voltage VSG is applied to each of the conductive films 40 of the conductive pillars SGP0e and SGP1e. For example, the voltage Vcut is applied to each of the conductive films 30 of the conductive pillars CGP4e and CGP5e. The conductive pillars CGP4e and CGP5e are conductive pillars CGPe positioned on the front side of the semiconductor CPS and also in the vicinity of the selected CG pillar CGPsel. More specifically, the conductive pillars CGP4e and CGP5e are two conductive pillars CGPe on the front side of the semiconductor CPS which are positioned closest in a +Y direction and a −Y direction to the position facing the selected CG pillar CGPsel on the rear side of the semiconductor CPS in the X direction. The voltage Vread is applied to each of the conductive films 30 of the conductive pillars CGP0e to CGP3e, CGP6e, and CGP7e.

Furthermore, in the first read operation, a voltage described below is applied to each of the conductive pillars SGP and CGP within the NAND string NSb.

For example, the voltage VSG is applied to each of the conductive films 40 of the conductive pillars SGP0o and SGP1o. For example, the voltage VCGRV is applied to the conductive film 30 of the conductive pillar CGP4o (selected CG pillar CGPsel). For example, the voltage Vcut is applied to the conductive films 30 of the conductive pillars CGP0o to CGP3o and CGP5o to CGP7o.

In this state, the voltage Vbl is applied to the bit line BL which is set to a read target and the voltage VSS is applied to the source line SL.

In the semiconductor CPS, the conductive region is formed in the vicinity of a portion in contact with each of the conductive pillars SGP0e, SGP1e, SGP0o, and SGP1o. The conductive region is not formed in the vicinity of a portion in contact with the conductive pillars CGP4e, CGP5e, CGP0o to CGP3o, and CGP5o to CGP7o. The conductive region is formed in the vicinity of a portion in contact with the conductive pillars CGP0e to CGP3e, CGP6e, and CGP7e. In the vicinity of the portion in contact with the conductive pillar CGP4o, in a case where the selected memory cell transistor MT4o is in the ON state, the conductive region is formed. On the other hand, in a case where the selected memory cell transistor MT4o is in the OFF state, the conductive region is not formed.

Furthermore, since the semiconductor CPS is relatively small in width, in the semiconductor CPS, in a case where the selected memory cell transistor MT4o is in the ON state, the conductive region is also formed between the conductive region formed in the vicinity of the conductive pillar CGP6e and the conductive region formed in the vicinity of the selected CG pillar CGPsel, and between the conductive region formed in the vicinity of the selected CG pillar CGPsel and the conductive region formed in the vicinity of the conductive pillar CGP3e. The conductive region is also formed between the conductive region formed in the vicinity of the conductive pillar CGP0e and the conductive region formed in the vicinity of the conductive pillar SGP1o.

In the semiconductor CPS, the conductive region is not formed in the vicinity of a portion in contact with the contact plug BC.

Therefore, in a case where the selected memory cell transistor MT4o is in the ON state, as shown in FIG. 22, the interconnect LBI and the source line SL are electrically coupled so that an electron current flows from the interconnect LBI to the source line SL. On the other hand, in a case where the selected memory cell transistor MT4o is in the OFF state, the interconnect LBI and the source line SL are not electrically coupled.

Meanwhile, in a case where the memory cell transistor MT7o is set to a read target, for example, the voltage VSG is applied to each of the conductive films 40 of the conductive pillars SGP0e, SGP1e, SGP0o, and SGP1o. For example, the voltage VCGRV is applied to the conductive film 30 of the conductive pillar CGP7o (selected CG pillar CGPsel). For example, the voltage Vcut is applied to each of the conductive films 30 of the conductive pillars CGP7e and CGP0o to CGP6o. For example, the voltage Vread is applied to each of the conductive films 30 of the conductive pillars CGP0e to CGP6e.

Furthermore, in a case where the memory cell transistor MT0o is set to a read target, for example, the voltage VSG is applied to each of the conductive films 40 of the conductive pillars SGP0e, SGP1e, SGP0o, and SGP1o. For example, the voltage VCGRV is applied to the conductive film 30 of the conductive pillar CGP0o (selected CG pillar CGPsel). The voltage Vcut is applied to each of the conductive films 30 of the conductive pillars CGP0e, CGP1e, and CGP1o to CGP7o. For example, the voltage Vread is applied to each of the conductive films 30 of the conductive pillars CGP2e to CGP7e.

### 3.4 Advantageous Effects of Present Embodiment

The third embodiment produces advantageous effects similar to those of the second embodiment.

Furthermore, since the memory string and the read string are periodically swapped (for example, at the time of the write operation and the erase operation), the cycle limit of the memory cell can be extended by making the write or erase stress uniform.

### 3.5 First Modification

A semiconductor memory device 3E according to a first modification of the third embodiment will be described. The semiconductor memory device 3E according to the present modification differs from that of the third embodiment in that a string table tblS is used as the string information. Meanwhile, a circuit configuration of the memory cell array 10E and a planar layout of the memory cell array 10E are similar to those of the third embodiment. Hereinafter, the following description will in principle concentrate on the features different from the third embodiment.

### 3.5.1 String Table

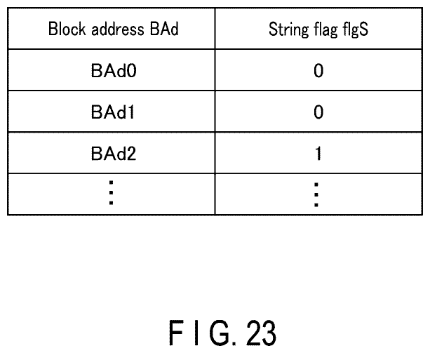

The string table tblS will be described with reference to FIG. 23. FIG. 23 is a conceptional diagram of the string table tblS used in the semiconductor memory device 3E according to the present modification.

As shown in FIG. 23, the string table tblS has a plurality of entries. Each entry includes the block address BAd and the string flag flgS. In the example shown in FIG. 23, the string flag flgS corresponding to each of the block addresses BAd0 and BAd1 is “0”. The string flag flgS corresponding to the block address BAd2 is “1”. For example, the first string NSa is the memory string in the block BLK corresponding to each of the block addresses BAd0 and Bad1, and the second string NSb is the memory string in the block BLK corresponding to the block address BAd2.

The string table tblS is stored in, for example, any of the blocks BLK of the memory cell array 10E. The string table tblS is loaded into a random-access memory (RAM) (not shown) within the memory controller 2 from the semiconductor memory device 3E, for example, immediately after the power is turned off. The string table tblS within the RAM is updated every time the memory string is switched, for example. An initial value of the string flag flgS is, for example, “1”. Furthermore, the string table tblS within the block BLK is updated at any timing.

### 3.5.2. Write Operation

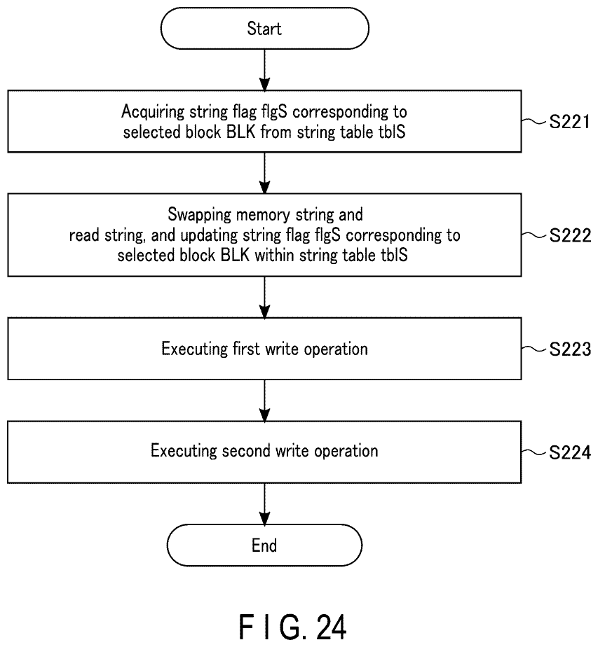

The write operation of the semiconductor memory device 3E according to the first modification of the third embodiment will be described. FIG. 24 is a flowchart showing an example of the write operation of the semiconductor memory device 3E according to the present modification.

For example, in a case where the write operation is initiated, the memory controller 2 acquires the string flag flgS corresponding to the selected block BLK from the string table tblS (S221).

Next, the memory controller 2 swaps the memory string and the read string on the basis of the string flag flgS, and updates the string flag flgS corresponding to the selected block BLK within the string table tblS (S222).

Next, the memory controller 2 instructs the semiconductor memory device 3E to execute the first write operation on the memory string after swapping and to execute the second write operation on the read string after swapping.

Next, the sequencer 13 executes the first write operation on the basis of an instruction received from the memory controller 2 (S223).

Next, the sequencer 13 executes the second write operation on the basis of an instruction received from the memory controller 2 (S224). Upon completion of the second write operation, the write operation is completed.

### 3.5.3 Read Operation

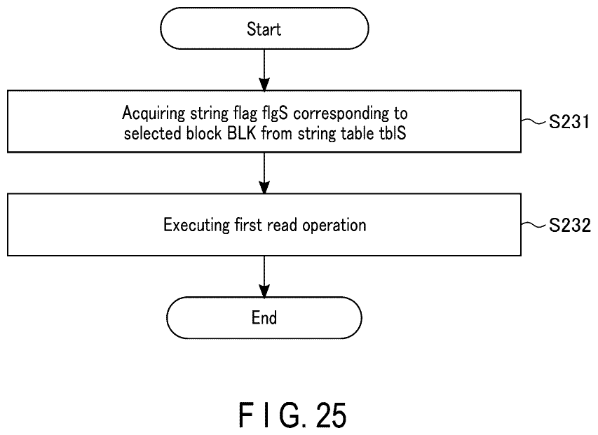

The read operation of the semiconductor memory device 3E according to the first modification of the third embodiment will be described. FIG. 25 is a flowchart showing an example of the read operation of the semiconductor memory device 3E according to the present modification.

For example, in a case where the read operation is initiated, the memory controller 2 acquires the string flag flgS corresponding to the selected block BLK from the string table tblS (S231).

Next, the memory controller 2 instructs the semiconductor memory device 3E to execute the first read operation on the basis of the string flag flgS.

Next, the sequencer 13 executes the first read operation on the basis of an instruction received from the memory controller 2 (S232).

### 3.5.4 Advantageous Effects of Present Modification

The present modification produces advantageous effects similar to those of the third embodiment.

### 3.6 Second Modification

A semiconductor memory device 3F according to a second modification of the third embodiment will be described. The semiconductor memory device 3F according to the present modification differs from that of the third embodiment in terms of a circuit configuration of a memory cell array 10F, a planar layout of the memory cell array 10F, and the read operation. The circuit configuration of the memory cell array 10F is similar to that shown in FIG. 16 described in the modification of the second embodiment. One of the first string NSa and the second string NSb is a memory string, and the other is a read string. The planer layout of the memory cell array 10F is similar to that shown in FIG. 17 described in the modification of the second embodiment. Hereinafter, the following description will in principle concentrate on the features different from the third embodiment.

### 3.6.1. Write Operation

The write operation of the semiconductor memory device 3F according to the second modification of the third embodiment is the same as that of the third embodiment.

### 3.6.2 Read Operation

The read operation of the semiconductor memory device 3F according to the second modification of the third embodiment will be described. A flowchart showing an example of the read operation of the semiconductor memory device 3F according to the present modification is similar to that shown in FIG. 21 described in the third embodiment.

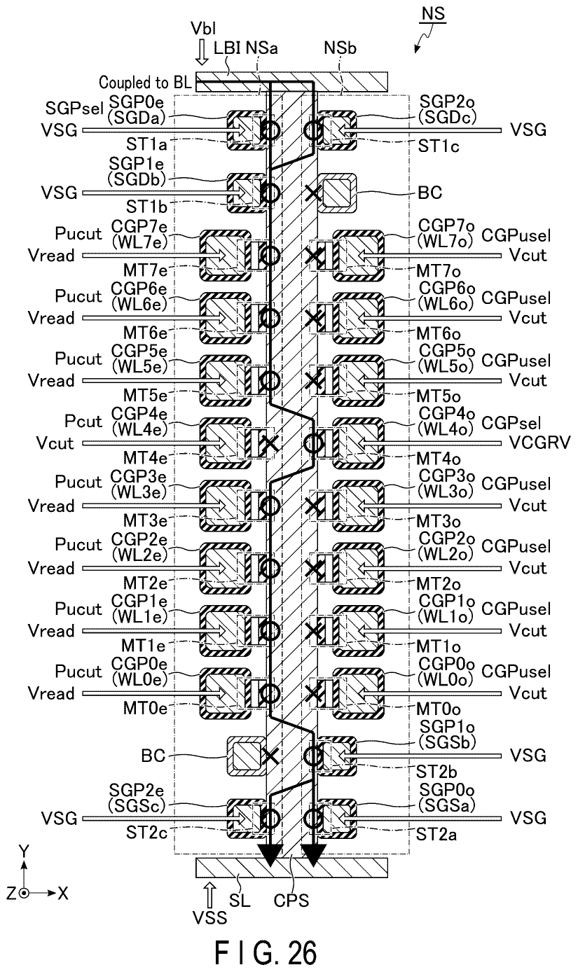

FIG. 26 is a view showing voltages of respective interconnects in the first read operation. FIG. 26 shows the example in which in the selected block BLK, the plurality of memory cell transistors MT4o within the selected string unit SU are selected as a read target, and the memory cell transistor MT4o within one NAND string NS is turned to an ON state.

As shown in FIG. 26, in the first read operation, a voltage described below is applied to each of the conductive pillars SGP and CGP within the first string NSa.

For example, the voltage VSG is applied to each of the conductive films 40 of the conductive pillars SGP0e to SGP2e. For example, the voltage Vcut is applied to the conductive film 30 of the conductive pillar CGP4e. The conductive pillar CGP4e is a conductive pillar CGPe positioned on the front side of the semiconductor CPS and also in the vicinity of the selected CG pillar CGPsel. More specifically, the conductive pillar CGP4e is a conductive pillar CGPe which is in a position facing the selected CG pillar CGPsel on the rear side of the semiconductor CPS in the X direction and is on the front side of the semiconductor CPS. For example, the voltage Vread is applied to each of the conductive films 30 of the conductive pillars CGP0e to CGP3e and CGP5e to CGP7e.

Furthermore, in the first read operation, a voltage described below is applied to each of the conductive pillars SGP and CGP within the NAND string NSb.

For example, the voltage VSG is applied to each of the conductive films 40 of the conductive pillars SGP0o to SGP2o. For example, the voltage VCGRV is applied to the conductive film 30 of the conductive pillar CGP4o. For example, the voltage Vcut is applied to each of the conductive films 30 of the conductive pillars CGP0o to CGP3o and CGP5o to CGP7o.

In this state, the voltage Vbl is applied to the bit line BL which is set to a read target and the voltage VSS is applied to the source line SL.

In the semiconductor CPS, the conductive region is formed in the vicinity of a portion in contact with each of the conductive pillars SGP0e to SGP2e and SGP0o to SGP2o. The conductive region is not formed in the vicinity of a portion in contact with the conductive pillars CGP4e, CGP0o to CGP3o, and CGP5o to CGP7o. The conductive region is formed in the vicinity of a portion in contact with each of the conductive pillars CGP0e to CGP3e and CGP5e to CGP7e. In the vicinity of the portion in contact with the conductive pillar CGP4o, in a case where the selected memory cell transistor MT4o is in the ON state, the conductive region is formed. On the other hand, in a case where the selected memory cell transistor MT4o is in the OFF state, the conductive region is not formed.

Furthermore, since the semiconductor CPS is relatively small in width, in the semiconductor CPS, the conductive region is also formed between the conductive region formed in the vicinity of the conductive pillar SGP2o and the conductive region formed in the vicinity of the conductive pillar SGP1e, between the conductive region formed in the vicinity of the conductive pillar CGP0e and the conductive region formed in the vicinity of the conductive pillar SGP0o, and between the conductive region formed in the vicinity of the conductive pillar SGP0o and the conductive region formed in the vicinity of the conductive pillar SGP2e. In a case where the selected memory cell transistor MT4o is in the ON state, the conductive region is also formed between the conductive region formed in the vicinity of the conductive pillar CGP5e and the conductive region formed in the vicinity of the selected CG pillar CGPsel, and between the conductive region formed in the vicinity of the selected CG pillar CGPsel and the conductive region formed in the vicinity of the conductive pillar CGP3e.

In the semiconductor CPS, the conductive region is not formed in the vicinity of a portion in contact with the contact plug BC.

Therefore, in a case where the selected memory cell transistor MT4o is in the ON state, as shown in FIG. 26, the interconnect LBI and the source line SL are electrically coupled so that an electron current flows from the interconnect LBI to the source line SL. On the other hand, in a case where the selected memory cell transistor MT4o is in the OFF state, the interconnect LBI and the source line SL are not electrically coupled.

Meanwhile, in a case where the memory cell transistor MT7o is set to a read target, for example, the voltage VSG is applied to each of the conductive films 40 of the conductive pillars SGP0e, SGP1e, SGP2e, SGP0o, SGP1o, and SGP2o. For example, the voltage VCGRV is applied to the conductive film 30 of the conductive pillar CGP7o (selected CG pillar CGPsel). For example, the voltage Vcut is applied to each of the conductive films 30 of the conductive pillars CGP7e and CGP0o to CGP6o. For example, the voltage Vread is applied to each of the conductive films 30 of the conductive pillars CGP0e to CGP6e.

Meanwhile, in a case where the memory cell transistor MT0o is set to a read target, for example, the voltage VSG is applied to each of the conductive films 40 of the conductive pillars SGP0e, SGP1e, SGP2e, SGP0o, SGP1o, and SGP2o. For example, the voltage VCGRV is applied to the conductive film 30 of the conductive pillar CGP0o (selected CG pillar CGPsel). For example, the voltage Vcut is applied to each of the conductive films 30 of the conductive pillars CGP0e and CGP1o to CGP7o. For example, the voltage Vread is applied to each of the conductive films 30 of the conductive pillars CGP1e to CGP7e.

### 3.6.3 Advantageous Effects of Present Modification

The present modification produces advantageous effects similar to those of the third embodiment.

Furthermore, a cell current can be increased as in the modification of the first embodiment.

### 4. Fourth Embodiment

A semiconductor memory device 3G according to a fourth embodiment will be described. The semiconductor memory device 3G according to the present embodiment differs from that of the second embodiment in that whether the first string NSa is used as the memory string and the second string NSb is used as the read string, or both the first string NSa and the second string NSb are used as the memory strings can be selected in units of block BLK. Hereinafter, a memory mode of the block BLK in which the first string NSa is used as the memory string and the second string NSb is used as the read string will be referred to as a “high read tolerance mode”. A memory mode of the block BLK in which both the first string NSa and the second string NSb are used as the memory string is denoted as a “normal mode”. A circuit configuration of the memory cell array 10G is similar to that shown in FIG. 12 described in the second embodiment. The planar layout of the memory cell array 10G is similar to that shown in FIG. 13 described in the second embodiment. The following description will concentrate on the features different form the second embodiment.

### 4.1 Method of Designating Storage Mode of Block

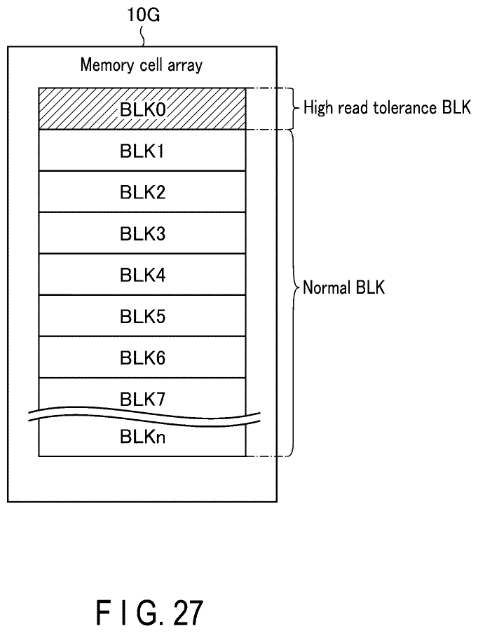

The present embodiment corresponds to a case in which the memory mode of a fixed block BLK is designated as a high read tolerance mode. FIG. 27 is a view illustrating a method of designating a memory mode of the block BLK in the semiconductor memory device 3G according to the present embodiment. As shown in FIG. 27, in the present embodiment, the memory mode of the fixed block BLK is designated as the high read tolerance mode. In the example shown in FIG. 27, the memory mode of the block BLK0 is designated as the high read tolerance mode. The memory mode of each of the other blocks BLK is designated as the normal mode. Hereinafter, the block designated as the high read tolerance mode will also be referred to as a “high read tolerance BLK”. The block BLK designated as the normal mode will also be referred to as a “normal BLK”.

The high read tolerance BLK stores, for example, information such as a File Allocation Table (FAT) whose use is determined. For example, the user designates, via the host, the block BLK storing information whose use is determined as the high read tolerance mode.

### 4.2 Write Operation

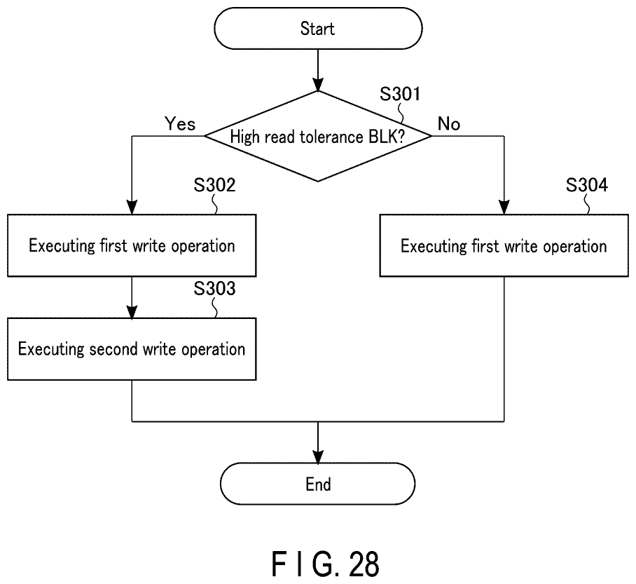

The write operation of the semiconductor memory device 3G according to the fourth embodiment will be described. The write operation of the semiconductor memory device 3G according to the present embodiment includes the first write operation and the second write operation. FIG. 28 is a flowchart showing an example of the write operation of the semiconductor memory device 3G according to the present embodiment.

For example, in a case where the write operation is initiated, the memory controller 2 determines whether or not the selected block BLK is the high read tolerance BLK (S301).

In a case where the selected block BLK is the high read tolerance BLK (S301_Yes), the memory controller 2 instructs the semiconductor memory device 3G to execute the first write operation on the memory string (first string NSa) and the second write operation on the read string (second string NSb). Next, the sequencer 13 executes the first write operation on the basis of an instruction received from the memory controller 2 (S302). That is, in the block BLK whose memory mode is designated as the high read tolerance mode, the write data is written to the first string NSa. Next, the sequencer 13 executes the second write operation on the basis of an instruction received from the memory controller 2 (S303).

On the other hand, in a case where the selected block BLK is not the high read tolerance BLK (that is, the selected block BLK is the normal BLK) (S301_No), the memory controller 2 instructs the semiconductor memory device 3G to execute the first write operation on the memory strings (the first string NSa and the second string NSb). Next, the sequencer 13 executes the first write operation on the basis of an instruction received from the memory controller 2 (S304). That is, in the block BLK whose memory mode is designated as the normal mode, the write data is written to both the first string NSa and the second string NSb. For example, in the NAND string NS, the conductive pillars CGP0e to CGP7e and CGP0o to CGP7o are selected in order of the conductive pillars CGP7e, CGP6e, . . . , CGP1e, CGP0e, CGP7o, CGP6o, . . . , CGP1o, and CGP0o.

### 4.3. Read Operation

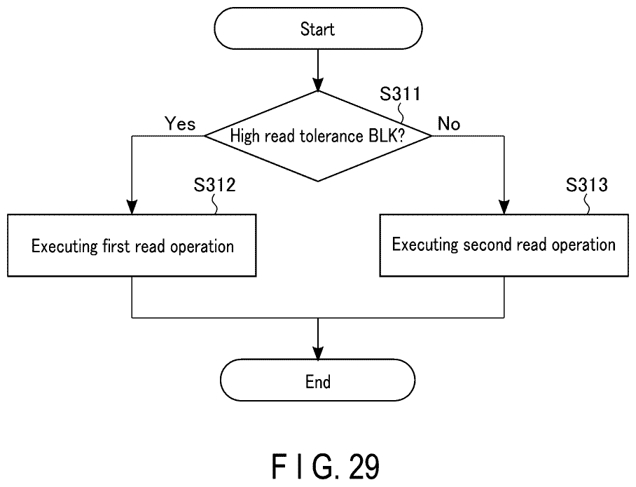

The read operation of the semiconductor memory device 3G according to the fourth embodiment will be described. The read operation of the semiconductor memory device 3G according to the present embodiment includes the first read operation and the second read operation. The first read operation is a read operation with respect to the high read tolerance BLK. The second read operation is a read operation with respect to the normal BLK. FIG. 29 is a flowchart showing an example of the read operation of the semiconductor memory device 3G according to the present embodiment.

For example, in a case where the read operation is initiated, the memory controller 2 determines whether or not the selected block BLK is the high read tolerance BLK (S311).

In a case where the selected block BLK is the high read tolerance BLK (S311_Yes), the memory controller 2 instructs the semiconductor memory device 3G to execute the first write operation. Next, the sequencer 13 executes the first read operation on the basis of an instruction received from the memory controller 2 (S312).

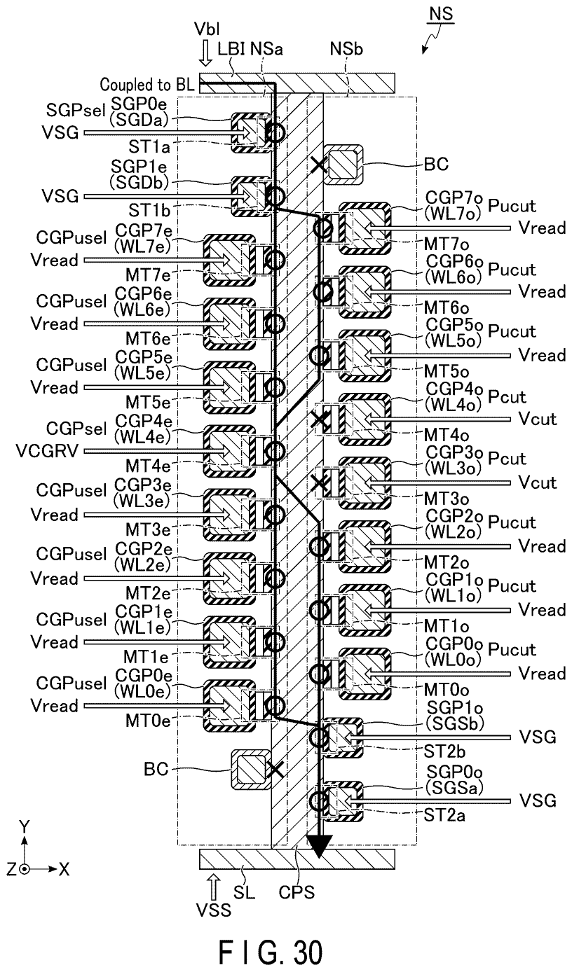

On the other hand, in a case where the selected block BLK is not the high read tolerance BLK (S311_No), the memory controller 2 instructs the semiconductor memory device 3G to execute the second read operation. Next, the sequencer 13 executes the second read operation on the basis of an instruction received from the memory controller 2 (S313). FIG. 30 is a view showing voltages of respective interconnects in the second read operation. FIG. 30 shows the example in which in the selected block BLK, the plurality of memory cell transistors MT4e within the selected string unit SU are selected as a read target, and the memory cell transistor MT4e within one NAND string NS is turned to the ON state.

As shown in FIG. 30, in the second read operation, a voltage described below is applied to each of the conductive pillars SGP and CGP within the first string NSa.

For example, the voltage VSG is applied to each of the conductive films 40 of the conductive pillars SGP0e and SGP1e. For example, the voltage VCGRV is applied to the conductive film 30 of the conductive pillar CGP4e (selected CG pillar CGPsel). For example, the voltage Vread is applied to each of the conductive films 30 of the conductive pillars CGP0e to CGP3e and CGP5e to CGP7e.

Furthermore, in the second read operation, a voltage described below is applied to each of the conductive pillars SGP and CGP within the NAND string NSb.

For example, the voltage VSG is applied to each of the conductive films 40 of the conductive pillars SGP0o and SGP1o. For example, the voltage Vcut is applied to each of the conductive films 30 of the conductive pillars CGP3o and CGP4o. For example, the voltage Vread is applied to each of the conductive films 30 of the conductive pillars CGP0o to CGP2o and CGP5o to CGP7o.

In this state, the voltage Vbl is applied to the bit line BL which is set to a read target and the voltage VSS is applied to the source line SL.

In the semiconductor CPS, the conductive region is formed in the vicinity of a portion in contact with each of the conductive pillars SGP0e, SGP1e, SGP0o, and SGP1o. The conductive region is not formed in the vicinity of a portion in contact with each of the conductive pillars CGP3o and CGP4o. The conductive region is formed in the vicinity of a portion in contact with each of the conductive pillars CGP0e to CGP3e, CGP5e to CGP7e, CGP0o to CGP2o, and CGP5o to CGP7o. In the vicinity of the portion in contact with the conductive pillar CGP4e, in a case where the selected memory cell transistor MT4e is in the ON state, the conductive region is formed. On the other hand, in a case where the selected memory cell transistor MT4e is in the OFF state, the conductive region is not formed.

Furthermore, since the semiconductor CPS is relatively small in width, in the semiconductor CPS, the conductive region is also formed between the conductive region formed in the vicinity of the conductive pillar SGP1e and the conductive region formed in the vicinity of the conductive pillar CGP7o, and between the conductive region formed in the vicinity of the conductive pillar CGP0e and the conductive region formed in the vicinity of the conductive pillar SGP1o. In a case where the selected memory cell transistor MT4e is in the ON state, the conductive region is also formed between the conductive region formed in the vicinity of the conductive pillar CGP5o and the conductive region formed in the vicinity of the selected CG pillar CGPsel, and between the conductive region formed in the vicinity of the selected CG pillar CGPsel and the conductive region formed in the vicinity of the conductive pillar CGP2o.

In the semiconductor CPS, the conductive region is not formed in the vicinity of a portion in contact with the contact plug BC.

Therefore, in a case where the selected memory cell transistor MT4e is in the ON state, as shown in FIG. 30, the interconnect LBI and the source line SL are electrically coupled so that an electron current flows from the interconnect LBI to the source line SL. On the other hand, in a case where the selected memory cell transistor MT4e is in the OFF state, the interconnect LBI and the source line SL are not electrically coupled.

For example, in the NAND string NS, the conductive pillars CGP0e to CGP7e and CGP0o to CGP7o are selected in order of the conductive pillars CGP7e, CGP6e, . . . , CGP1e, CGP0e, CGP7o, CGP6o, . . ., CGP1o, and CGP0o.

### 4.4 Advantageous Effects of Present Embodiment

The fourth embodiment produces advantageous effects similar to those of the second embodiment.

Furthermore, in the semiconductor memory device 3G according to the present embodiment, one of the first string NSa and the second string NSb is used as the memory string in the high read tolerance BLK, whereas both of the first string NSa and the second string NSb are used as the memory string in the normal BLK. Therefore, the high read tolerance BLK can realize the memory cell with a high read tolerance, whereas the normal BLK can increase a storage capacity of the memory cell.

Furthermore, as described with reference to FIG. 30, in the second read operation, a cell current is caused to flow through the memory cell transistor MT corresponding to the non-selected CGPusel, so that the cell current can be increased.

Furthermore, the fixed block BLK can be designated as the high read tolerance BLK, so that the semiconductor memory device 3G according to the present embodiment can be utilized in a case, for example, where a use is determined.

### 4.5 First Modification

A semiconductor memory device 3H according to a first modification of the fourth embodiment will be described. The semiconductor memory device 3H according to the present modification differs from that of the fourth embodiment in terms of a circuit configuration of a memory cell array 10H, a planar layout of the memory cell array 10H, and the read operation. The circuit configuration of the memory cell array 10H is similar to that shown in FIG. 16 described in the modification of the second embodiment. The planer layout of the memory cell array 10H is similar to that shown in FIG. 17 described in the modification of the second embodiment. Hereinafter, the following description will in principle concentrate on the features different from the fourth embodiment.

### 4.5.1 Write Operation

The write operation of the semiconductor memory device 3H according to the first modification of the fourth embodiment is the same as that of the fourth embodiment.

### 4.5.2 Read Operation

The read operation of the semiconductor memory device 3H according to the first modification of the fourth embodiment will be described. A flowchart showing an example of the read operation of the semiconductor memory device 3H according to the present modification is similar to that shown in FIG. 29 described in the fourth embodiment.

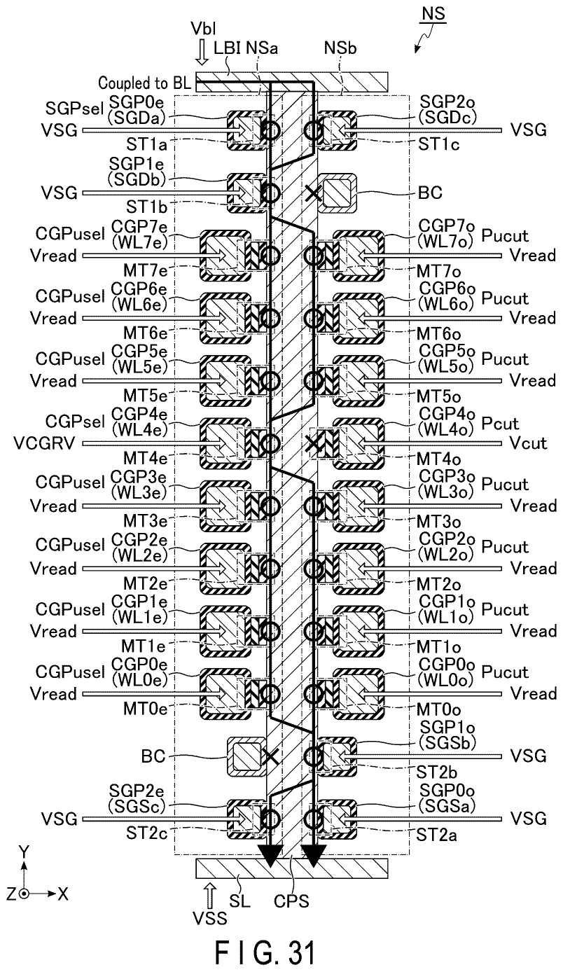

FIG. 31 is a view showing voltages of respective interconnects in the second read operation. FIG. 31 shows the example in which in the selected block BLK, the plurality of memory cell transistors MT4e within the selected string unit SU are selected as a read target, and the memory cell transistor MT4e within one NAND string NS is turned to an ON state.

As shown in FIG. 31, in the second read operation, a voltage described below is applied to each of the conductive pillars SGP and CGP within the first string NSa.

For example, the voltage VSG is applied to each of the conductive films 40 of the conductive pillars SGP0e to SGP2e. For example, the voltage VCGRV is applied to the conductive film 30 of the conductive pillar CGP4e (selected CG pillar CGPsel). For example, the voltage Vread is applied to each of the conductive films 30 of the conductive pillars CGP0e to CGP3e and CGP5e to CGP7e.

Furthermore, in the second read operation, a voltage described below is applied to each of the conductive pillars SGP and CGP within the NAND string NSb.

For example, the voltage VSG is applied to each of the conductive films 40 of the conductive pillars SGP0o to SGP2o. For example, the voltage Vcut is applied to the conductive film 30 of the conductive pillar CGP4o. For example, the voltage Vread is applied to each of the conductive films 30 of the conductive pillars CGP0o to CGP3o and CGP5o to CGP7o.

In this state, the voltage Vbl is applied to the bit line BL which is set to a read target and the voltage VSS is applied to the source line SL.

In the semiconductor CPS, the conductive region is formed in the vicinity of a portion in contact with each of the conductive pillars SGP0e to SGP2e and SGP0o to SGP2o. The conductive region is not formed in the vicinity of a portion in contact with the conductive pillar CGP4o. The conductive region is formed in the vicinity of a portion in contact with each of the conductive pillars CGP0e to CGP3e, CGP5e to CGP7e, CGP0o to CGP3o, and CGP5o to CGP7o. In the vicinity of the portion in contact with the conductive pillar CGP4e, in a case where the selected memory cell transistor MT4e is in the ON state, the conductive region is formed. On the other hand, in a case where the selected memory cell transistor MT4e is in the OFF state, the conductive region is not formed.

Furthermore, since the semiconductor CPS is relatively small in width, in the semiconductor CPS, the conductive region is also formed between the conductive region formed in the vicinity of the conductive pillar SGP2o and the conductive region formed in the vicinity of the conductive pillar SGP1e, and between the conductive region formed in the vicinity of the conductive pillar SGP1e and the conductive region formed in the vicinity of the conductive pillar CGP7o. The conductive region is also formed between the conductive region formed in the vicinity of the conductive pillar CGP0e and the conductive region formed in the vicinity of the conductive pillar SGP1o, and between the conductive region formed in the vicinity of the conductive pillar SGP1o and the conductive region formed in the vicinity of the conductive pillar SGP2e. In a case where the selected memory cell transistor MT4e is in the ON state, the conductive region is also formed between the conductive region formed in the vicinity of the conductive pillar CGP5o and the conductive region formed in the vicinity of the selected CG pillar CGPsel, and between the conductive region formed in the vicinity of the selected CG pillar CGPsel and the conductive region formed in the vicinity of the conductive pillar CGP3o.

In the semiconductor CPS, the conductive region is not formed in the vicinity of a portion in contact with the contact plug BC.

Therefore, in a case where the selected memory cell transistor MT4e is in the ON state, as shown in FIG. 31, the interconnect LBI and the source line SL are electrically coupled so that an electron current flows from the interconnect LBI to the source line SL. On the other hand, in a case where the selected memory cell transistor MT4e is in the OFF state, the interconnect LBI and the source line SL are not electrically coupled.

### 4.5.3 Advantageous Effects of Present Modification

The present modification produces advantageous effects similar to those of the fourth embodiment.

Furthermore, a cell current can be increased as in the modification of the first embodiment.

### 4.6 Second Modification

A semiconductor memory device 3I according to a second modification of the fourth embodiment will be described. The semiconductor memory device 3I according to the present modification differs from the fourth embodiment in terms of the method of designating a memory mode of the block BLK. Hereinafter, the following description will in principle concentrate on the features different from the fourth embodiment.

### 4.6.1 Method of Designating Storage Mode of Block

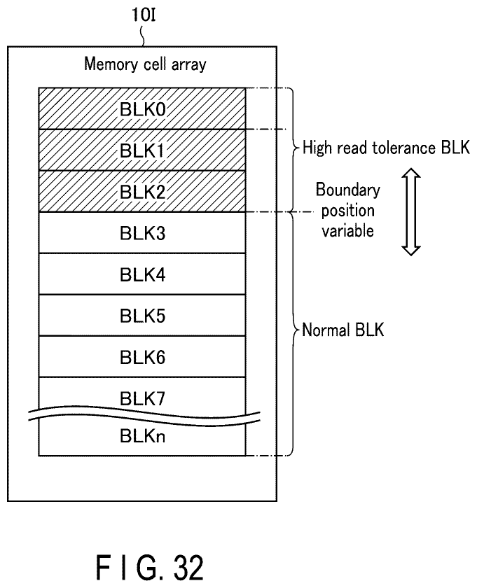

The present modification corresponds to a case in which a region of the block BLK in which the memory mode is designated as the high read tolerance mode is variable. FIG. 32 is a view illustrating a method of designating a memory mode of the block BLK in a semiconductor memory device 3I according to the present modification. As shown in FIG. 32, in the present modification, a region of the block BLK designated as the high read tolerance mode is variable. That is, a boundary position between the high read tolerance BLK and the normal BLK is varied. In the example shown in FIG. 32, the memory mode of the block BLK0 to BLK2 is designated as the high read tolerance mode. The memory mode of each of the other blocks BLK is designated as the normal mode.

### 4.6.2 Mode Flag

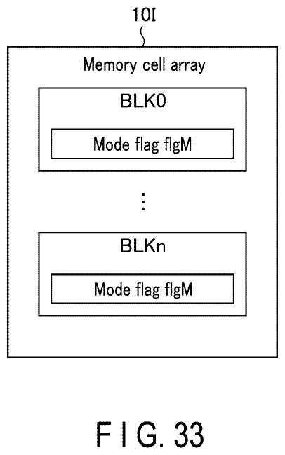

In the present modification, a mode flag flgM is used as information (hereinafter referred to as “memory mode information”) indicating whether the memory mode of the selected block BLK is designated as the high read tolerance mode or the normal mode. The mode flag flgM will be described with reference to FIG. 33. FIG. 33 is a view illustrating the mode flag flgM used in the semiconductor memory device 3I according to the present modification.

As shown in FIG. 33, each block BLK stores the mode flag flgM in a memory cell transistor MT within the memory area. As the mode flag flgM, for example, “0” is stored in a case of the normal mode, whereas “1” is stored in a case of the high read tolerance mode.

### 4.6.3 Write Operation

The write operation of the semiconductor memory device 3I according to the second modification of the fourth embodiment will be described. The write operation of the semiconductor memory device 3I according to the present modification includes the first write operation.

For example, in a case where the write operation is initiated, the memory controller 2 instructs the semiconductor memory device 3I to execute the first write operation on the memory strings (the first string NSa and the second string NSb). Next, the sequencer 13 executes the first write operation on the basis of an instruction received from the memory controller 2. In the first write operation, the sequencer 13 also performs writing (updating) of the mode flag flgM (for example, “0”) within the selected block BLK.

### 4.6.4 Block Area Variable Operation

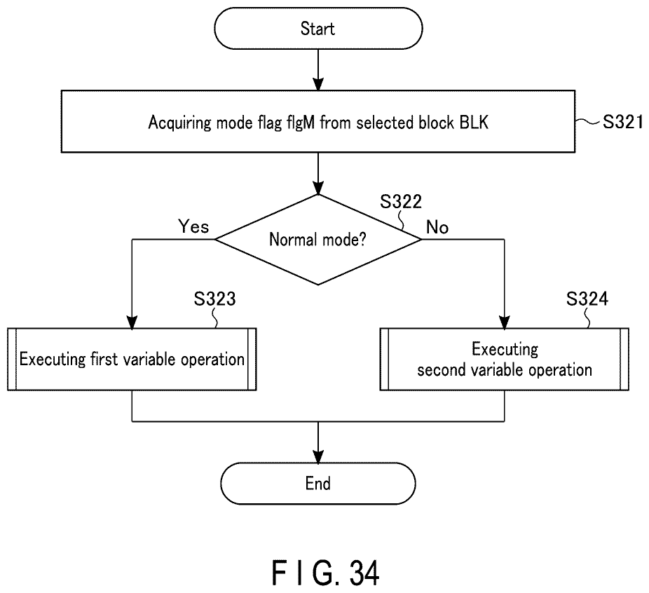

A block area variable operation of the semiconductor memory device 3I according to the second modification of the fourth embodiment will be described. The block area variable operation of the semiconductor memory device 3I according to the present modification includes the first variable operation and the second variable operation. FIG. 34 is a flowchart showing an example of the block area variable operation of the semiconductor memory device 3I according to the present modification.

For example, at fixed time intervals, the memory controller 2 accesses the semiconductor memory device 3I, thereby acquiring the mode flag flgM from the selected block BLK (S321).

Next, the memory controller 2 determine whether or not the mode flag flgM indicates the normal mode (S322).

In a case where the mode flag flgM corresponds to the normal mode (S322_Yes), the memory controller 2 executes the first variable operation (S323).

On the other hand, in a case where the mode flag flgM corresponds to the high read tolerance mode (S322_No), the memory controller 2 executes the second variable operation (S324).

### First Variable Operation

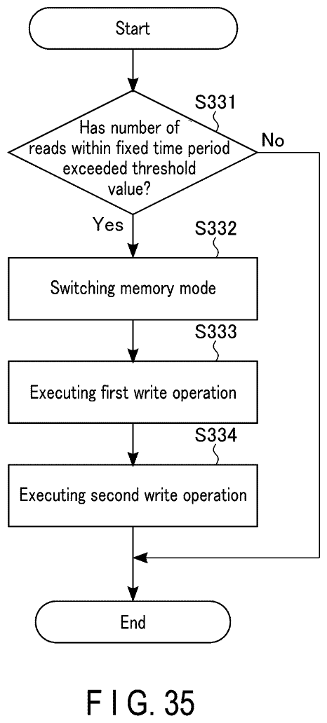

The first variable operation will be described. FIG. 35 is a flowchart showing an example of the first variable operation of the semiconductor memory device 3I according to the present modification.

For example, the memory controller 2 determines whether or not the number of times data of the selected block BLK has been read within a fixed period of time has exceeded a threshold value TH1 (S331).

In a case where the number of reads has exceeded the threshold value TH1 (S331_Yes), the memory controller 2 switches the memory mode (S332). As a result, the memory mode is switched to the high read tolerance mode. Next, the memory controller 2 instructs the semiconductor memory device 3I to execute the first write operation and the second write operation. Next, the sequencer 13 executes the first write operation on the basis of an instruction received from the memory controller 2 (S333). In the first write operation, the sequencer 13 also performs writing (updating) of the mode flag flgM (for example, “1”) within the selected block BLK. Next, the sequencer 13 executes the second write operation on the basis of an instruction received from the memory controller 2 (S334). As described above, in a case where the number of times data of the normal BLK has been read within the fixed period of time has exceeded the threshold value TH1, the normal BLK concerned is switched to the high read tolerance mode, and the normal BLK concerned is changed to the high read tolerance BLK. As a result, the area of the high read tolerance BLK increases (the boundary position between the high read tolerance BLK and the normal BLK is varied), and the first variable operation is terminated.

On the other hand, in a case where the number of reads has not exceeded the threshold value TH1 (S331_No), the first variable operation is terminated.

### Second Variable Operation

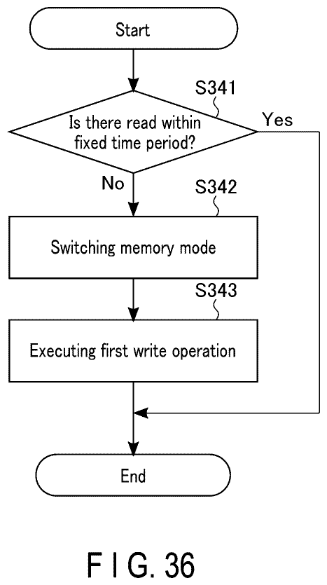

The second variable operation will be described. FIG. 36 is a flowchart showing an example of the second variable operation of the semiconductor memory device 3I according to the present modification.

For example, the memory controller 2 determines whether or not data of the selected block BLK has been read within a fixed period of time (S341).

In a case where data has been read within the fixed period of time (S341_Yes), the second variable operation is terminated.

On the other hand, in a case where data has not been read within the fixed period of time (S341_No), the memory controller 2 switches the memory mode (S342). As a result, the memory mode is switched to the normal mode. Next, the memory controller 2 instructs the semiconductor memory device 3I to execute the first write operation. Next, the sequencer 13 executes the first write operation on the basis of an instruction received from the memory controller 2 (S343). In the first write operation, the sequencer 13 also performs writing (updating) of the mode flag flgM (for example, “0”) within the selected block BLK. As described above, in a case where data of the high read tolerance BLK has not been read within the fixed period of time, the memory mode of the high read tolerance BLK concerned is switched to the normal mode, and the high read tolerance BLK concerned is changed to the normal BLK. As a result, the area of the high read tolerance BLK decrease (the boundary position between the high read tolerance BLK and the normal BLK is varied), and the second variable operation is terminated.

As described above, in the block area variable operation, the boundary position between the high read tolerance BLK and the normal BLK is varied on the basis of the number of accesses to data of the selected block BLK.

### 4.6.5 Read Operation

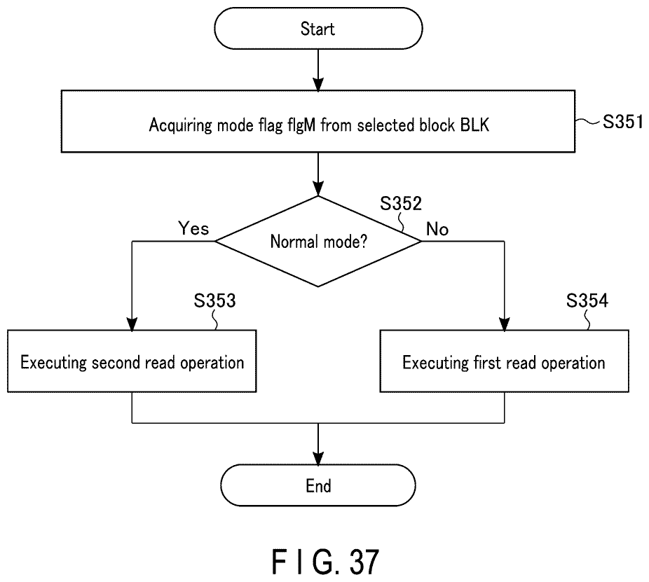

The read operation of the semiconductor memory device 3I according to the second modification of the fourth embodiment will be described. FIG. 37 is a flowchart showing an example of the read operation of the semiconductor memory device 3I according to the present modification.

For example, in a case where the read operation is initiated, the memory controller 2 accesses the semiconductor memory device 3I, thereby acquiring the mode flag flgM from the selected block BLK (S351).

Next, the memory controller 2 determines whether or not the mode flag flgM corresponds to the normal mode (S352).

In a case where the mode flag flgM corresponds to the normal mode (S352_Yes), the memory controller 2 instructs the semiconductor memory device 3I to execute the second read operation. Next, the sequencer 13 executes the second read operation on the basis of an instruction received from the memory controller 2 (S353).

On the other hand, in a case where the mode flag flgM corresponds to the high read tolerance mode (S352_No), the memory controller 2 instructs the semiconductor memory device 3I to execute the first read operation. Next, the sequencer 13 executes the first read operation on the basis of an instruction received from the memory controller 2 (S354).

### 4.6.6 Advantageous Effects of Present Modification

The present modification produces advantageous effects similar to those of the fourth embodiment.

Furthermore, the boundary position between the high read tolerance BLK and the normal BLK can be varied, so that usage as a cache, etc., is possible. For example, depending on the number of accesses, a data storage destination can be shifted from an external DRAM cache (not shown) to the high read tolerance BLK and from the high read tolerance BLK to the normal BLK.

### 4.7 Third Modification

A semiconductor memory device 3J according to a third modification of the fourth embodiment will be described. The semiconductor memory device 3J according to the present modification differs from that of the second modification of the fourth embodiment in that a mode table tblM is used as memory mode information. Meanwhile, a circuit configuration of the memory cell array 10J and a planar layout of the memory cell array 10J are similar to those of the second modification of the fourth embodiment. Hereinafter, the following description will in principle concentrate on the features different from the second modification of the fourth embodiment.

### 4.7.1 Mode Table

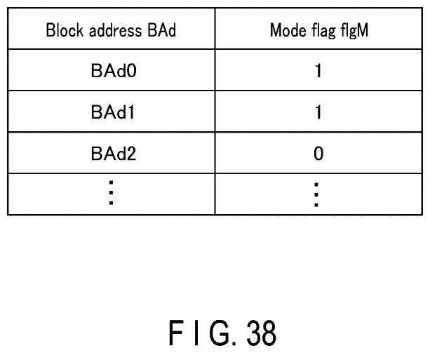

The mode table tblM will be described with reference to FIG. 38. FIG. 38 is a conceptional diagram of the mode table tblM used in the semiconductor memory device 3J according to the present modification.

As shown in FIG. 38, the string table tblM has a plurality of entries. Each entry includes the block address BAd and the mode flag flgM. In the example shown in FIG. 38, the mode flag flgM corresponding to each of the block addresses BAd0 and BAd1 is “1”. The string flag flgM corresponding to the block address BAd2 is “0”. For example, the block BLK corresponding to each of the block addresses BAd0 and BAd1 corresponds to the high read tolerance mode, whereas the block BLK corresponding to the block address BAd2 corresponds to the normal mode.

The mode table tblM is stored in, for example, one of the blocks BLK of the memory cell array 10J. The mode table tblM is loaded into the RAM within the memory controller 2 from the semiconductor memory device 3J, for example, immediately after the power is turned off. The mode table tblM within the RAM is updated every time the memory mode is switched. An initial value of the mode flag flgM is, for example, “0”. Furthermore, the mode table tblM within the block BLK is updated at a given timing.

### 4.7.2 Write Operation

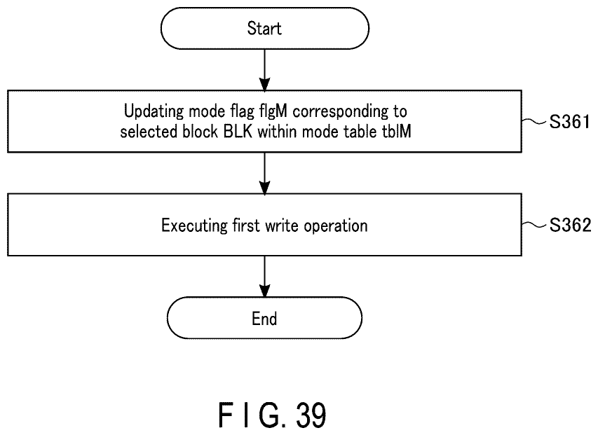

The write operation of the semiconductor memory device 3J according to the third modification of the fourth embodiment will be described. The write operation of the semiconductor memory device 3J according to the present modification includes the first write operation. FIG. 39 is a flowchart showing an example of the write operation of the semiconductor memory device 3J according to the present modification.

For example, in a case where the write operation is initiated, the memory controller 2 acquires the mode flag flgM corresponding to the selected block BLK within the mode table tblM (S361).

Next, the memory controller 2 instructs the semiconductor memory device 3J to execute the first write operation on the memory strings (the first string NSa and the second string NSb). Next, the sequencer 13 executes the first write operation on the basis of an instruction received from the memory controller 2 (S362). Upon completion of the first write operation, the write operation is completed.

### 4.7.3 Block Area Variable Operation

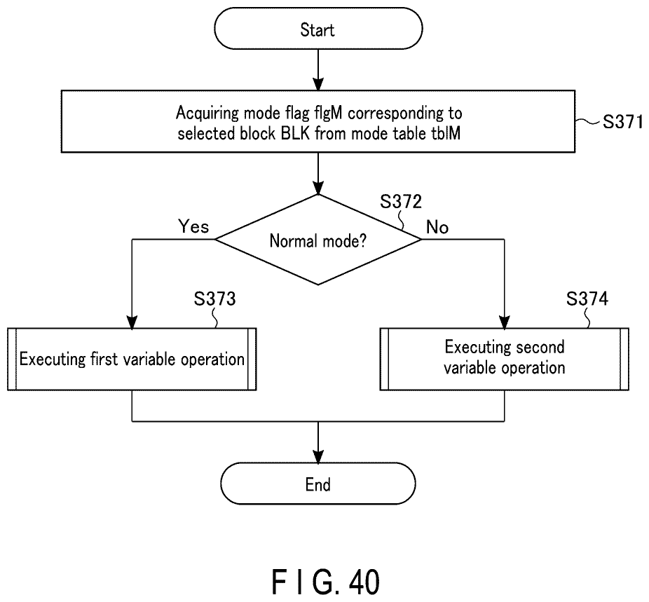

The block area variable operation of the semiconductor memory device 3J according to the third modification of the fourth embodiment will be described. The block area variable operation of the semiconductor memory device 3J according to the present modification includes the first variable operation and the second variable operation. FIG. 40 is a flowchart showing an example of the block area variable operation of the semiconductor memory device 3J according to the present modification.

For example, at fixed time intervals, the memory controller 2 acquires the mode flag flgM corresponding to the selected block BLK within the mode table tblM (S371).

Next, the memory controller 2 determine whether or not the mode flag flgM indicates the normal mode (S372).

In a case where the mode flag flgM corresponds to the normal mode (S372_Yes), the memory controller 2 executes the first variable operation (S373).

On the other hand, in a case where the mode flag flgM corresponds to the high read tolerance mode (S372_No), the memory controller 2 executes the second variable operation (S374).

### First Variable Operation

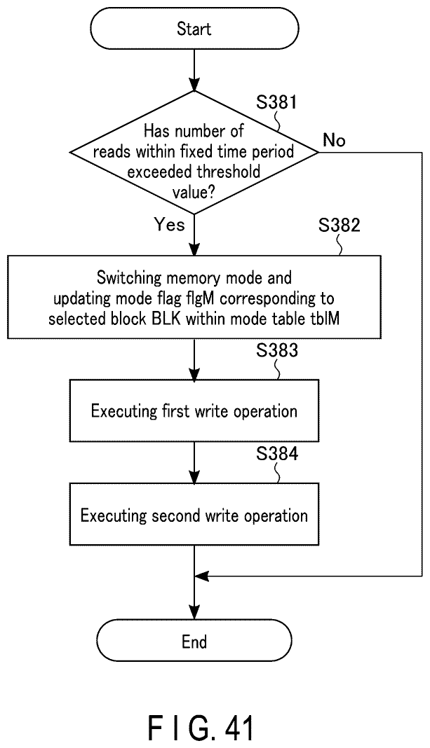

The first variable operation will be described. FIG. 41 is a flowchart showing an example of the first variable operation of the semiconductor memory device 3J according to the present modification.

For example, the memory controller 2 determines whether or not the number of times data of the selected block BLK is read within a fixed period of time has exceeded the threshold value TH1 (S381).

In a case where the number of reads has exceeded the threshold value TH1 (S381_Yes), the memory controller 2 switches the memory mode and updates the mode flag flgM corresponding to the selected block BLK within the mode table tblM (S382). As a result, the memory mode is switched to the high read tolerance mode.

Next, the memory controller 2 instructs the semiconductor memory device 3J to execute the first write operation and the second write operation. Next, the sequencer 13 executes the first write operation on the basis of an instruction received from the memory controller 2 (S383). Next, the sequencer 13 executes the second write operation on the basis of an instruction received from the memory controller 2 (S384). As a result, the area of the high read tolerance BLK increases, and the first variable operation is terminated.

On the other hand, in a case where the number of reads has not exceeded the threshold value TH1 (S381_No), the first variable operation is terminated.

### Second Variable Operation

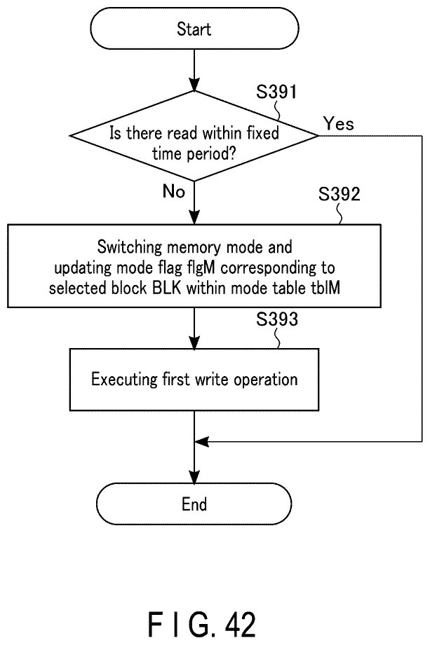

The second variable operation will be described. FIG. 42 is a flowchart showing an example of the second variable operation of the semiconductor memory device 3J according to the present modification.

For example, the memory controller 2 determines whether or not data of the selected block BLK has been read within a fixed period of time (S391).

In a case where data has been read within the fixed period of time (S391_Yes), the second variable operation is terminated.

On the other hand, in a case where data of the selected block BLK has not been read within the fixed period of time (S391_No), the memory controller 2 switches the memory mode and updates the mode flag flgM corresponding to the selected block BLK within the mode table tblM (S392). As a result, the memory mode is switched to the normal mode. Next, the memory controller 2 instructs the semiconductor memory device 3J to execute the first write operation. Next, the sequencer 13 executes the first write operation on the basis of an instruction received from the memory controller 2 (S393). As a result, the area of the high read tolerance BLK decreases, and the second variable operation is terminated.

### 4.7.4 Read Operation

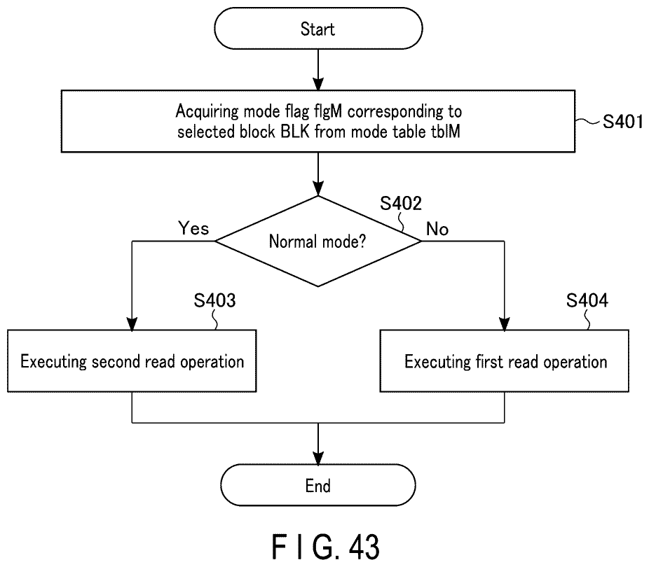

The read operation of the semiconductor memory device 3J according to the third modification of the fourth embodiment will be described. FIG. 43 is a flowchart showing an example of the read operation of the semiconductor memory device 3J according to the present modification.

For example, in a case where the read operation is initiated, the memory controller 2 acquires the mode flag flgM corresponding to the selected block BLK from the mode table tblM (S401).

Next, the memory controller 2 determine whether or not the mode flag flgM corresponds to the normal mode (S402).

In a case where the mode flag flgM is the normal mode (S402_Yes), the memory controller 2 instructs the semiconductor memory device 3J to execute the second read operation. Next, the sequencer 13 executes the second read operation on the basis of an instruction received from the memory controller 2 (S403).

On the other hand, in a case where the mode flag flgM is the high read tolerance mode (S402_No), the memory controller 2 instructs the semiconductor memory device 3J to execute the first read operation. Next, the sequencer 13 executes the first read operation on the basis of an instruction received from the memory controller 2 (S404).

### 4.7.5 Advantageous Effects of Present Modification

The present modification produces advantageous effects similar to those of the second modification of the fourth embodiment.

### 4.8 Fourth Modification

A semiconductor memory device 3K according to a fourth modification of the fourth embodiment will be described. The semiconductor memory device 3K according to the present modification differs from that of the fourth embodiment in terms of the method of designating the memory mode of the block BLK. Hereinafter, the following description will in principle concentrate on the features different from the fourth embodiment.

### 4.8.1 Method of Designating Memory Mode of Block

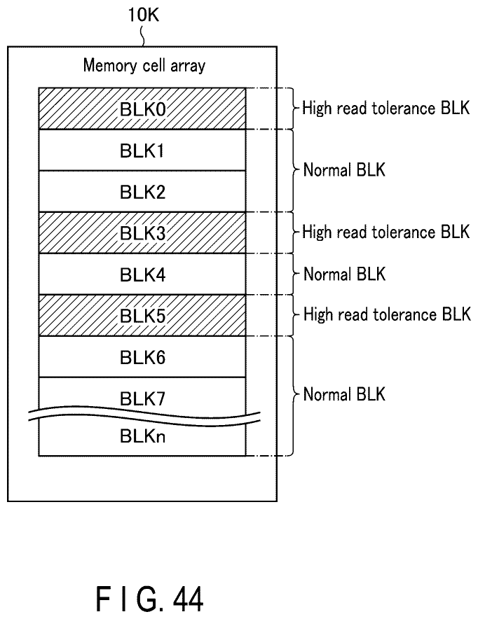

The modification corresponds to a case in which the memory mode of a block BLK during the write operation is designated. FIG. 44 is a view illustrating a method of designating the memory mode of the block BLK in a semiconductor memory device 3K according to the present modification. As shown in FIG. 44, in the present modification, one of the high read tolerance mode and the normal mode can be designated. In the example shown in FIG. 44, the memory mode of the blocks BLK0, BLK3, and BLK5 is designated as the high read tolerance mode. The memory mode of each of the other blocks BLK is designated as the normal mode.

### 4.8.2 Mode Flag

In the present modification, as memory mode information, the mode flag flgM is used as in the second modification of the fourth embodiment.

### 4.8.3 Write Operation

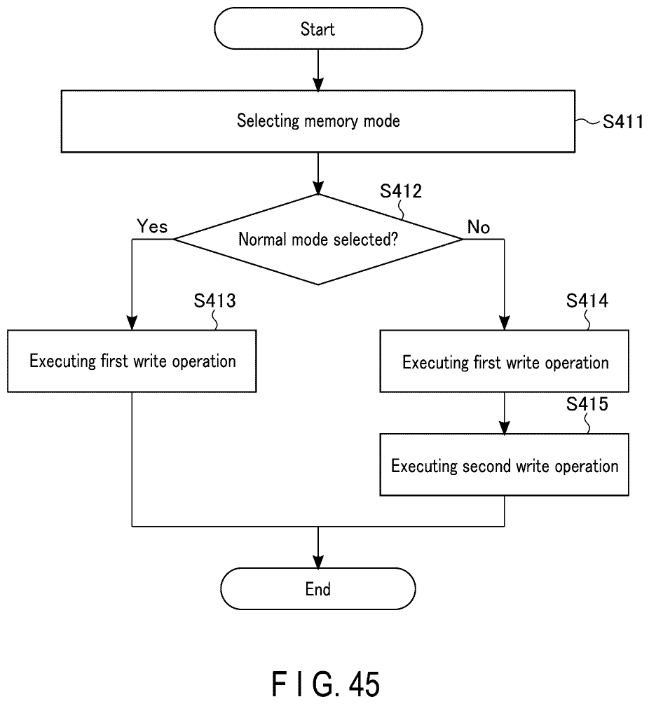

The write operation of the semiconductor memory device 3K according to the fourth modification of the fourth embodiment will be described. The write operation of the semiconductor memory device 3K according to the present modification includes the first write operation and the second write operation. FIG. 45 is a flowchart showing an example of the write operation of the semiconductor memory device 3K according to the present modification.

For example, in a case where the write operation is initiated, the memory controller 2 selects the memory mode of the selected block BLK on the basis of write data. The memory controller 2 can select one of the high read tolerance mode and the normal mode on the basis of the type of write data.

Next, the memory controller 2 determine whether or not the selected memory mode is the normal mode (S412).

In a case where the selected memory mode is the normal mode (S412_Yes), the memory controller 2 instructs the semiconductor memory device 3K to execute the first write operation. Next, the sequencer 13 executes the first write operation on the basis of an instruction received from the memory controller 2 (S413). In the first write operation, the sequencer 13 also performs writing (updating) of the mode flag flgM within the selected block BLK. Upon completion of the first write operation, the write operation is completed.

On the other hand, in a case where the selected memory mode is the high read tolerance mode (S412_No), the memory controller 2 instructs the semiconductor memory device 3K to execute the first write operation and the second write operation. Next, the sequencer 13 executes the first write operation on the basis of an instruction received from the memory controller 2 (S414). In the first write operation, the sequencer 13 also performs writing (updating) of the mode flag flgM within the selected block BLK. Next, the sequencer 13 executes the second write operation on the basis of an instruction received from the memory controller 2 (S415). Upon completion of the second write operation, the write operation is completed.

### 4.8.4 Read Operation

The read operation of the semiconductor memory device 3K according to the fourth modification of the fourth embodiment will be described. The read operation of the semiconductor memory device 3K according to the present modification is similar to the read operation described in the second modification of the fourth embodiment.

### 4.8.5 Advantageous Effects of Present Modification

The present modification produces advantageous effects similar to those of the fourth embodiment.

Furthermore, in the write operation, the memory mode can be designated on the basis of the type of write data, so that the flexibility of data handling is improved.

### 4.9 Fifth Modification

A semiconductor memory device 3L according to a fifth modification of the fourth embodiment will be described. The semiconductor memory device 3L according to the present modification differs from that of the fourth modification of the fourth embodiment in that the mode table tblM is used as memory mode information. Meanwhile, a circuit configuration of the memory cell array 10L and a planar layout of the memory cell array 10L are similar to those of the fourth modification of the fourth embodiment. Hereinafter, the following description will in principle concentrate on the features different from the fourth modification of the fourth embodiment.

### 4.9.1 Mode Table

In the present modification, as memory mode information, the mode table tblM is used as in the third modification of the fourth embodiment.

### 4.9.2 Write Operation

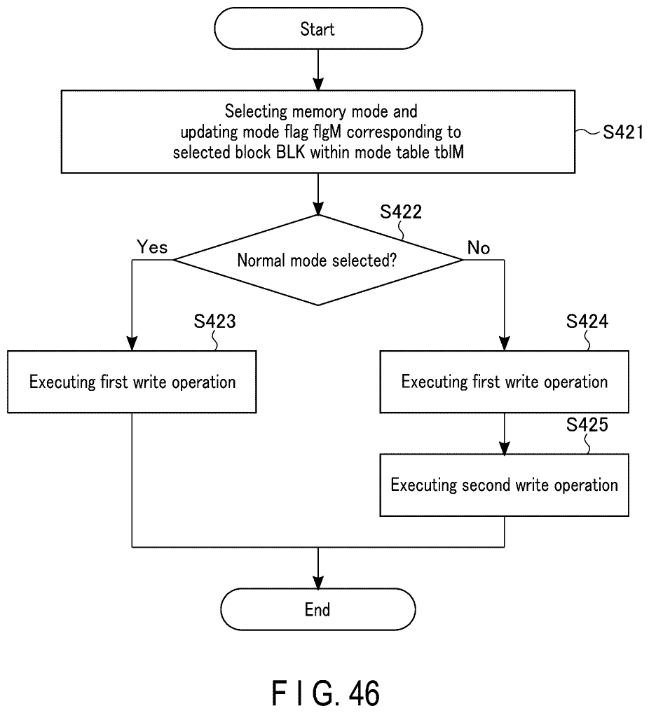

The write operation of the semiconductor memory device 3L according to the fifth modification of the fourth embodiment will be described. FIG. 46 is a flowchart showing an example of the write operation of the semiconductor memory device 3L according to the present modification.

For example, in a case where the write operation is initiated, the memory controller 2 selects the memory mode of the selected block BLK on the basis of the write data, and updates the mode flag flgM corresponding to the selected block BLK within the mode table tblM (S421).

Next, the memory controller 2 determine whether or not the selected memory mode is the normal mode (S422).

In a case where the selected memory mode is the normal mode (S422_Yes), the memory controller 2 instructs the semiconductor memory device 3L to execute the first write operation. Next, the sequencer 13 executes the first write operation on the basis of an instruction received from the memory controller 2 (S423). Upon completion of the first write operation, the write operation is completed.

On the other hand, in a case where the selected memory mode is the high read tolerance mode (S422_No), the memory controller 2 instructs the semiconductor memory device 3K to execute the first write operation and the second write operation. Next, the sequencer 13 executes the first write operation on the basis of an instruction received from the memory controller 2 (S424). Next, the sequencer 13 executes the second write operation on the basis of an instruction received from the memory controller 2 (S425). Upon completion of the second write operation, the write operation is completed.

### 4.9.3 Read Operation

The read operation of the semiconductor memory device 3L according to the fifth modification of the fourth embodiment will be described. The read operation of the semiconductor memory device 3L according to the present modification is similar to the read operation described in the third modification of the fourth embodiment.

### 4.9.4 Advantageous Effects of Present Modification

The present modification produces advantageous effects similar to those of the fourth modification of the fourth embodiment.

### 5. Fifth Embodiment

A semiconductor memory device 3M according to a fifth embodiment will be described. The semiconductor memory device 3M according to the present embodiment differs from that of the fourth modification of the fourth embodiment in terms of including an arithmetic function. Hereinafter, the following description will in principle concentrate on the features different from the fourth modification of the fourth embodiment.

### 5.1 Configuration of Semiconductor Memory Device

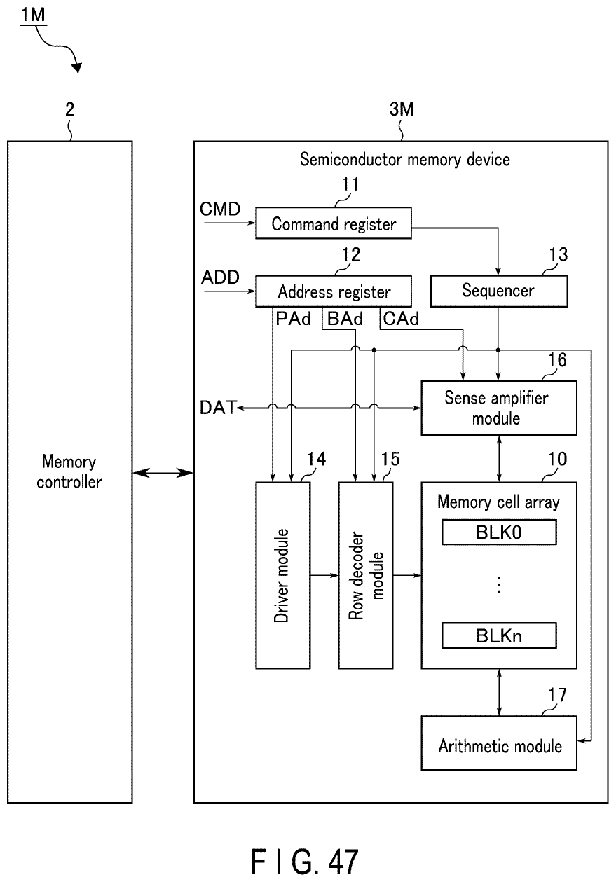

A configuration of the semiconductor memory device 3M according to the fifth embodiment will be described with reference to FIG. 47. FIG. 47 is a block diagram showing an example of a configuration of a memory system 1M including the semiconductor memory device 3M according to the fifth embodiment.

As shown in FIG. 47, the semiconductor memory device 3M further includes an arithmetic module 17.

The arithmetic module 17 is a module configured to perform various types of arithmetic processing using data stored in the memory cell transistor MT. Furthermore, the sequencer 13 controls the arithmetic module 17.

### 5.2 Configuration of Arithmetic Module

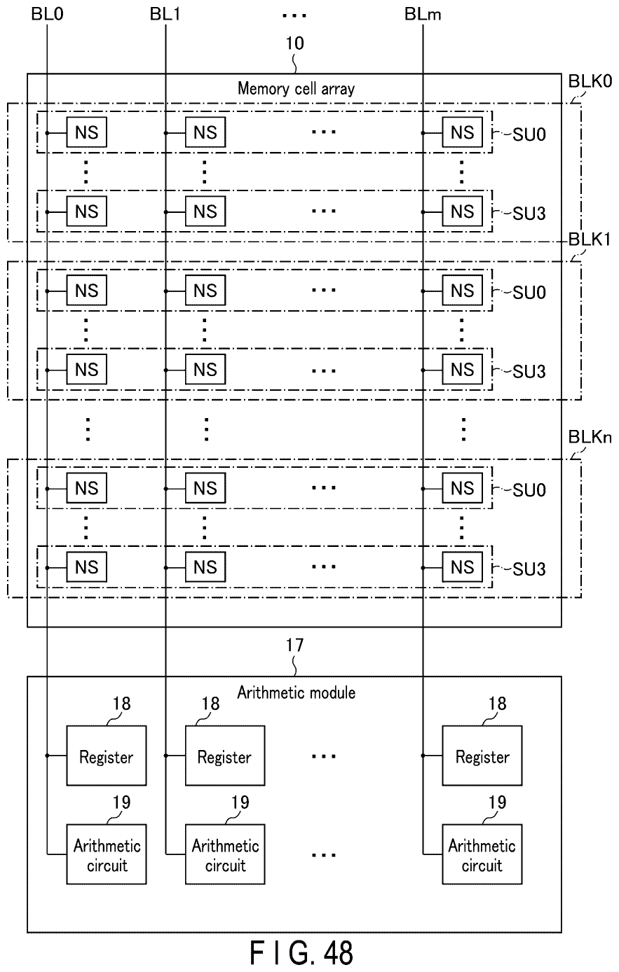

Next, a configuration of the arithmetic module 17 will be described with reference to FIG. 48. FIG. 48 is a block diagram showing an example of a configuration of the arithmetic module 17. FIG. 48 also shows the memory cell array 10 and the bit lines BL.

As shown in FIG. 48, the arithmetic module 17 includes a plurality of registers 18 and a plurality of arithmetic circuits 19.

Each of the registers 18 stores, e.g., data received from the memory cell transistor MT within the memory cell array 10 and data in the execution of the arithmetic processing. The register 18 includes a plurality of latch circuits. Each of the latch circuits stores data.

The arithmetic circuit 19 is a circuit configured to perform various types of arithmetic processing. Examples of the arithmetic processing include addition processing, subtraction processing, and comparison processing.

The plurality of NAND strings NS, the register 18, and the arithmetic circuit 19 within each of the blocks BLK are coupled to the same bit line BL.

Each of the blocks BLK within the memory cell array 10 is either the high read tolerance BLK or the normal BLK. For example, reference data such as arithmetic designating data is stored in the NAND string NS within the high read tolerance BLK. The arithmetic designating data is data for designating arithmetic contents, and for example, “1” defines addition processing whereas “0 ” defines subtraction processing. For example, input/output data is stored in the NAND string NS within the normal BLK.

### 5.3 Arithmetic Processing

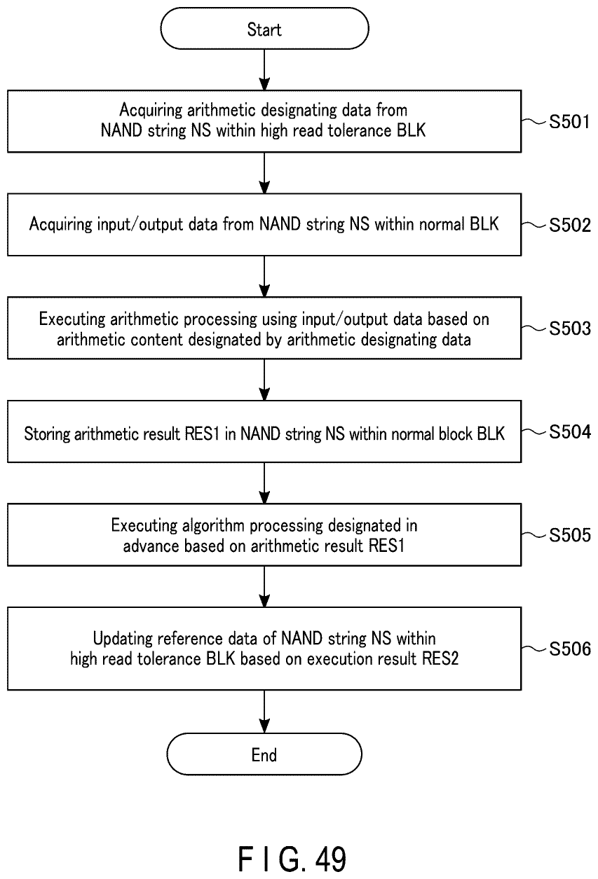

The arithmetic processing by the arithmetic module 17 of the semiconductor memory device 3M according to the fifth embodiment will be described. FIG. 49 is a flowchart showing an example of the arithmetic processing by the arithmetic module 17 of the semiconductor memory device 3M according to the present embodiment.

For example, upon receipt of an arithmetic processing request from the outside, the memory controller 2 instructs the semiconductor memory device 3M to execute the arithmetic processing.

Next, the sequencer 13 controls the arithmetic module 17 on the basis of the instruction received from the memory controller 2. The arithmetic module 17 executes the arithmetic processing.

More specifically, the arithmetic circuit 19 acquires the arithmetic designating data from the NAND string NS within the high read tolerance BLK (S501).

Next, the arithmetic circuit 19 acquires the input/output data from the NAND string NS within the normal BLK (S502).

Next, the arithmetic circuit 19 executes the arithmetic processing on the basis of the arithmetic designating data of the NAND string NS within the high read tolerance BLK and the input/output data of the NAND string NS within the normal BLK. For example, the arithmetic circuit 19 performs the arithmetic processing using the input/output data on the basis of the arithmetic contents designated by the arithmetic designating data (S503).

Next, the arithmetic circuit 19 stores an arithmetic result RES1 acquired through the arithmetic processing, in the NAND string NS within the normal BLK (S504). For example, the arithmetic circuit 19 stores arithmetic result RES1 in another NAND string NS within the normal BLK. Meanwhile, the arithmetic result RES1 may be output to the outside of the memory system 1M via the memory controller 2.

Next, the arithmetic circuit 19 executes algorithm processing designated in advance, on the basis of the arithmetic result RES1 (S505).

Next, the arithmetic circuit 19 updates the reference data of the NAND string NS within the high read tolerance BLK on the basis of an execution result RES2 (S506). For example, the arithmetic circuit 19 updates the data of the NAND string NS within the high read tolerance BLK on the basis of the execution result RES2.

### 5.6 Configuration of Artificial Intelligence (AI) Module

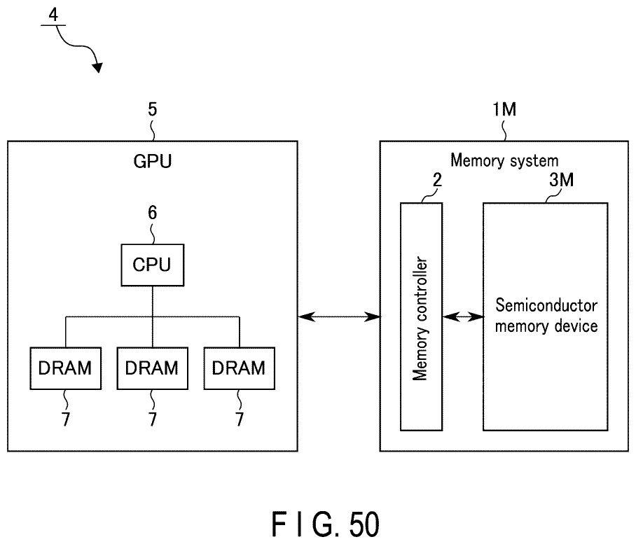

The memory system 1M including the semiconductor memory device 3M according to the fifth embodiment is applicable to, for example, an AI module. FIG. 50 is a block diagram showing an example of a configuration of the AI module in which the memory system 1M including the semiconductor memory device 3M according to the fifth embodiment is incorporated.

As shown in FIG. 50, an AI module 4 is, for example, a chip on which an AI is mounted. The AI module 4 includes, for example, a graphics processing unit (GPU) 5 and a memory system 1M.

The GPU5 includes a central processing unit (CPU) 6 and a plurality of dynamic random access memories (DRAMs) 7. The GPU 5 is coupled to the memory system 1M.

The CPU 6 is, for example, a general-purpose CPU. The CPU 6 executes various types of processing. The CPU 6 is coupled to each of the DRAMs 7.

The DRAMs 7 are each, for example, a working memory. For example, the DRAM 7 holds a large amount of data used in generative AI. The example in FIG. 50 shows a case in which the GPU 5 includes three DRAMs 7; however, the number of DRAMs 7 included in the GPU 5 may not be three.

For example, the CPU 6 transmits an arithmetic processing request to the memory system 1M. In a case where the memory system 1M receives the arithmetic processing request, the arithmetic processing is executed by the arithmetic module 17 of the semiconductor memory device 3M.

### 5.5 Advantageous Effects of Present Embodiment

The present embodiment produces advantageous effects similar to those of the fourth modification of the fourth embodiment.

With a large language model (LLM), etc., for use in generative AI, a result is generated by performing machine learning with respect to a large amount of data. Furthermore, in the AI module, for example, because of the low transfer rate with respect to the external storage, it is necessary for the large number of DRAMs inside to hold data.

The semiconductor memory device 3M according to the present embodiment further includes an arithmetic module 17. The arithmetic module 17 includes a plurality of registers 18 each coupled to one of the bit lines BL, and a plurality of arithmetic circuits 19 each coupled to one of the bit lines BL. The NAND strings NS within the high read tolerance BLK are each coupled to one of the bit lines BL. The plurality of NAND strings NS within the normal BLK are each coupled to one of the bit lines BL.

With the above configuration, as described with reference to FIG. 49, for example, reference data such as arithmetic designating data can be stored in the high read tolerance BLK, and input/output data can be stored in the normal BLK. Furthermore, the above configuration includes an arithmetic function. Thus, the arithmetic processing can also be performed while holding the large amount of reference data and input/output data.

### 6. Others

As described above, a semiconductor memory device (3) according to an embodiment includes a plurality of memory strings (NS) arranged apart from each other in a first direction (Z). The plurality of memory strings (NS) each include a semiconductor layer (22 (CPS)) extending in a second direction (Y) intersecting the first direction (Z), a first string (NSa) arranged closer to a first side surface of the semiconductor layer (22) in a third direction (X) intersecting the first direction (Z) and the second direction (Y), and a second string (NSb) arranged closer to a second side surface of the semiconductor layer (22) in the third direction (X). The first string (NSa) includes a first select transistor (ST1a) and a plurality of first memory cell transistors (MT0e to MT7e) each using the semiconductor layer (22) as a channel and arranged apart from each other in the second direction (Y). The second string (NSb) includes a plurality of first transistors (TR0 to TR7) and a second select transistor (ST2a) each using the semiconductor layer (22) as a channel and arranged apart from each other in the second direction (Y).

The embodiments are not limited to those described in the above, and various modifications can be made.

The above embodiments and modifications may be combined where possible. For example, the second modification of the third embodiment may be combined with the first modification of the third embodiment. The structure in FIG. 17 described in the second modification of the second embodiment may be applied to the second to fifth modifications of the fourth embodiment and the fifth embodiment. The fifth embodiment may be combined with one of the fourth embodiment and the first, second, third, and fifth modification of the fourth embodiment.

Furthermore, the order of the steps in the flowchart described in the above embodiments may be altered to the extent possible.

The string flgS within the block BLK is used in the third embodiment, and the string table tblS is used in the first modification of the third embodiment; however, instead of them, the string flag flgS may be added to the FAT.

The mode flgM within the block BLK is used in the second modification and the fourth modification of the fourth embodiment, and the mode table tblM is used in the third modification and the fifth modification of the fourth embodiment; however, instead of them, the mode flag flgM may be added to the FAT.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a plurality of memory strings arranged apart from each other in a first direction,
wherein the plurality of memory strings each include:
a semiconductor layer extending in a second direction intersecting the first direction;
a first string arranged closer to a first side surface of the semiconductor layer in a third direction intersecting the first direction and the second direction; and
a second string arranged closer to a second side surface of the semiconductor layer in the third direction,
the first string includes a first select transistor and a plurality of first memory cell transistors each using the semiconductor layer as a channel and arranged apart from each other in the second direction, and
the second string includes a plurality of first transistors and a second select transistor each using the semiconductor layer as a channel and arranged apart from each other in the second direction.

2. The device according to claim 1, wherein
the plurality of first transistors within the second string each have a same structure as structures of the first select transistor and the second select transistor.

3. The device according to claim 1, wherein
in a read operation, of the plurality of first memory cell transistors within the first string, a cell current is not caused to flow through the first memory cell transistors other than a selected first memory cell transistor; and
of the plurality of first transistors within the second string, the cell current is not caused to flow through one or more of the first transistors positioned in a vicinity of the selected first memory cell transistor and is caused to flow through the remaining first transistors.

4. A semiconductor memory device comprising:
a plurality of memory strings arranged apart from each other in a first direction in each of a plurality of blocks,
wherein the plurality of memory strings each include:
a semiconductor layer extending in a second direction intersecting the first direction;
a first string arranged closer to a first side surface of the semiconductor layer in a third direction intersecting the first direction and the second direction; and
a second string arranged closer to a second side surface of the semiconductor layer in the third direction,
the first string includes a first select transistor and a plurality of first memory cell transistors each using the semiconductor layer as a channel and arranged apart from each other in the second direction,
the second string includes a plurality of second memory cell transistors and a second select transistor each using the semiconductor layer as a channel and arranged apart from each other in the second direction, and
write data is written to one of the first string and the second string.

5. The device according to claim 4, wherein
the string to which the write data is to be written is switched in units of block of the blocks.

6. The device according to claim 5, wherein
the string to which the write data is to be written is periodically switched.

7. The device according to claim 6, wherein
the string to which the write data is to be written is switched every time a write operation is executed on a selected block of the blocks.

8. The device according to claim 4, wherein
predetermined data is written to a remaining one of the first string and the second string.

9. The device according to claim 8, wherein
the predetermined data is data at a write level in an SLC.

10. A semiconductor memory device comprising:
a plurality of memory strings arranged apart from each other in a first direction in each of a plurality of blocks,
wherein the plurality of memory strings each include:
a semiconductor layer extending in a second direction intersecting the first direction;
a first string arranged closer to a first side surface of the semiconductor layer in a third direction intersecting the first direction and the second direction; and
a second string arranged closer to a second side surface of the semiconductor layer in the third direction,
the first string includes a first select transistor and a plurality of first memory cell transistors each using the semiconductor layer as a channel and arranged apart from each other in the second direction,
the second string includes a plurality of second memory cell transistors and a second select transistor each using the semiconductor layer as a channel and arranged apart from each other in the second direction, and
of the plurality of blocks, in a first block for which a memory mode is designated as a first mode, write data is written to one of the first string and the second string, and in a second block for which the memory mode is designated as a second mode, the write data is written to both of the first string and the second string.

11. The device according to claim 10, wherein
of the plurality of blocks, a fixed block is designated as the first mode.

12. The device according to claim 10, wherein
based on a number of accesses to data in a selected block of the blocks, a boundary position between the first block and the second block within the plurality of blocks is varied.

13. The device according to claim 12, wherein
in a case where a number of reads within a fixed period of time with respect to data in the second block of the plurality of blocks has exceeded a first threshold value, the memory mode of the second block is switched to the first mode, and in a case where no read is performed within a fixed period of time with respect to data in the first block, the memory mode of the first block is switched to the second mode.

14. The device according to claim 10, wherein
in a write operation, the memory mode of a selected block of the blocks is designated.

15. The device according to claim 14, wherein
each of the plurality of blocks stores a first flag as information indicating whether the memory mode of the selected block has been designated as the first mode or the second mode, and
in the write operation, the first flag is updated.

16. A memory system comprising:
the semiconductor memory device according to claim 14; and
a controller configured to control the semiconductor memory device,
wherein the memory controller includes a first table as information indicating whether the memory mode of the selected block has been designated as the first mode or the second mode, and updates the first table in a write operation.

17. The device according to claim 10, further comprising:
a plurality of bit lines each coupled to one of the plurality of memory strings included in each of the plurality of blocks; and
an arithmetic module,
wherein the arithmetic module includes:
a plurality of registers each coupled to one of the bit lines; and
a plurality of arithmetic circuits each coupled to one of the bit lines, and
each of the arithmetic circuits executes arithmetic processing on a basis of first data of a first memory string within the first block and second data of a second memory string within the second block.

18. The device according to claim 17, wherein
the plurality of arithmetic circuits each execute the arithmetic processing using the second data on a basis of an arithmetic content designated by the first data.

19. The device according to claim 17, wherein
the arithmetic circuits store a result of the arithmetic processing in a third memory string within the second block.

20. The device according to claim 17, wherein
the arithmetic circuits execute algorithm processing designated in advance, on a basis of a result of the arithmetic processing, and update the first data of the first memory string within the first block, on a basis of a result of the algorithm processing.
